(19) United States
(12) Patent Application Publication
(10) Pub. No.: US 2025/0174570 A1
(43) Pub. Date: May 29, 2025

(54) METHODS AND SYSTEM FOR ADDITIVE MANUFACTURED SEMICONDUCTOR PACKAGING, ASSEMBLIES, AND HETEROGENEOUS INTEGRATION

(71) Applicant: Advanced Printed Electronic Solutions LLC, Fishkill, NY (US)

(72) Inventor: Richard Neill, Garrison, NY (US)

(73) Assignee: Advanced Printed Electronic Solutions LLC, Fishkill, NY (US)

(21) Appl. No.: 18/963,306

(22) Filed: Nov. 27, 2024

Related U.S. Application Data
(60) Provisional application No. 63/550,315, filed on Feb. 6, 2024.
(60) Provisional application No. 63/602,882, filed on Nov. 27, 2023.

(51) Int. Cl. H01L 23/538; H01L 21/48; H01L 21/52; H01L 23/13; H01L 23/367; H01L 25/07

(52) U.S. Cl. CPC H01L 23/5386; H01L 21/4846; H01L 21/52; H01L 23/13; H01L 23/3675; H01L 25/072

(57) ABSTRACT

A device and a method of making the device is provided. The device includes a substrate defining a three-dimensionally shaped volume deposition layer. At least one mount defining a semiconductor plane member is integrally formed on the volume deposition layer. The semiconductor plane member is configured to couple with a semiconductor die or at least one connection point thereon.

### RELATED APPLICATIONS

This application claims the benefit of priority to U.S. Provisional Application Ser. No. 63/602,882, titled “Methods and System for Additive Manufactured Semiconductor Packaging, Assemblies, and Heterogeneous Integration,” and filed Nov. 27, 2023 and claims the benefit of priority to U.S. Provisional Application Ser. No. 63/550,315, titled “Methods and System for Additive Manufactured Semiconductor Packaging, Assemblies, and Heterogeneous Integration,” and filed Feb. 6, 2024 the contents of each of the above applications is hereby incorporated by reference in their entirety.

### BACKGROUND OF THE DISCLOSURE

The subject matter disclosed herein relates to semiconductor devices, and in particular to semiconductor packaging.

Semiconductor packaging has evolved from dual in-line (DIP) package types, where a single chip die contains a limited number of peripheral input-output (I/O) pads. These I/O pads are then wire bonded and connected to a variety of device package leads.

Advanced semiconductors such as central processing units (CPUs), graphics processing units (GPUs), and System-on-Chip (SoC) devices, contain chip dies with billions of transistors and provide dense I/O interfaces based on bump and microbump technologies implemented in a variety of package structures. Over time, the trend has been towards increased complexity and functionality while achieving a smaller form factor, reduction in power, and reduction in cost. Following the so-called SoC design approach (integration of more functions in a device with each generation) has led to significant design, production cost increases and reliability or yield issues (which increases final component cost) as semiconductor process technologies increase in complexity.

Motivated by a desire to increase device functionality while maintaining manufacturing yield, reliability and cost, the industry is evolving from the SoC based approach, where increasingly complex and costly single dies are designed and fabricated, to a more cost-effective System-in-Package (SiP) or System-on-Package (SoP) approach whereby multiple, simpler chip dies along with other components (e.g., sensors, micro-electro-mechanical systems (MEMS), photonic devices, mixed-signal devices, radio frequency devices, analog devices, passives, and/or the like including combinations and/or multiples thereof) are integrated and packaged together. In many cases the chip dies are based on reusable libraries of IP or pre-engineered, hardened dies from different suppliers. This results in lower development time and costs as designers can mix-and-match different chip dies and integrate them into both existing package types, process nodes, as well as completely new architectures.

This approach to SiP and SoP semiconductor device and system designs is referred to as the “Chiplet” model in conjunction with Heterogeneous Integration (HI) technologies as shown schematically in FIG. 1A. In chiplet, heterogeneous integrated based designs (chiplet/HI), semiconductor packages are constructed by integrating multiple dies, each of which is simpler as compared to a single larger SoC die. A chiplet-based implementation is organized in planar-only geometric stacking structures comprising one or more die bond methods that attach the one or more chiplet dies either directly to a substrate or in conjunction with interposer or redistribution layer (RDL) structures to implement a complete multi-chiplet package solution. An interposer (FIG. 1B-FIG. 1C) is an intermediary structure within the package whose purpose is to provide a high-speed, low-latency electrical interface routing between circuits or inter-chiplet die connection points. Secondly, the interposer allows for the fan-out of electrical signals from one die bump pitch (C2 or microbump, pillar, or direct die pad) to a different, typically larger bump (C4) pitch for easier packaging. An RDL provides similar functionality, especially for die-to-die interconnections, power, and ground signal distribution, or redistribution of the I/O locations from the chip to the package, enabling easier connection by virtue of I/O connection fan-out of the resulting chip package to a printed circuit board (PCB) or other substrate.

Semiconductor packaging based on chiplets provides for the integration of complex, highly dense die pad pitches and corresponding interconnections among chiplets enabling the realization of complete SiP or SoP based on methods of Heterogeneous Integration (HI).

It should be appreciated that while FIGS. 1A-1D illustrate a particular prior art semiconductor packaging configuration and forecasted future semiconductor multiple die packaging scenarios, this is for example purposes only.

While existing semiconductor packaging techniques are suitable for their intended purposes the need for improvement and package flexibility remains, particularly in providing systems and methods having the features described herein.

### BRIEF DESCRIPTION OF THE DISCLOSURE

According to one aspect of the disclosure, a device is provided. The device includes a substrate defining a three-dimensionally shaped volume deposition layer. At least one chiplet plane member integrally formed on the volume deposition layer, the chiplet plane member configured to electrically couple with a semiconductor die or at least one bump or die pad bond connection.

According to another aspect of the disclosure, a device is provided. The device includes a three-dimensional volume distribution layer defined by a plurality of chiplet voxels. A first chiplet plane member is defined by a first chiplet voxel of the plurality of chiplet voxels, the chiplet plane member being configured to electrically couple with a semiconductor die pad or a bump connection.

According to yet another aspect of the disclosure, a method for fabricating or simulating a chiplet-based device package is provided. The method includes using additive manufactured electronics (AME) parametrics for additive manufacturing.

These and other advantages and features will become more apparent from the following description taken in conjunction with the drawings.

### BRIEF DESCRIPTION OF DRAWINGS

The subject matter, which is regarded as the disclosure, is particularly pointed out and distinctly claimed in the claims at the conclusion of the specification. The foregoing and other features, and advantages of the disclosure are apparent from the following detailed description taken in conjunction with the accompanying drawings in which:

FIGS. 1A-1D are schematic illustrations of a prior art semiconductor packaging configuration for SiP, SoP and chiplets;

FIG. 2A is a schematic illustration of a chiplet coupled to a chiplet plane member in accordance with an embodiment;

FIG. 2B is a schematic illustration of a chiplet coupled to a plurality of chiplet plane members having varying depths in accordance with an embodiment;

FIGS. 2C-2H are schematic illustrations of different configurations of devices having volume distribution layers with chiplet plane members and chiplet frames;

FIG. 3A is a schematic illustration of a volume distribution layer comprised of chiplet voxels that define chiplet plane members in accordance with an embodiment;

FIG. 3B is a schematic illustration of a volume distribution layer comprised of chiplet voxels having chiplet plane members having less than or greater than four sides.

FIGS. 4A and 4B are schematic illustrations showing an integration of chiplet dies to volume distribution layer with inter-chiplet interconnections using a chiplet plane member in accordance with an embodiment;

FIGS. 4C-4E are schematic illustrations showing the illustration of the chiplet dies to volume distribution layers having integrally formed circuit interconnections, spatial interconnections, and/or through printed vias in accordance with an embodiment;

FIG. 4F is a schematic illustration of the process shown in FIG. 4A using chiplet stacks in accordance with an embodiment;

FIGS. 4G-4H are schematic illustrations of chiplet dies being formed into chiplet stacks attached to a substrate and multi-chiplet stack interconnection network in accordance with an embodiment;

FIGS. 4J-4R are schematic illustrations of chiplet voxels having multiple chiplet dies arranged in different configurations in accordance with an embodiment;

FIGS. 5A and 5B are schematic illustrations of a SiP/SoP device having volume distribution layers, chiplet planes, chiplet frames and optional thermal volume layers, shield volume layers, and outer packaging layers in accordance with an embodiment;

FIGS. 6A-6E are schematic illustrations of a SiP/SoP device using an interposer device fabricated using AME methods in accordance with an embodiment;

FIGS. 7A-7E are schematic illustrations of devices having planar and/or nonplanar volume distribution layers with chiplet planes, spatial interconnects and different configurations of optional thermal volume layers in accordance with an embodiment;

FIGS. 8A-8E are schematic illustrations of a portion of a device having a chiplet mounted to a chiplet planar member with different thermal management configurations in accordance with an embodiment;

FIG. 9A is a schematic illustration of a device having one or more volume distribution layers defined by chiplet voxels;

FIG. 9B is a schematic illustration of an enlarged portion of the device of FIG. 9A showing a chiplet voxel with multiple chiplet plane members;

FIGS. 9C-9J are illustrations of hexagonal chiplet/heterogeneous-integration volume package elements in accordance with one or more embodiments;

FIGS. 10A-10C are schematic illustrations of a method of testing and repairing or reconfiguring circuits fabricated through additive manufacturing;

FIGS. 10D-10H are schematic illustrations of a method for generating a chiplet and/or component testing device in accordance with one or more embodiments;

FIG. 11A is a schematic illustration of a prior art multiple chiplet modules interconnected in a system-in-package configuration using prior art inter-chiplet communication methods;

FIGS. 11B and 11C are schematic illustrations of multiple chiplet modules interconnected in a system-in-package configuration using AME fabrication methods in accordance with an embodiment;

FIGS. 11D-11F are schematic illustrations of an additive manufactured electronics chiplet interconnect in accordance with an embodiment;

FIG. 12A is a schematic illustration of multiple chiplet implementation whose chiplets are interconnected using AME fabrication methods in accordance with an embodiment;

FIG. 12B is a schematic illustration of multiple chiplet implementation interconnected using AME fabrication methods in accordance with an embodiment;

FIG. 13A is a schematic illustration of prior art tile-based system-on-chip device whose multiple tile modules are interconnected in a network-on-chip configuration using prior art communication methods;

FIGS. 13B and 13C are schematic illustrations of a tile-based system-on-chip device adapted to a chiplet architecture, integrating a UCIe-based tile module and AME fabrication methods in accordance with an embodiment;

FIGS. 14A and 14B are data flow diagrams for a system for designing an AME device in accordance with an embodiment;

FIGS. 15A-15C are data flow diagrams for auto recovery and or repair of AME fabricated semiconductor devices in accordance with an embodiment;

FIGS. 16A and 16B are block diagrams of architectures for optimized planar chiplet/HI package AME design and fabrication according to one or more embodiments described herein;

FIG. 16C is a block diagram of a software architecture for AME-based package as a service according to one or more embodiments described herein;

FIG. 17A is a pre-defined layer stack according to one or more embodiments described herein;

FIG. 17B is a pre-defined device floor plan for a planar packaging flow according to one or more embodiments described herein;

FIG. 17C is a configurable device floor plan for a planar packaging flow according to one or more embodiments described herein;

FIG. 17D is a generatively designed device floor plan for a planar packaging flow according to one or more embodiments described herein;

FIG. 17E is a pre-defined multi-layer structure with a chiplet stack according to one or more embodiments described herein; and

FIG. 18 is a schematic illustration of a processing system for implementing the presently described techniques according to one or more embodiments described herein.

The detailed description explains embodiments of the disclosure, together with advantages and features, by way of example with reference to the drawings.

### DETAILED DESCRIPTION OF THE DISCLOSURE

Embodiments of the present disclosure provide for devices that are configured and fabricated in a manner that allows for non-planar semiconductor packaging, such as for the integration of circuits having chiplets on or within complex geometries. Still further embodiments of the disclosure provide for a means of fabricating a device wherein the device is defined by a plurality of chiplet voxels that allow to for the additive manufacturing of semiconductor devices. Still further embodiments of the disclosure provide for packaging and fabricating optimal material tool path processes. Yet still further embodiments incorporate additive manufacturing methods in the fabrication and implementing operation of inter-chiplet integration and communications.

Prior art chiplet semiconductor packaging is performed in a planar manner. While the overall package is three-dimensional, conventional manufacturing techniques result in the components of the package being arranged in a planar manner, either stacked or parallel on flat substrates. As a result, the shape of the package is severely restrained. It should be appreciated that this causes inefficiencies in the design of the device in which semiconductor package will be used since it must accommodate the planar nature of the semiconductor package.

With improvements to manufacturing processes, such as those utilizing additive manufacturing for example, device shapes may be fabricated in three-dimensions without the constraints imposed by prior art manufacturing processes. These improvements may be applied to chiplet semiconductor packaging as described herein to produce chiplet-based semiconductor devices that at least partially vary in three-dimensional space and have reduced size, reduced cost, improved performance, or a combination of the foregoing.

It should be appreciated that while embodiments herein refer or imply that the devices or the layers/chiplet-voxels (as defined herein) that comprise the devices are relatively rigid, this is for example only and the claims should not be so limited. The materials used in the additive manufacturing processes may include materials that are flexible (relative, for example, to a prior art printed circuit board) or have sufficient flexibility to allow the device (or layers/chiplet-voxels therein) to be used in flexible electronics applications, such as a semiconductor package in the shape of a flexible arc that bends or mounts on a user's wrist for example. Accordingly, the embodiments described herein may be made from a flexible material having an elastic limit that allows the device, or portions thereof, to be repeated deformed, bent or twisted and then substantially returned to its original shape.

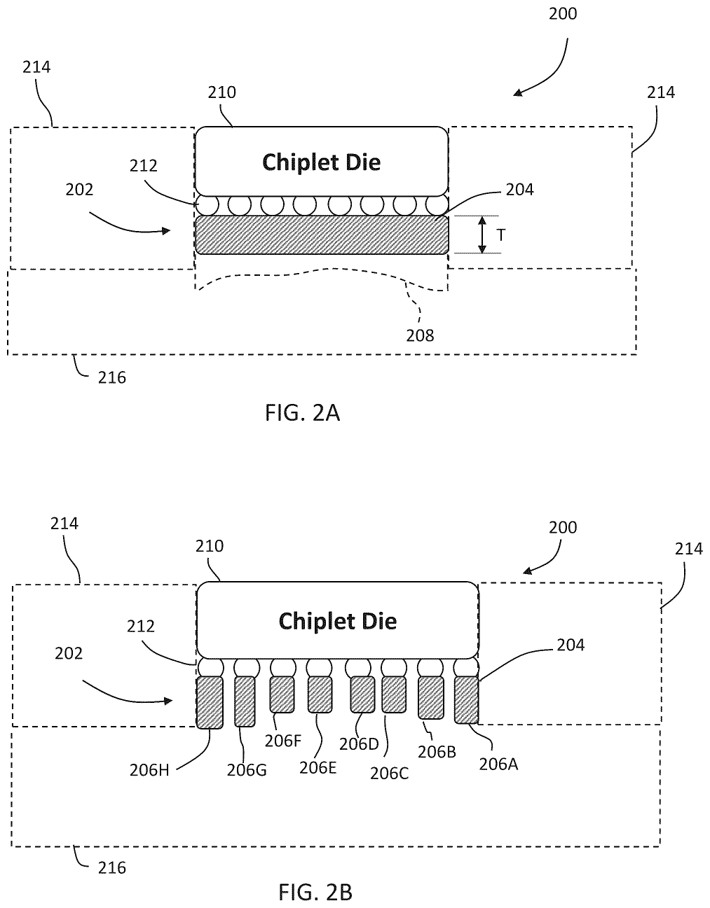

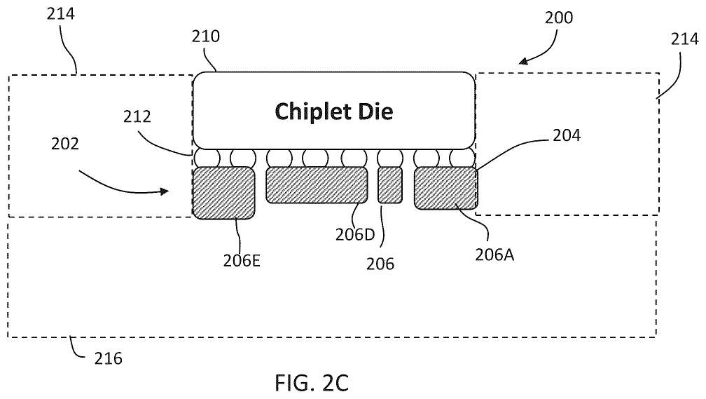

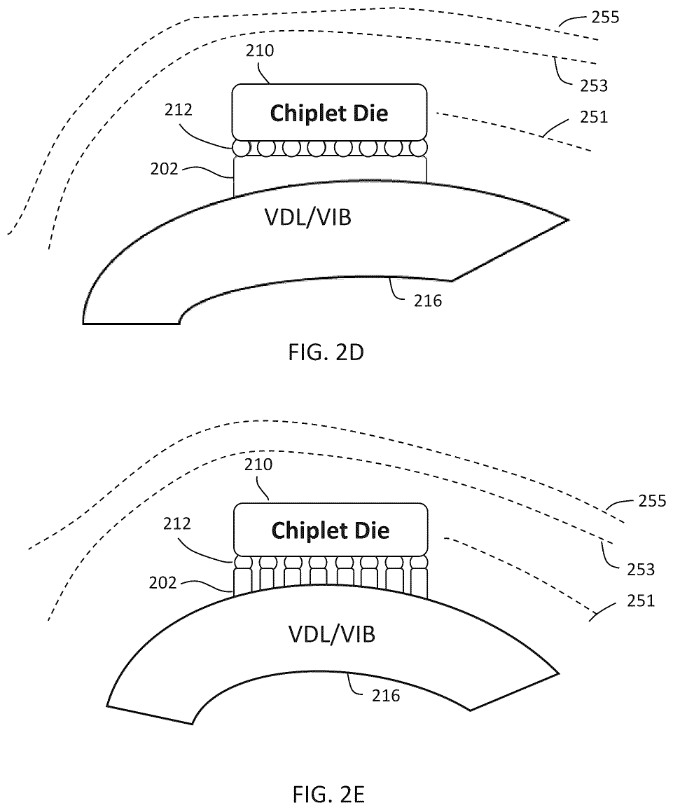

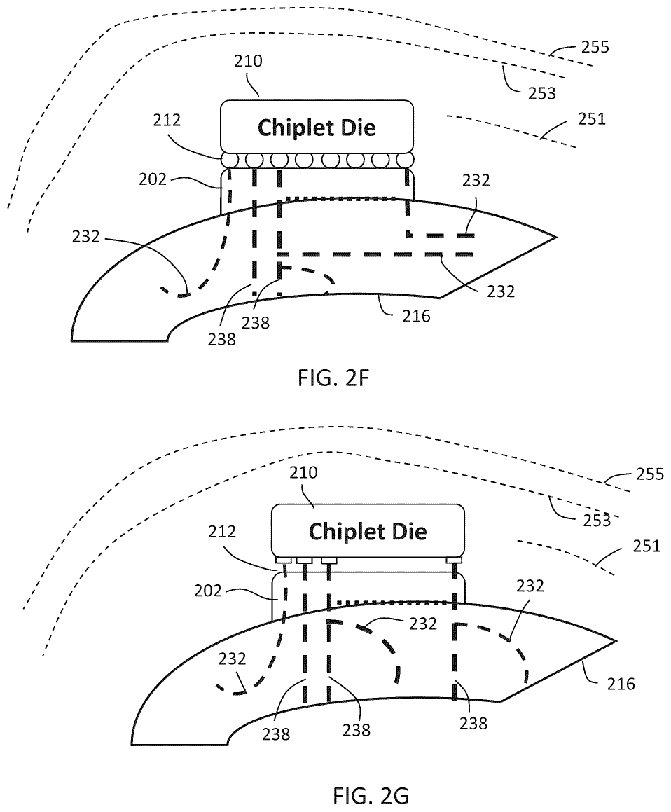

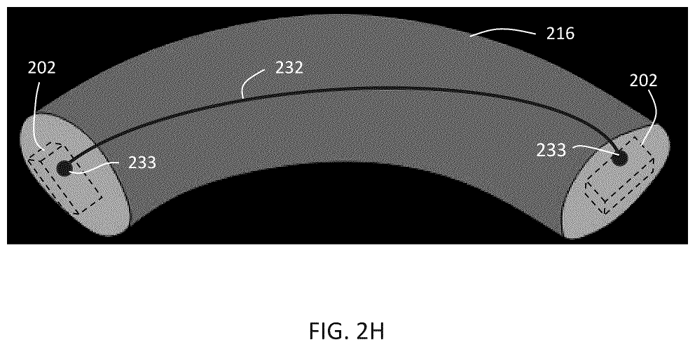

Referring now to FIGS. 2A-4D, embodiments are shown of embodiments of an additive manufactured electronics (AME) chiplet semiconductor device 200 heterogeneous integration (HI) that were fabricated using in accordance with the teachings provided herein. The device 200 may be manufactured using a multi-axis additive manufacturing system, such as that described in U.S. patent application Ser. No. 17/574,326, the contents of which is incorporated by reference herein. In another embodiment, planar devices may be manufactured using 3-axis additive manufacturing systems.

The device 200 includes a chiplet mounting member 202 having at least one planar surface that defines a chiplet plane 204. In some embodiments (FIG. 2B), the chiplet mounting member 202 may be comprised of a plurality of members 206A-206H (sometimes referred to as a pedestal or “boss”). It should be appreciated that the chiplet mounting member 202 is illustrated in FIG. 2B with eight members 206A-206H for example purposes only and the member 202 may have more or fewer members 206A-206H, or subsets thereof (FIG. 2C). In embodiments having a plurality of members 206A-206H, each of the plurality of members includes a chiplet plane 204 that is co-planar with the planar surface of the other plurality of members, while the opposite side of the members 206A-206H compensate for the curved underlying volume geometry.

As used herein, a volume distribution layer (VDL) is a structure within the device that provides for interconnects, through-printed-vias, passive and active devices that route signals and power, such as from chiplets for example. In some respects, the VDL provides the functionality of a planar distribution layer or an interposer and redistribution layer (RDL) in a traditional chiplet configuration. It should be appreciated that additive manufacturing methods for fabricating the VDL allow the shape of the VDL and the components and conductors to have three-dimensional shapes that can vary in shape, thickness and material for example.

As used herein, a volume interface bridge (VIB) is a particular type of VDL that allows for the interconnection of chiplets or other components that have different connection (e.g. die pads, bump or bumpless connections, wires and circuit interconnections) densities (such as line and space design rules) to allow for heterogeneous package integration where integration density may vary in complexity. It should be appreciated that these types of high-density interconnects may utilize a higher resolution additive manufacturing process than that used for fabricating a given VDL instance. Since the higher resolution process may cost more, or use more fabrication time for example, in some embodiments the VIB may be fabricated in a separate process from the VDL to improve efficiencies and lower costs. Similar to the VDL, the use of additive manufacturing methods to fabricate the VIB allow the shape of the VIB and the components and conductors to have three-dimensional shapes that can vary in shape, thickness and material for example.

In an embodiment, the chiplet plane surface, is an integral part of the VDL or VIB structure, that has a planar portion (e.g. a plane surface region that may be embedded within a 3D volume that one or more semiconductor dies can attach to) that chiplet die(s) can reside on and attach via die pads and/or bump and/or bumpless connections, and whose internal layer region (VDL/VIB) may be non-planar. Depending on the die type (i.e., Chiplet, Flip chip, BGA, etc.), the VDL interface or connection to a chip die pad (at the chip plane interface boundary) can implement one of several known bonding and attachment types and methods. In one or more embodiments, a chiplet plane can be embedded on or in a curved surface or volume substrate. In one or more embodiments, a chiplet plane may exist as a single plane or be made up multiple smaller planes where the chip dies interfaces are an accommodating protrusion or pedestal that is normal to the chiplet pad or die bump. The interface points, electrically, are interconnection circuits or integral to a VDL/VIB structure. In an embodiment, the chiplet plane is adjacent to the chiplet frame layer that resides over a thermal volume layer planar region in terms of layer ordering.

It should be appreciated that the illustrated chiplet mounting members 202 are for example purposes only and in other embodiments the chiplet mounting members may have other shapes. For example, the monolithic chiplet mounting member 202 of FIG. 2A may have a uniform or constant thickness “T” or may have a curved or nonuniform thickness as indicated by dashed line 208. In embodiments where the chiplet mounting member 202 is comprised of the plurality of members, such as members 206A-206H for example, each of the plurality of members 206A-206H may have different thicknesses. Further, in other embodiments, the members 206A-206H may be variable widths. Further, in still other embodiments, the members 206A-206H may have non-planar surfaces on a side opposite the chiplet plane 204.

As will be discussed in more detail below, the chip die mounting member 202 provides a chiplet plane 204 for mounting a chiplet die 210. In one embodiment, the chiplet die 210 may be electrically and structurally coupled to the chiplet plane 204 by one or more die pads or bump connections 212. While the coupling between a chiplet die and a chiplet plane, for example between chiplet die 210 and chiplet plane 204, is illustrated primarily using bumps or bump connections, it is appreciated that the bump connections may be fully or partially replaced, augmented, or substituted by one or more die pads, rod connections, or another electrical and structural coupling suitable for use with integrated circuits, photonic integrated circuits, photonic connections, and wireless interfaces.

In embodiments where the chiplet mounting member 202 is comprised of a plurality of members 206A-206H, each of the plurality of members may include one or more die pads or bump connections. In other embodiments, the connection may be performed by a pad, C4/C2 bumps, bumpless (direct connection to pad or via), hybrid bonding, thermal compression, or solder ball process, C4/C2 bumps, bumpless, solder ball for example. It should be appreciated that these examples of connections are for example purposes only another types of semiconductor connections, including photonic-based, may be used without deviating from the teachings provided herein.

As discussed in more detail herein, the chiplet mounting member 202 and the chiplet die 210 may be supported and maintained in a desired position by a frame 214. It should be appreciated that frame 214 is illustrated with planar surfaces, however this is for example purposes and the frame 214 may be comprised of planar surfaces/interfaces, non-planar surfaces/interfaces, or a combination of the foregoing.

In one or more embodiments, and as will be discussed in more detail herein, the device 200 may include one or more VDL 216 or VIB's that are disposed adjacent to and at least partially connect with the chiplet mounting member 202. The VDL 216 may comprise one or more layers, whose interconnection geometries can traverse in 3D space to form circuit networks among and within the layers. In some embodiments, the VDL 216 may be passive-only or contain active devices in addition to circuits. Passive VDL layers contain circuit interconnections and may include discrete or thin-film resistor, capacitor, or inductors as representative passive components. Active VDL's contain in addition, devices including analog or digital semiconductor devices, microelectronic machines (MEMS) devices, sensors, resistors, capacitors, inductors (in the form of discrete components or fabricated) and other active devices providing signal functions (example UCIe retimers) and power conditioning (voltage regulation, noise suppression, impedance matching) in support of die power/ground conditioning and regulation, die-to-die or inter-chiplet communications that may utilize various associated standard inter-chiplet specifications, such as UCIe or the ODSA and Bunch-of-Wires (BoW) standards for example. The BoW standard is the sub-group of the ODSA standard which specifies the physical die-to-die electrical connectivity and interface which may be used with the systems and methods discussed herein. Reference herein to embodiments which use the ODSA standard may also use the BoW standard and embodiments which use the BoW standard may also use the ODSA standard. Furthermore, the present teachings are intended to be applicable and compatible with future versions and iterations of the standards discussed herein which may be used in whole or in part with the present disclosure.

However it is appreciated that other standards, such as the Open HBI standard, published Sep. 21, 2021 for example, may also be used. Still another embodiment, the proposed AIB standard described in Kehlet, Accelerating Innovation Through A Standard Chiplet Interface: The Advanced Interface Bus (AIB), Intel White Paper, WP-01285-1.1, Jun. 10, 2019. The UCIe, OpenHBI, and AIB standards are incorporated herein by reference. It should be appreciated that references herein to active/passive devices may include photonic devices, such as but not limited to optical waveguides, micro-mirrors, optical signals, and the like.

In one or more embodiments, the VDL and/or VIB may be fabricated in a separate manufacturing process and integrated into the device via additive manufacturing systems, and using a pick and place machine. The asynchronous fabrication of a VDL or VIB may be advantageous in that high resolution (e.g. more costly) manufacturing processes may be used to fabricate portions of the device while allowing a relatively lower resolution additive manufacturing process to fabricate the remainder of the device. An asynchronous process may also be used where the operating specifications for the VDL/VIB utilize different materials, such as glass, ceramics, resins, organic or inorganic, or other materials for example.

In an embodiment, the VDL may be used to provide the functionality of a prior-art “interposer” and/or “RDL” without the planar limitations of the prior-art devices. In other words, the VDL may be used as a three-dimensional planar interposer and/or RDL or as a “volume interposer” or “volume redistribution layer” having arbitrary 3D geometry.

One or more layers of the VDL 216 may include power planes or ground planes, or power networks, or ground networks including interconnections for power and ground interfaces. As discussed in more detail herein, each VDL layer 216 supports interconnects across the VDL layers in three-dimensional space. In one or more embodiments the interconnects may include three-dimensional printed electronic spatial interconnects (PSIs) or through-printed vias (TPVs). A TPV is a subset of the PSI where a tunnel or cylindrical volume aperture in 3D space/through 3D space is additively fabricated completely through multiple VDL layers to define a path of conductive material to electrically connect the chiplet die I/O interfaces. In some embodiments, the TPV may be combined with PSIs for bonding the chiplet I/O to an interconnection network. It should be appreciated that TPV's disclosed herein may be oriented in any direction. In other words, from the viewpoint of the Figures, the TPV's may be oriented in vertical, horizontal, or at angles for example. In an embodiment, the TPV may be configured in 3D space and is filled with conductive materials (in whole or additively) across a single or multiple VDL layers.

In some embodiments, the VDL 216 may include one or more VIBs that provide high-density interconnections across chiplets by grouping high density (and higher cost) interconnections that allows simpler and lower cost interconnections elsewhere to reduce the overall semiconductor packaging cost. A VIB may also be optimized for higher performance interconnections among chip die interfaces, whereby communications speed, latency, or electrical or physical parameters such as impedance, insertion-loss, cross-talk, RF and EMI effects, heat management and other electrical characteristics must be considered.

It should be appreciated that while the embodiments of FIG. 2A and FIG. 2B illustrate the frame 214 and the VDL 216 as being planar, this is for example purposes and these elements made change shape and/or volume when viewed in three-dimensional space. Referring now to FIG. 2D-2F, embodiments are shown of VDL's 216 that have a curved cross section (FIG. 2D-FIG. 2G). In these embodiments, the chiplet mounting member 202 adapts the planar configuration of the chiplet 210 to the curved surface of the VDL 216. It should be appreciated that while the illustrated embodiments show the chiplet mounting member 202 as sitting or being positioned on top of the VDL 216, this is for example purposes and the claims should not be so limited. In other embodiments, the chiplet mounting member 202 may be positioned at least partially within the VDL 216.

It should be appreciated, and as will be discussed in more detail herein, additional layers may be deposited adjacent the chiplet die 210. These may include one or more of a thermal volume layer 251, a shield volume layer 253, and/or an encapsulation layer 255 or lid for example. Other types of layers may also be disposed adjacent to the chiplet die 210, such as VDL's VIB's, power planes, or ground plane layers for example.

As used herein, the terms “lid” and “encapsulation layer” may be used interchangeably to reference a peripheral or outer packaging layer. In some embodiments, the lid or encapsulation layer may include the functionality of the thermal volume layer and/or the shield volume layer. Further, the lid or encapsulation layer may having openings or apertures extending through the layer to one or more adjacent layers. These apertures may be used for thermal management for example. In other embodiments, these apertures may be used to allow components positioned at least partially adjacent to the lid or encapsulation layer to function. These components may include, but are not limited to, sensors, thermocouples, thermistors, humidity sensors, proximity sensors, ultrasonic transducers, pressure sensors, hall effect sensors, photodetectors, infrared sensors, gas sensors, MEMS devices, antennae (individual or phase array), imaging sensors, CCD sensors, focal plane array imaging sensors, LIDAR sensors, quantum devices, and the like for example.

FIG. 2F and FIG. 2G further illustrate electrical connections, such as through through-printed via's 238 and interconnections 232. As will be discussed in more detail herein, the interconnections 232 and vias 238 are arranged within the VDL 216 and provide for an interconnection with other chiplets or electrical components. The interconnections 232 may be linear or have a three-dimensional (e.g. curved) shape.

The chiplet die is coupled to the VDL through additive manufacturing compatible bonding methods that include depositing conductive materials. Within the VDL layer, apertures or vias may be formed that are filled with a conductive material forming a 3D interconnection between die I/O interfaces and interconnection networks.

In other embodiments, the VDL layer circuit interconnections may include conductive materials that directly bonded to and between die pad interfaces and interconnection networks. When bonding to chiplet die pads or bumps, material is deposited and sintered progressively, or jetted/deposited then reflowed or sintered via application of energy (thermal, photonic, etc.), such that a bond is created between the chiplet interconnection interface and the TPV. It is appreciated that various methods of manufacturing may be used to form a desired VDL, such as additive manufacturing, including extrusion, droplet, aerosol, dispensed, fusion, or jetting based material deposition, or volumetric additive manufacturing (VAM), although not limited thereto.

In some embodiments, methods from VAM are utilized to fabricate one or more aspects of the substrate and/or device package including one or more VDL structures. The VDL may be formed from a material which can be selectively cured into a conductive or insulating voxel/region using programmatic polymerization techniques. In some embodiments, VAM “overprinting” may be used. Overprinting refers to the ability to add new 3D structures directly onto or around existing structures, essentially “printing over” a pre-existing object within the active printing volume, without the need for additional support structures. In VAM applications, this may be achieved by strategically adjusting the light patterns used to solidify the material and may allow for complex, multi-material designs where different components such as semiconductor packages with multiple internal structures can be built in stages within the same print volume.

In some embodiments, VAM and overprinting may be used to form the VDL or planar interposer/RDL structures including conductive/insulating signal networks, power and ground plane and distribution networks, chiplet die-to-die interfaces, bonding and attachment interfaces, or other components (such as passive or active electronic devices, photonic interfaces, and I/O connectors) through the process of selective photo-polymerization and/or simultaneous synthesis. In this way, regions of 3D space within a given material are transformed from liquid to solid state as conductive or insulating on a voxel-by-voxel basis. Such methods may be desirable as a semiconductor package structure may be fabricated quickly and efficiently through both iterative and overprinting processes.

In other embodiments, different methods may also be utilized for chiplet die bonding; including thermocompression and laser assisted bonding similar to flip-chip bonding approaches or hybrid bonding methods. It should be appreciated that one benefit AME, VAM, and other methods described herein include new bonding approaches may be incorporated without deviating from the teachings herein.

Referring now to FIG. 2H, a VDL 216 is shown having a shape that changes in three-dimensional space. In this embodiment, the chiplet mounting members 202 are mounted on opposite ends of a curved VDL 216. A printed spatial interconnection 232 extends through the VDL 216 to electrically connect the chiplet mounting members 202. It should be appreciated that the interconnection 232 may follow a path or be shaped in a manner that curves relative to the VDL 216 to achieve a desired performance or function (e.g. reduce EMF) or target device package geometry. In an embodiment, each end of the spatial interconnection 232 is an I/O connection 233, such as a pad or bump for example. In an embodiment, the material characteristics of VDL 216 may vary in order to achieve a desired thermal, electrical, or mechanical functions or characteristics.

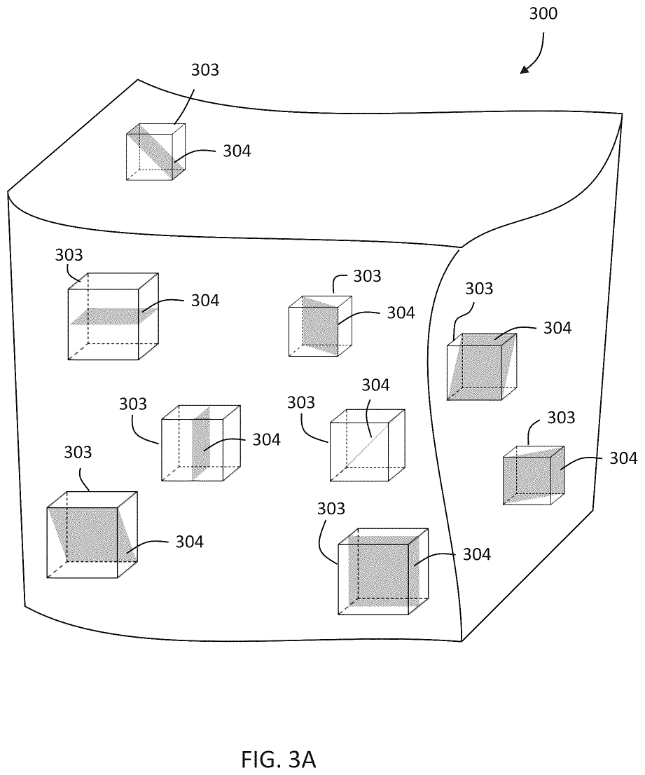

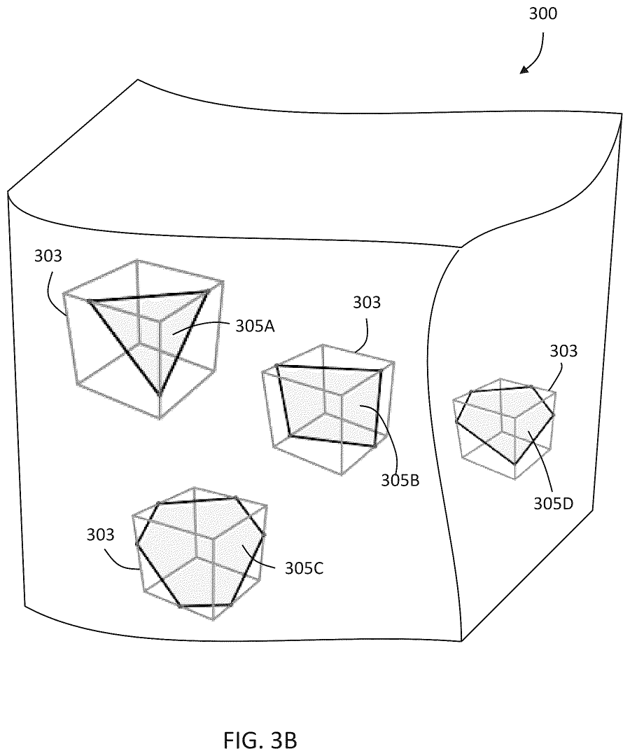

It should be appreciated that while the embodiments of FIG. 2A-2G illustrate the chiplet mounting member 202 as having a plane that is tangential to a surface, this is for example purposes and the claims should not be so limited. In other embodiments, the chiplet mounting member may be disposed within a device 300 (FIG. 3A) that is defined as having a plurality of chiplet voxels 303. The chiplet voxels 303 define a space for the chiplet mounting member and allow the chiplet planes 304 to be defined on any angle within the chiplet voxel. Accordingly, the chiplet planes 304 may be internal to the device 300, on a surface of the device 300, or a combination thereof.

In other embodiments, the chiplet voxels 303 may allow for the defining of chiplet planes that are defined by other geometric shapes, such as a triangular chiplet plane 305A, a quadrilateral plane 305B, or polygonal planes having five or more edges 305C, 305D.

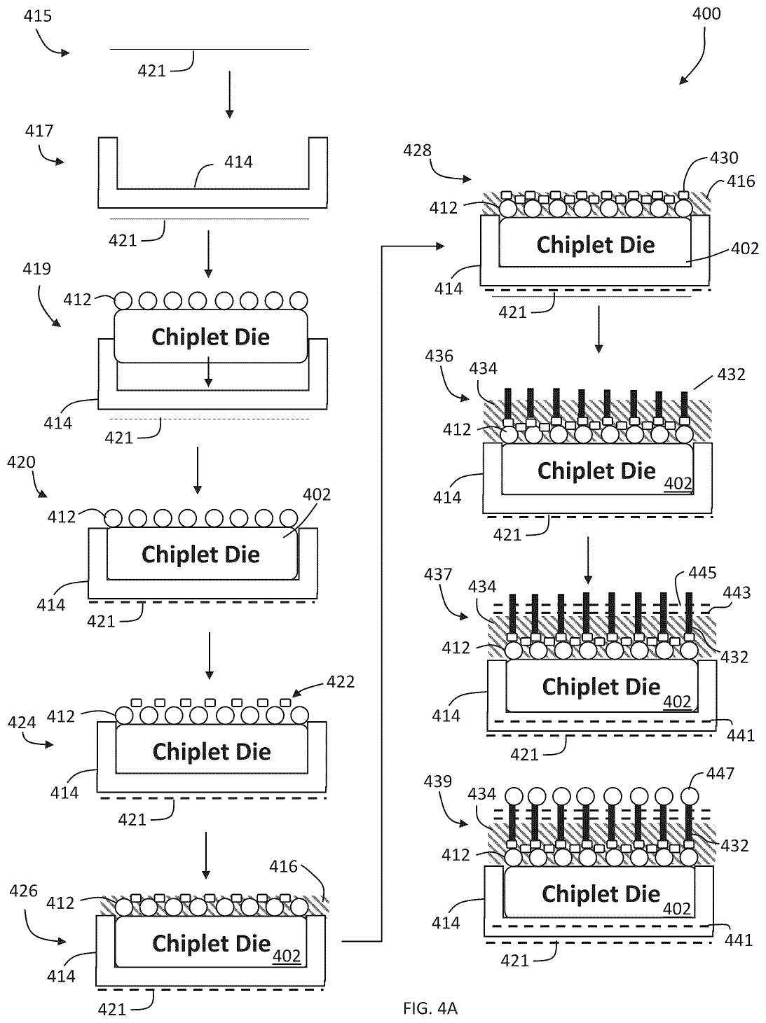

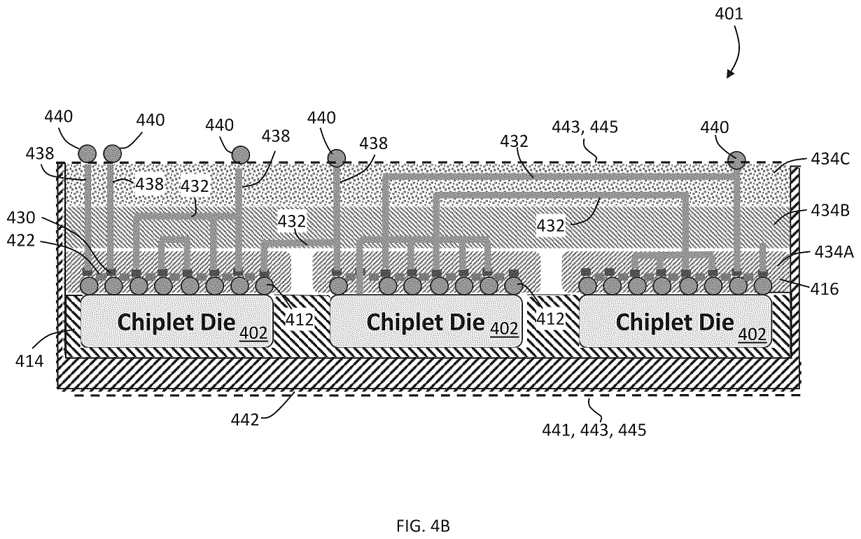

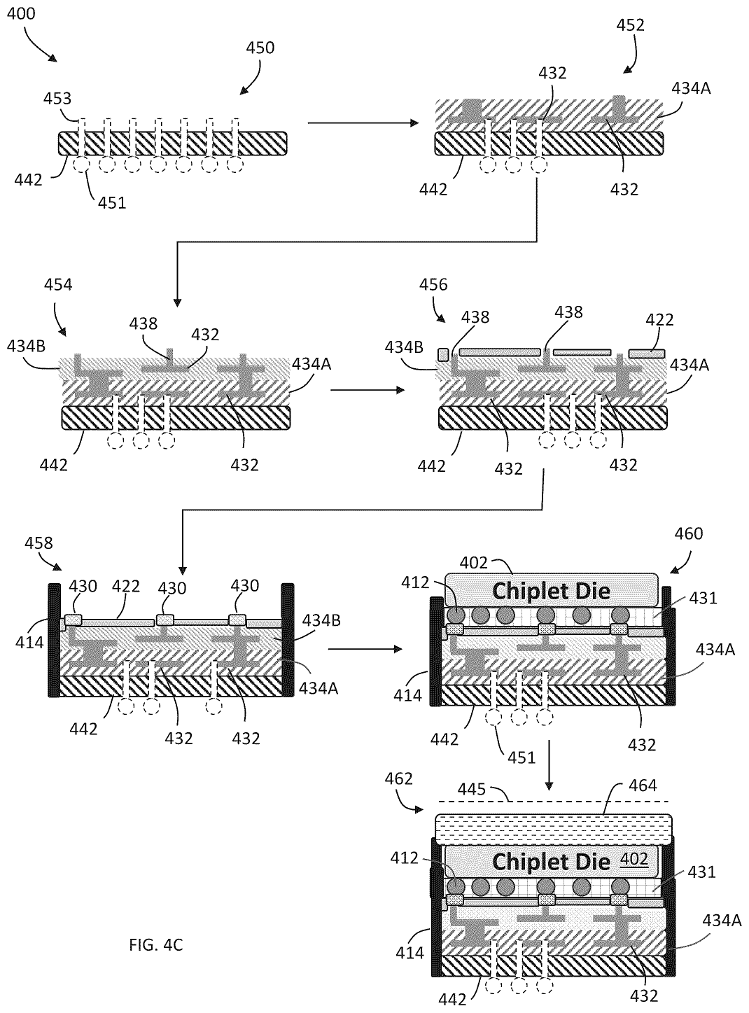

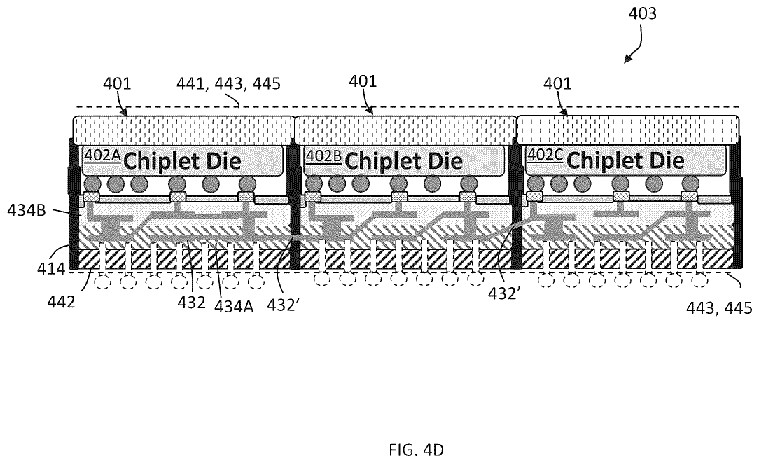

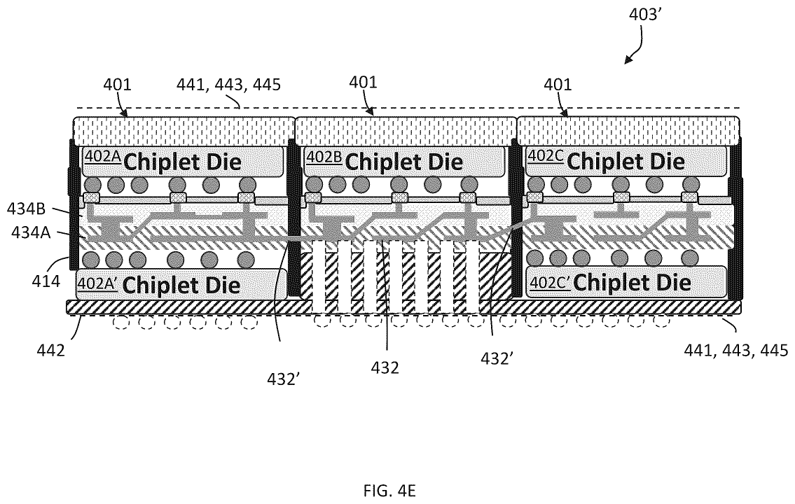

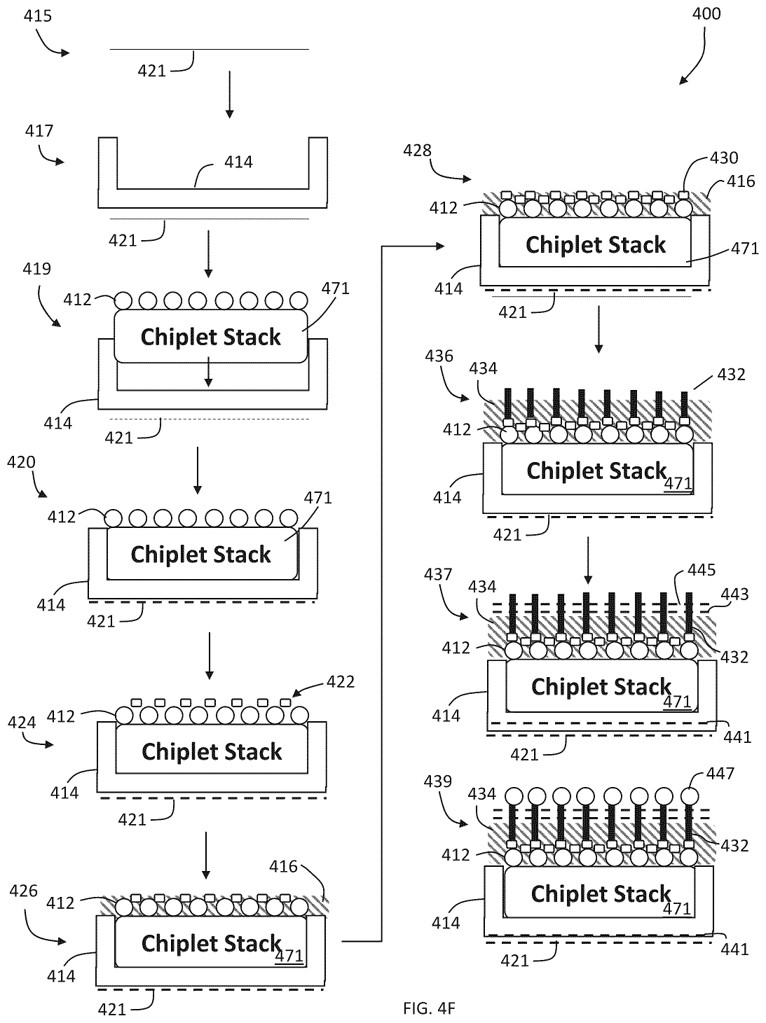

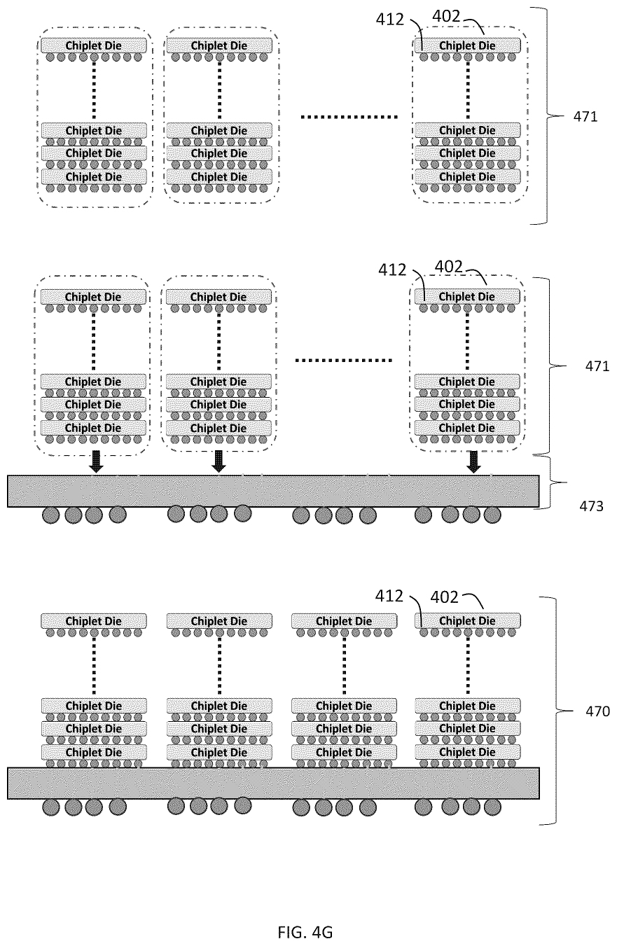

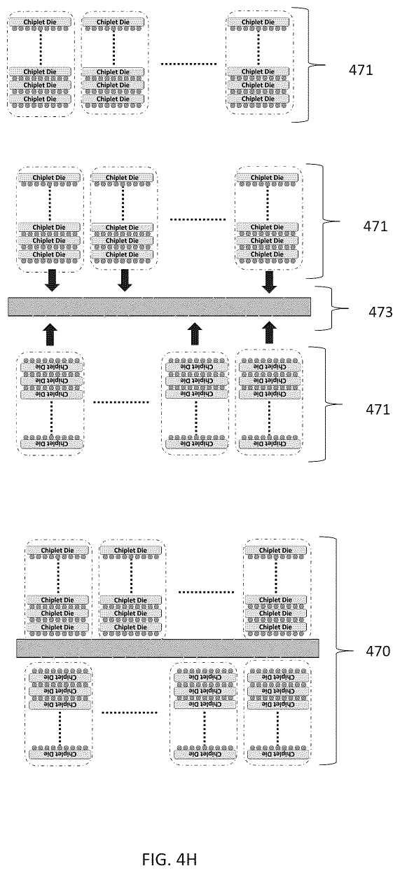

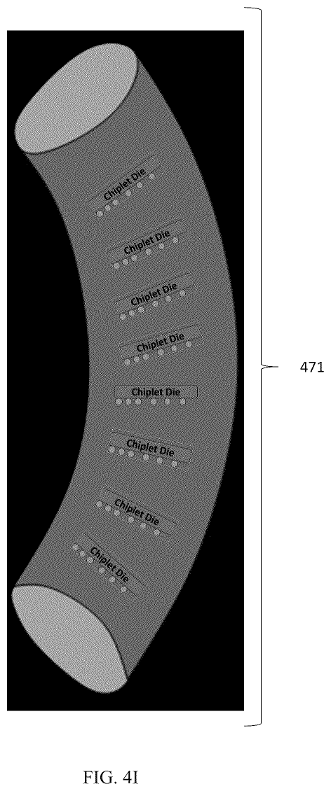

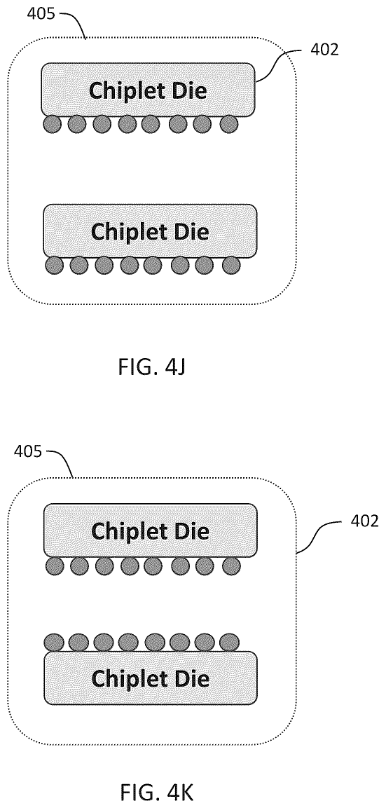

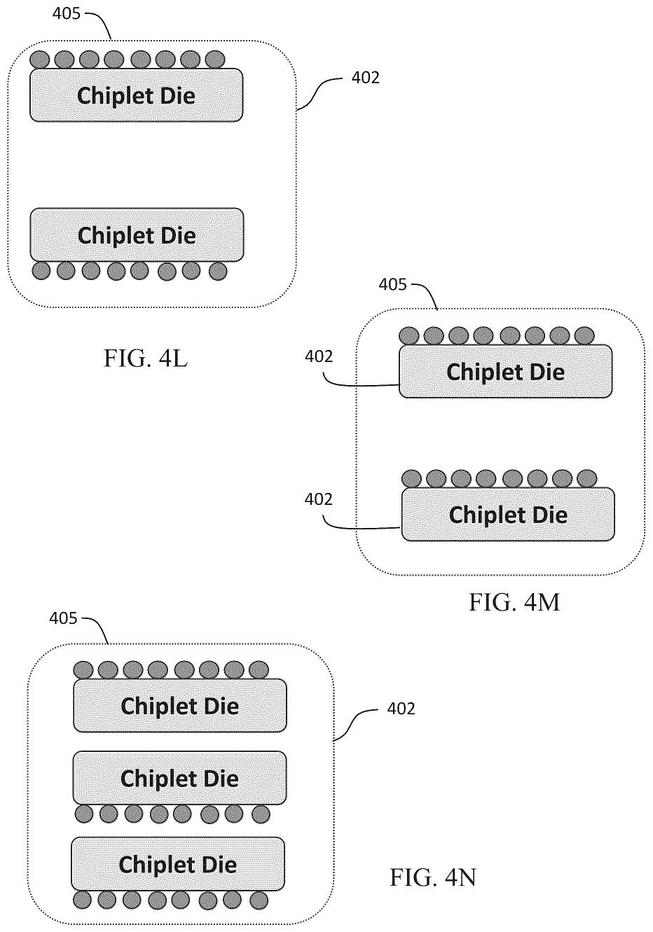

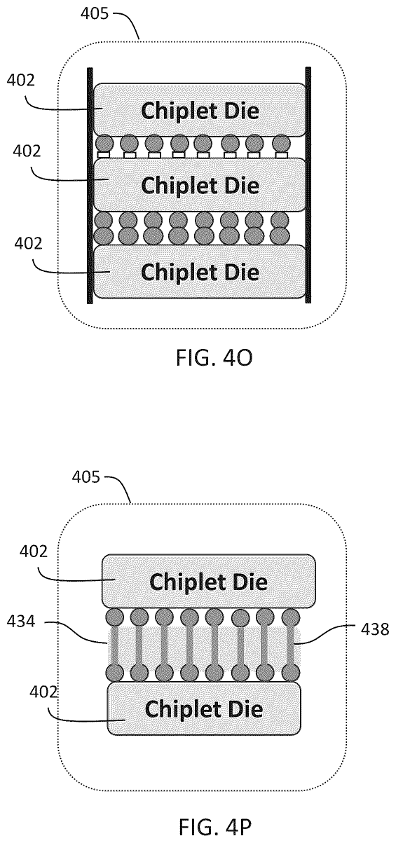

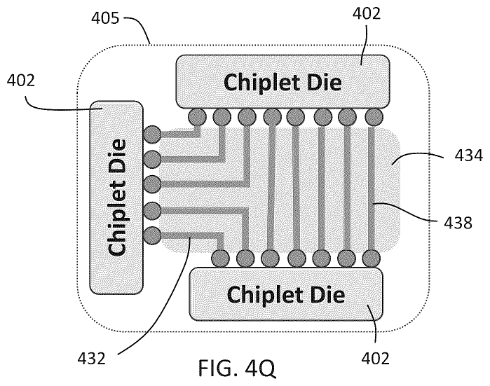

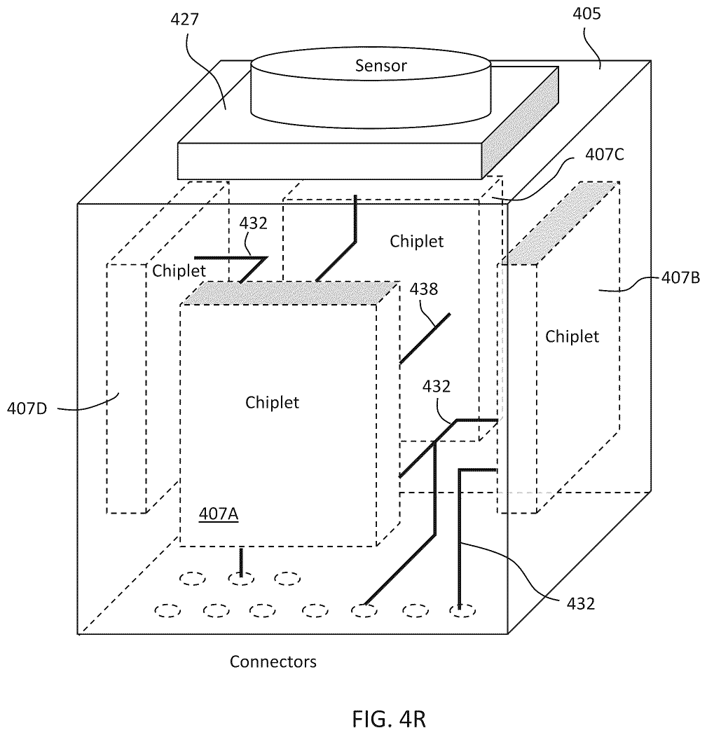

It should be appreciated that in one or more embodiments, the fabrication of the device 200, 300 may be facilitated using additive manufacturing system described by the aforementioned U.S. patent application Ser. No. 17/574,326. Referring now to FIG. 4A-4D, embodiments are illustrated showing examples of two different chiplet semiconductor packaging fabrication process flows. It should be appreciated that the embodiments of FIG. 4A-4D are illustrative and not intended to be limiting.

In an embodiment, the fabrication process 400 may begin depositing 415 a layer, such as an base layer 421. It should be appreciated that in more complex embodiments, the layer or layers 421 may comprise one or more of a VDL, a shield layer, a thermal layer, or an encapsulation layer for example. In an embodiment, the layer 421 is the chiplet mounting plane of a VDL. The process 400 then proceeds to step 417 where a frame 414 is fabricated. The frame 414 may be made from the same or different material than the layer 421. The frame 414 includes a well area that is sized to receive a chiplet die 402. In some embodiments, the fabrication process 400 as discussed herein may utilize chiplet stacks 471 in place of the single chiplet die 402 (shown in FIG. 4F). The frame 414 may receive or one or chiplet dies 402 that are stacked vertically forming a chiplet stack 471. The individual chiplet dies 402 within each chiplet stack 471 may be bonded together utilizing various methods, for example hybrid bonding techniques or other die-to-die bonding methods. In another embodiment, the chiplet stack 471 may be prefabricated as a sub-assembly unit and processed as such. In another embodiment, frame 414 includes a well area that accepts other electronic components including non-chiplet passive and active devices including photonic devices and I/O connectors.

The method 400 then proceeds to step 419 where a chiplet die 402 is inserted into a frame 414. It should be appreciated that in other embodiments, the chiplet die 402 may be placed into a prefabricated frame 414 or the frame may be additively fabricated directly on the layer 421 as shown. In some embodiments, a thermal layer or a shielding layer may be deposited in the frame 414 before the chiplet die 402 is inserted into the frame 414. The chiplet die 402 is coupled to the frame in step 420. In an embodiment, an adhesive or other fastening medium may be sprayed on the frame 414 prior to insertion of the chiplet die.

It should be appreciated that while the illustrated embodiment of FIG. 4A shows the chiplet die 402 is mounted in a horizontal orientation, this is for example purposes and the claims should not be so limited. Further, the process 400 of FIG. 4A is an example of a “bottom-up” fabrication method, however, as shown in FIG. 4C, other fabrication methods may be used. As used herein, a “top-down” or a “bottom-up” fabrication method may be based on a chiplet point of view, or a package point of view related to the direction in which the additive manufacturing materials are deposited.

Further, it should be appreciated that the use of terms herein such as top, bottom, side, upper, lower, above or below are for convenience and example purposes and not intended to define an in-operation orientation. The AME devices disclosed herein may be three dimensional in nature and may be fabricated a plurality of “sides” or with no definitive side, top, or bottom for example.

The process 400 then proceeds to deposit a dielectric layer/mask 422 in step 424 onto, over, or about the chiplet connections 412 while not contacting the chiplet bonding pad locations 412. The process 400 then proceeds to deposit in step 426 a VDL layer 416 onto, over, or about the chiplet connections 412 or dielectric layer/mask 422. It should be appreciated that the VDL layer 416 may include apertures, through printed vias, or spatial interconnections facilitating one or more bonding contact points for conductive circuits for chiplet die-to-die, die-to-die chiplet stack, or die-to-component, or die-to-I/O interconnections. In an embodiment, no dielectric material is applied, and direct conductive circuitry is formed by proceeding directly to step 428

In an embodiment, the process 400 then proceeds to deposit in step 428 a conductive material, such as conductive material (e.g. ink, or paste) for example, into the apertures or through-printed-vias, or directly to each die pad, to form electrically conductive interconnections 430 with the chiplet I/O connections 412. It should be appreciated that while FIG. 4A illustrates the interconnections 430 as being perpendicular to the chiplet plane, this is for example purposes and the claims should not be so limited. The process 400 then proceeds to deposit in step 436 or print additional conductive interconnects into the through-printed vias. It should be appreciated that in some embodiments, additional layers, such as a VDL layer 434 (step 436), or optional thermal layers 441, shielding layers 443, ground planes, power planes, or an encapsulation layer 445 (step 437) may also be deposited therein.

In some embodiments, the shielding layers 443 may be deposited on any one or more sides of the semiconductor packaging and may function as a full or partial faraday cage/shield to prevent interference signals. In some embodiments, optional thermal layers 441 may be deposited near the chiplet die 402, for example embedded in or adjacent to the frame 414 or other similar structure. In some embodiments, these optional layers may be deposited prior to the insertion of the chiplet die 402, for example during steps 417, 419. In some embodiments, one or more of the thermal layers 441, shielding layers 443, and encapsulating layers 445 may be integrated with frame 414 or each other. For example, the shielding layer 443 may function as the encapsulating layer 445 or the thermal layer 441 may be made of material that blocks interference signals. The optional shielding volume layer may be desired with electromagnetic reduction/protection is desired for the underlying heterogeneous integrated packaging. The operational thermal volume layer may be used if heat dissipation is specified for chiplet operation. The thermal volume layer may comprise multiple structure layers and/or functionalities as described herein.

In other embodiments the process 400 for conductive and insulating/dielectric materials may be fabricated utilizing VAM methods that include simultaneous synthesis of materials, wherein one or more material regions are selectively defined and fabricated in a controlled fashion to produce conductor or dielectric/insulating regions on a voxel by voxel basis.

In some embodiments the process 400 for fabrication of structural regions of the substrate and/or package, including non-conductive elements, may be fabricated utilizing VAM methods and overprint capability. For example, VAM overprinting may be utilized to synthesize substrate and/or package structures around previously fabricated structures that include conductors, insulators, VDL, VIB, interposer and RDL structures, chiplets, chiplet stacks, power and ground networks, and other device components including photonic circuits and devices, as well as I/O connectors.

In the embodiment of FIG. 4A, the process 400 ends with completion of the package structure, followed by the depositing and electrically coupling connectors 447, such as solder balls, bumps, leads, or pillars for example, to the interconnections 432 in step 439. In an embodiment, the connectors 447 are deposited after the encapsulation layer 445 as shown. However, in other embodiments, the connectors 447 are deposited prior to the fabrication of the encapsulation layer 445 and the encapsulation layer is deposited around the connectors 447 in step 439. In other embodiments the final package coupling connectors 447 are added to complete the package I/O through an external systems also referred to as bumping machines as one non-limiting example. In other embodiments other types of I/O interfaces or connectors may be desired and the appropriate external system for the selected I/O interface is utilized.

Referring now to FIG. 4B, an embodiment is shown illustrating how the process 400 of FIG. 4A may be expanded to define an interconnected multi-chiplet semiconductor package or device 401. In this embodiment, a frame 414 is additively fabricated with an integral thermal and/or shielding layer disposed (additively fabricated or prefabricated and placed) if required, followed by one or more locations for a plurality of chiplet mounting members or chiplet dies 402. Once the chiplet dies 402 are disposed in the frame 414, the first VDL 416 is deposited, followed by the dielectric layer/mask 422 and a connective interconnection 430 in the same manner as described above. In this embodiment, the interconnections 432 may be extended and themselves interconnected by depositing additional conductive material (e.g. conductive epoxy, ink, paste) within the VDL 434A. Further VDL layers 434B, 434C may be deposited over the first VDL 434A with a predetermined configuration of apertures and through-printed-vias, such as through-printed-via 438 for example. In some embodiments, additional layers (e.g. for encapsulation, structural layers in support of I/O or connector interfaces) may be included. Further, in some embodiments, the layers may be combined together, such as where a conductive material is sprayed on a layer surface. The through-printed via's 438 may include an electrical connection/interfaces 440. In an embodiment, the frame 414, chiplet dies 402, and VDL's 416, 434A, 434B, 434C may be disposed within a housing 442. In an embodiment, the housing 442 is integrally formed with the frame 414, chiplet dies 402, and VDL's 416, 434A, 434B, 434C using additive manufacturing.

In an embodiment, the device 401 may include one or more shielding layers 443 or encapsulating layers 445 deposited adjacent to the VDL 434C. In an embodiment, the device 401 may include one or more thermal layers 441 or shielding layers 443 embedded in or adjacent to the housing 442. In some embodiments, the thermal layers 441 or shield layers 443 may be between the chiplet die 402 and the frame 414, embedded in the frame 414, or between the frame 414 and the housing 442. The thermal layer 441 may be positioned near the chiplet die 402 to regulate the temperature of the chiplet die 402. It should be appreciated that other layers are contemplated as described herein, such as a power plane or a grounding layer for example. It should be further appreciated that the number and order of layers may differ depending on the desired semiconductor device requirements.

The method of fabricating a device, such as device 401 may be include additional steps compared to that shown in FIG. 4A. Referring now to FIG. 4C, an embodiment is shown of a “bottom-up” method of making a device 401. As used herein a “bottom-up” method may be from the point of view of the chiplet. In the embodiment of FIG. 4C, some of the layers, such the layers 442, 434A, 422 and connections such as interconnections 432 for example, are deposited prior to the insertion of the chiplet die. In this embodiment, the process 400 starts in step 450 with fabricating (e.g. depositing) a housing layer 442. In an embodiment, the layer 442 may also be an I/O connection layer that includes one or more connectors 451 and interconnects 453 that are fabricated with or prior to the layer 442. In an embodiment, the structure in step 450 may be prefabricated an integrated assembly. In another embodiment the one or more connectors 451 shown are not fabricated during step 450 and this process is completed during or after step 462 in a similar manner as previously described. As mentioned previously, this layer may be planar (as illustrated) or have a three-dimensional shape. The process 400 then proceeds to step 452 where the VDL 434A is fabricated on the housing 442. Within the VDL 434A and integrated with the VDL 434A are any interconnections 432 for transferring signals or power to or between the electrical components of the device 401. The first VDL 434A may also include TPV's 438. In an embodiment, the TPV's 438 are formed simultaneously with the first VDL 434A. In other embodiments, the TPV's 438 are formed as holes that a subsequently filled (e.g. with an electrically conductive material) once the VDL 434A is formed.

The process 400 then proceeds to step 454 where a second VDL 434B is fabricated with additional interconnections 432 and TPV's 438. It should be appreciated that step 454 may be performed multiple times to achieve the desired shape, interconnection and/or circuit. The process 400 then proceeds to step 456 where a dielectric/mask layer 422 is fabricated over the VDL 434B. It should be appreciated that the interconnections 432 or TPV's 438 remain exposed.

The process 400 then proceeds to step 458 where electrical connections 430 are fabricated/deposited onto the interconnections 432 and/or TPV 438. In some embodiments, the frame 414 may also be fabricated during steps 450-458. The process 400 then proceeds to step 460 where the chiplet connections 412 and chiplet die 402 are coupled to the electrical connections 430. In an embodiment, the chiplet connections 412 and chiplet die 402 are assembled onto the electrical connections 430, such as using a pick-and-place device for example followed by one more die pad bonding methods described herein. In an embodiment, an under-fill material 431 is injected, dispersed, or flowed under the chiplet die 402 to provide thermal and mechanical stress relief for the chiplet connections after they are completed. The underfill material is deposited in the open space around the chiplet I/O connections. It should be appreciated that while the under-fill material is only shown in FIG. 4C, this is for clarity purposes and any of the embodiments disclosed herein may include an under-fill material to assist in supporting the chiplet connections as well as other components within the package assembly.

Finally, process 400 proceeds to optional step 462 where a shielding or thermal layer 464 is fabricated over the chiplet die 402. In an embodiment, an encapsulation layer 445 is deposited adjacent to the layer 464. In an embodiment, the frame 414 provides an interface to the thermal volume layer, a stabilizing structure to maintain the chiplet position, and the chiplet mounting member.

In an embodiment, shown in FIG. 4D, the process 400 of FIG. 4C may be combined to fabricate a device 403 circuit or circuits having a plurality of chiplet dies 402A-402C where interconnections 432′ in the VDL layers 434A, 434B allow for transmission of signals and/or electrical power and/or ground. In an embodiment, the individual devices 401 are batch fabricated in a separate process and assembled together to form the device 403. In an embodiment, one or more layers such as thermal layer 441, shield layer 443, and/or encapsulation layer 445 may be deposited or embedded in one or more sides of the devices 401.

In an embodiment, shown in FIG. 4E, the process of FIG. 4C may be combined to fabricate a device 403′ circuit or circuits similar to the device 403, for the sake of brevity the differences between the device 403′ and the device 403 are discussed with respect to FIG. 4E. In some embodiments, one or more of the individual devices 401 of the device 403′ may include a chiplet die 402A′, 402C′ opposing the chiplet die 402A, 402C respectively. The device 403, 403′ may include any number of individual devices 401, the individual devices 401 may include an opposing chiplet die 402A′, 402C′ as desired. In some embodiments, the thermal layer 441 adjacent to the chiplet die 402A′, 402C′ may include thermal vias directed to the thermal layer 441 adjacent the chiplet die 402A, 402B, 402C or vice versa, in this way the thermal layers 441 may direct heat to a desired location, for example a heat sink.

Referring now to FIG. 4G-4I, shown is a heterogeneous integrated advanced package 470 according to some embodiments. In some embodiments, the heterogeneous integrated advanced package 470 may include chiplet stacks 471 and other complex arrangements where the individual chiplet dies 402 are mounted or assembled/bonded on top of one another. In some embodiments the chiplet dies 402 are stacked in a relative Z direction as a linear array to form the chiplet stack 471 to increase chiplet density. In some embodiments the chiplet dies 402 may be stacked linearly or in any shaped chiplet stack 471 (shown in FIG. 4I). The shape and configuration of the chiplet stack 471 may depend on the integrated circuit application and manufacturing method used, for example, AM and VAM methods. In another embodiment, the chiplet stack may be prefabricated and implemented at the semiconductor wafer level, and preprocessed externally into a chiplet stack assembly 471 for direct additive manufacturing use in accordance to the methods described herein and as illustrated in FIG. 4G-4I.

In some embodiments, the chiplet stacks 471 may be connected to a substrate and multi-chiplet stack interconnection network 473 to form the heterogeneous integrated advanced package 470. The substrate and multi-chiplet stack interconnection network 471 may be an interposer, RDL, or VDL, combinations thereof, along with other components that are integrated and fabricated using additive manufacturing methods discussed herein. In some embodiments, the chiplet stacks 471 may be connected to the substrate and multi-chiplet stack interconnection network 473 using known semiconductor attachment, bonding and assembly methods or using additive manufacturing methods discussed herein.

In some embodiments, chiplet stacks 471 may be attached to more than one side of the substrate and multi-chiplet stack interconnection network 473 (shown in FIG. 4G). The substrate and multi-chiplet stack interconnection network 473 may be planar or non-planar and the chiplet stacks 471 may be arranged on any one or more geometries of the substrate and multi-chiplet stack interconnection network 473. In some embodiments, the heterogeneous integrated advanced package 470 may be arranged in an array in the X-Y direction to form a larger heterogeneous integrated advanced package.

In some embodiments, where the complexity or density of the 3D heterogenous integrated package is highly complex, such as the case of implementing one or more chiplet stacks with a maximum die-to-die pad adjacent spacing of 1 um or less, the processes described herein may utilize 2.5D and 3D processing models in combination. In this embodiment, 2.5D processing models are employed by additive manufacturing, where two or more chiplet dies are placed side-by-side on an interposer, RDL, or VDL to achieve high die-to-die interconnect density in a horizontal direction. In this embodiment, 3D processing models are then utilized in the vertical direction, where chiplet dies are integrated by die stacking methods (such as wafer scale or other high-resolution fabrication processes) for shorter interconnect dimensions and smaller package footprint.

As such, in this embodiment a complex or dense 3D heterogeneous integrated package may be broken up into smaller 3D sub-assemblies that are interconnected using a 2.5D processing model using AM and VAM methods. In some embodiments, the 3D sub-assemblies may be pre-fabricated and treated as single component by a 2.5D processing method. In this way, a complex or dense 3D heterogeneous integrated package which normally would be difficult to manufacture may be manufactured using pre-fabricated 3D sub-assemblies representing one or more subsets of the 3D heterogeneous integrated package components. This may be desirable as 2.5D and 3D manufacturing methods may each be advantageous for different steps in the 3D heterogeneous integrated package manufacturing process.

It should be appreciated that for each of the embodiments described herein, each of the devices may also include a VDL having a frame that holds active or passive electrical devices (e.g. resistors, capacitors and the like) that are embedded or integrated into the VDL. These active or passive electrical devices may be used for power or signal conditioning, or inter-chiplet communications for example.

In some embodiments, such as when more complex semiconductor packages and heterogeneous device integrations are being fabricated, it may be advantageous to define the semiconductor device in terms of one or more 3D volumes or 3D volumetric meshes that contain zero, one, or more than one chiplet dies and other devices. As used herein, these 3D volumes are referred to as a “chiplet voxel.” The chiplet voxel may be an arbitrary 3D volume space, a plurality of uniform 3D volume spaces, or a plurality of non-uniform (variable) 3D volume spaces. Each chiplet voxel may contain one or more VDL/VIB's associations or one or more chiplets, active electrical devices or passive electrical devices. In an embodiment, the VDL and VIBs in one chiplet voxel may overlap with one or more adjacent chiplet voxel(s) in 3D space.

In an embodiment, chiplet voxels follow the same internal layer structure and ordering as the base case described previously. In an embodiment, a chiplet voxel may not contain a chiplet die, or other active/passive electrical devices and may only contain VDL and or VIB's if associated to another chiplet voxel in 3D space. In embodiments, similar to the embodiments shown and described herein above, the spatial interconnections within the VDL or VIB may be straight or curved paths whose path or route travels in 3D space

Chiplet voxels may also contain connections pads or bumps that enable the package to attach to external circuits (such as PCBs) or other assemblies. Chiplet voxels may be arranged in 3D dimensions enabling complex 3D chiplet structures, in arbitrary 3D space. Chiplet voxels containing no features (e.g. no chiplets or VDL/VIB's) may be referred to as null chiplet voxels and serve as only structural 3D spatial regions.

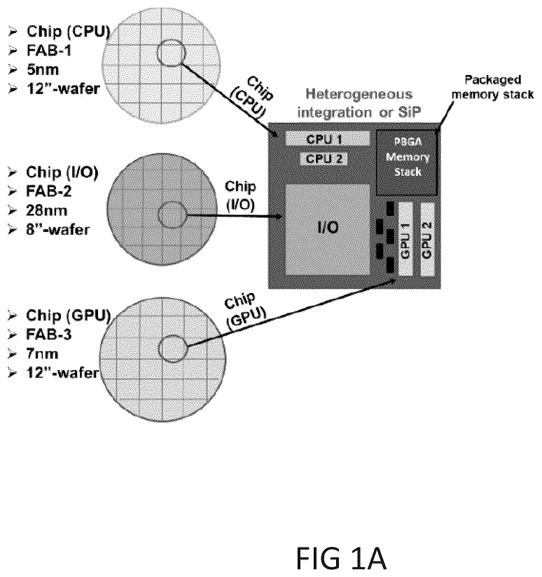

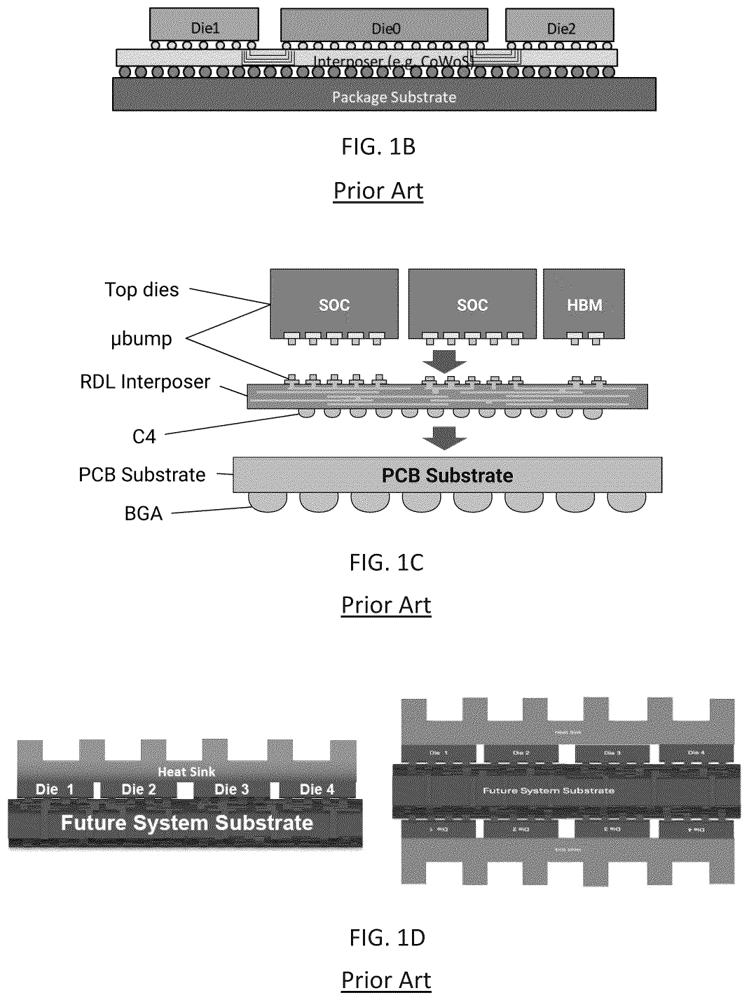

It should be appreciated that any prior-art planar or 2.5 dimension or planar-3D semiconductor package or heterogeneous integrated chiplet solution (SiP/SoP, CoWoP, etc) packaging technologies (e.g. FIG. 1A-1D) can be emulated or implemented using the additive manufacturing chiplet voxel fabrication methods and structure described herein.

As discussed herein, the AME device may be defined by one or more chiplet voxels. The chiplet voxel is the arrangement of one or more chiplet dies 402 and related attached circuit interconnections, power networks, ground networks and compounds within a particular semiconductor packaging. These chiplet voxels may have a single chiplet die as illustrated in FIG. 4A for example. In other embodiments there may be multiple chiplet dies 402 per chiplet voxel 405 as illustrated in FIG. 4J-4P. In some embodiments, additional chiplet dies 402 may be added to an pre-existing chiplet voxel 405 using one or more AME or VAM processes. In some embodiments, one or more of the chiplet dies 402 in the chiplet voxel 405 may be replaced by a chiplet stack 471.

It should be appreciated that the illustrations of FIGS. 4J-4P are for example purposes and the claims should not be so limited. In other embodiments, the chiplet dies 402 may be arranged on angles relative to each other including along three-dimensional planes. The various chiplet voxels 405 may be formed from multiple chiplet dies 402 stacked for heterogeneous 3D integration utilizing integration methods including, but not limited to, an interposer, RDL, flip chip bonding, a VDL/VIB/TPV, pillar based attachment, photonic interconnections, or hybrid bonding methods in conjunction with additive manufactured processes.

In one embodiment that variety of orientations illustrated in FIGS. 4J-4P allow for multiple chiplet dies to stack in a given direction relative to one another for further increase in packing density. In this method, chiplets die pads are bonded directly to one another, or alternatively bonded utilizing a VDL and through-printed via (TPV).

The chiplet voxel 405 may include chiplet dies 402 that are oriented in the same direction (FIG. 4JE, FIG. 4M), chiplet dies 402 that are oriented with the connector or pad sides facing each other (FIG. 4K), and chiplet dies 402 that are oriented with the connector or pad sides facing opposite directions other (FIG. 4L). The chiplet voxel 405 may further have more than two chiplet dies 402 with the chiplet connectors or pads not being aligned (FIG. 4N), or with more than two chiplet dies 402 where two of the chiplet dies 402 are directly coupled to each other (FIG. 4O). The chiplet voxel 405 shown in FIG. 4O may be formed using an additive based method for hybrid bonding. In still further embodiments, there may be a volume distribution layer 434 disposed between the chiplet dies 402 that includes interconnects or through printed vias 438 that electrically connect the chiplet dies 402 (FIG. 4P). The chiplet voxel 405 shown in FIG. 4P may be formed using a VDL/VIB/TPV approach.

In further embodiments, the chiplet voxel 405 may have multiple chiplet dies 402 that are not all arranged in parallel but rather have at least one chiplet die that is arranged on a non-zero angle relative to at least one other chiplet die (FIG. 4Q). The chiplet voxel 405 shown in FIG. 4Q may be formed using a VDL/VIB/TPV approach. In this embodiment, a volume distribution layer 434 includes interconnects 432 and TPV. An embodiment similar to FIG. 4Q in three-dimensions is shown in FIG. 4R. In this embodiment, the chiplet voxel 405 is a cuboid or parallelepiped shape. It should be appreciated that this is for exemplary purposes only and the chiplet voxel may have other shapes. In this embodiment, four chiplets 407A, 407B, 407C, 407D are arranged adjacent four of the sides of the chiplet voxel. These chiplets are connected by interconnections 432 and TPV 438. It should be appreciated that a volume distribution layer (not shown for clarity) may be disposed between the chiplets 407A, 407B, 407C, 472D. Disposed on one side the chiplet voxel 405 is a sensor 427 that is coupled to one or more of the chiplets 407A, 407B, 407C, 407D. On an opposite side of the chiplet voxel from the sensor 427 is a connection plane having a plurality of connections that allow the chiplet voxel 405 to be electrically coupled to another chiplet voxel, device or component.

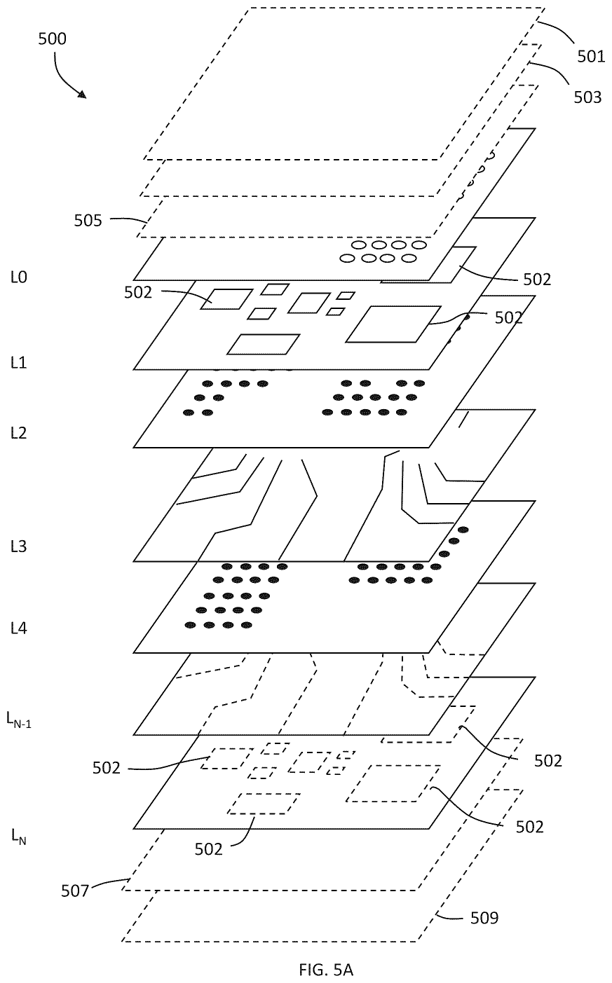

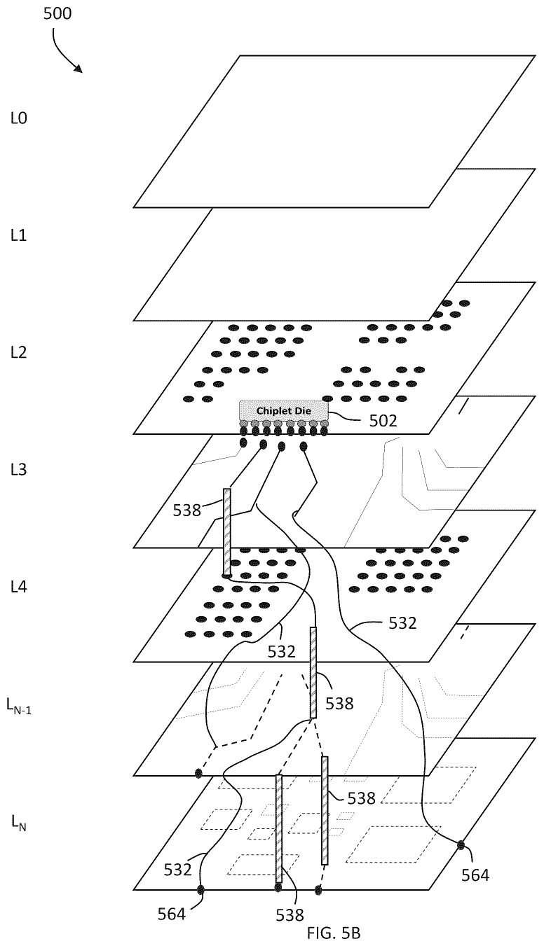

Referring now to FIG. 5A an embodiment is shown of a device 500 having a plurality of additively manufactured layers that are integrally (or substantially integrally) formed together. It should be appreciated that the device 500 may be any number of layers “N” that define a desired semiconductor packaging arrangement. The layers may include multiple layers forming a chiplet voxel and having chiplet dies 502 frames, such as layer L₁ and layer L_{N} for example. The device 500 may further include dielectric layers L₂, L₄ and conductive interconnection circuit layers L₃, L_{N-1}. In an embodiment, the Layer L₀ may be a dielectric layer, a shielding layer 501, a thermal layer 503 or a package outer layer (e.g. a lid 505) for example. Still further layers may include an opposing-side/bottom frame/layer 507 and/or a bottom layer I/O 509. Further, each layer can vary in shape, geometry, or thickness for example.

It should be appreciated that in the stacking of multiple chiplet dies, the chiplet planes can be oriented in all orientations relative to one another. In some embodiments, the chiplet planes may not be parallel to each other. In other words, the chiplet planes may be horizontally stacked, vertically stacked, or at any angle relative to one another (from the viewpoint of the Figures), or in combinations and any multi-arrangements or angles and ordering with vary degrees of distance or space relative to one another in 3D space.

Referring now to FIG. 5B, another embodiment is shown of the device 500. As in the embodiment of FIG. 5A, any number of layers “N” may be defined to fabricate the desired circuit. In this embodiment, the device 500 includes a shielding layer L₀ and a thermal layer L₁. One or more chiplets 502 are fabricated on layer L₂. Adjacent the layer L₂ a VDL layer L₃ provides TPV's 538 and spatial interconnects 532 that define an electrical path or circuit to connect the chiplet layer L₂ with a substrate or base layer L_{N}. It should be appreciated that there may be any number of layers L₄-L_{N-1} between the chiplet layer L₂ and the base layer L_{N}. The base layer L_{N} further provides connections 564 that allow signals and/or power to between transferred between the device 500 and external circuits. It should be appreciated that while the embodiment of FIG. 5B illustrates the connections 564 as being on the edge of the base layer L_{N}, this is for example purposes and the claims should not be so limited.

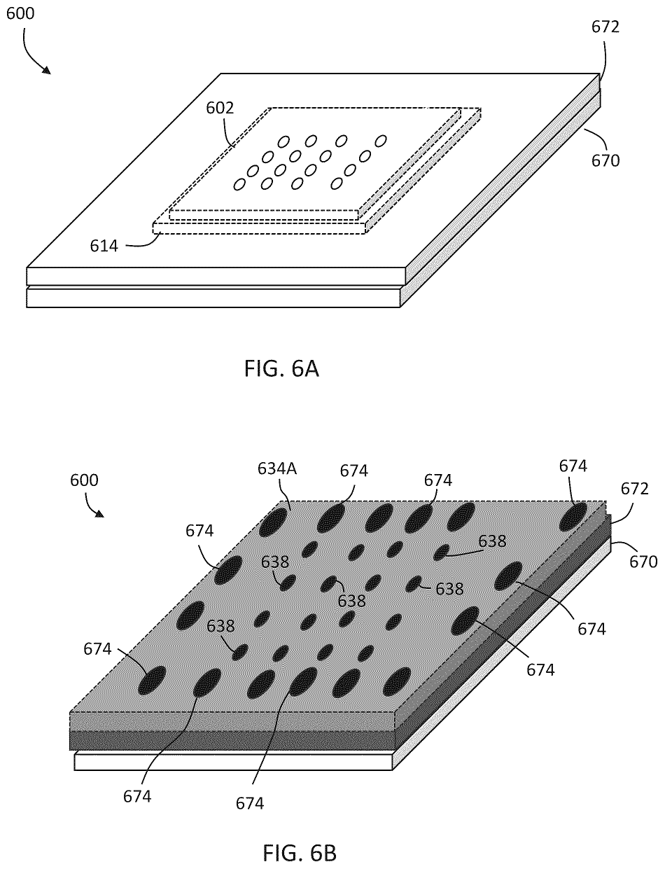

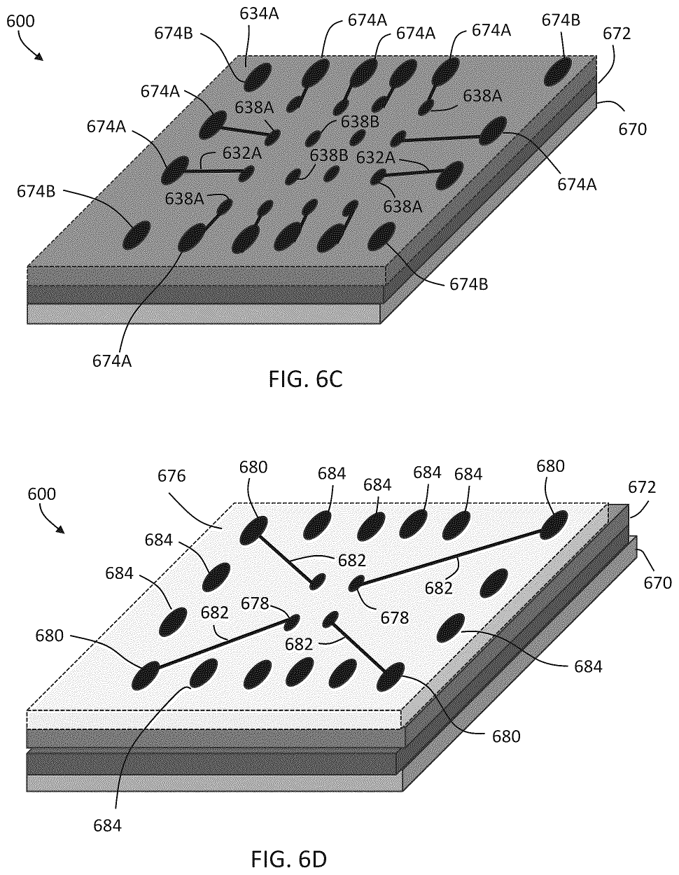

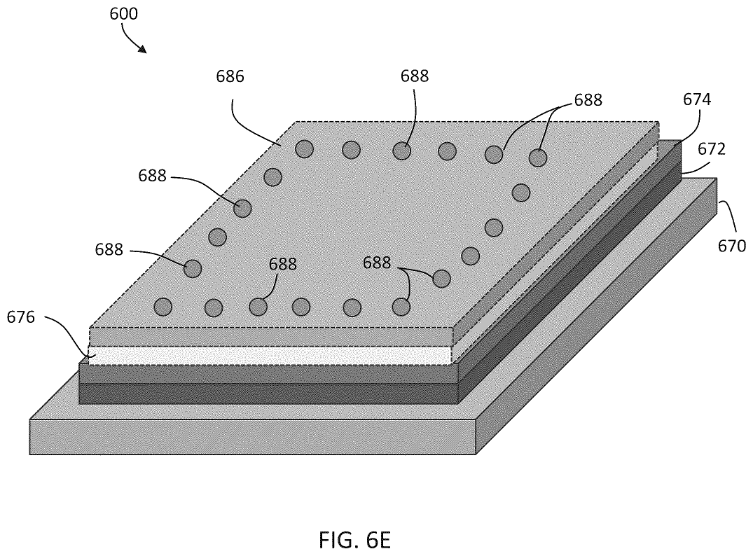

It should be appreciated the methods and structures of the semiconductor packaging described herein may provide advantages in a number of applications, such as but not limited to the fabrication of a package implemented fan-out interposer 600 as shown in FIG. 6A-6E. First layer 670 and layer 672 are fabricated. These may be substrates that form shield/thermal/encapsulation/lid layers and outer package encapsulation layers for example. A chiplet frame 614 (e.g. a die pocket) is fabricated on the layer 672 and a chiplet die 602 is placed therein (e.g. a pick and place of a flip chip die). In an embodiment, an adhesive is placed within the frame 614 prior to placing the chiplet die 602. The chiplet die 602 has a plurality of contacts 612 (die pads or bonding sites) arranged in an array. It should be appreciated that the contacts 612 have relatively close spacing and may have a higher density than the circuits, semiconductors, or electrical devices that the chiplet is connected to. In these situations, it may be desired to fan-out the electrical connections of the chiplet to allow for desired interconnections of I/O on the opposing package side of a completed semiconductor package having a lower density of connections for PCB mounting.

It should be further appreciated that the number of contacts 612 illustrated in FIG. 6A is for example purposes and the actual chiplet die may have more or fewer contacts, or in different configuration patterns.

It should be appreciated that during the fabrication process fiducials may be fabricated and utilized at each step to allow for a desired level of precision in the alignment of chip dies, TPV/vias and aperture locations for example.

In the next step in the fabrication process, a VDL layer 634A is fabricated onto layer 672, frame 614 and chiplet die 602. In this embodiment, the VDL 634 may include a plurality of TPV's 638 that align with and electrically connect with the contacts 612. A plurality of conductive connections 674 are arranged about the periphery of the of the TPV's 638 as shown in FIG. 6B.

Next, as shown in FIG. 6C, conductive spatial interconnects 632A are made between perimeter TPV's 638A and a first set of connections 674A. It should be appreciated that this arrangement has the effect of fanning out the perimeter TPV's 638A. The remaining TPV's 638B located in the center of the layer remain unconnected to any connects 674B on this layer.

Next, as shown in FIG. 6D, another VDL layer 676 is fabricated in this layer, the center TPV's 638B connects with TPV's 678 that extend through the layer 676. The connections 674B connect with TPV's 680 that extend through the layer 676. Spatial interconnects 682 connect the TPV's 678 to the TPV's 680 to fan-out the center contacts to the perimeter of the layer 676. The connections 674A extend through the layer 676 via TPV's 684.

It should be appreciated that while the interconnects 632A, 682 are illustrated as being planar, this is for example and clarity purposes and the claims should not be so limited. In other embodiments, the interconnects 632A, 682 may have a three-dimensional shape. Further, the layers 670, 672, 676 may not be planar, but rather have a shape that may vary in three dimensions.

Finally, as shown in FIG. 6E, a VDL, I/O and final package substrate 686 is fabricated over VDL layer 676. The layer 676 may be fabricated using insulator/dielectric material, form conductive TPVs in conjunction with package material, fabricate I/O pads 688 and bumps over TPV apertures, bonding I/O pads/bumps to conductive interfaces.

It should be appreciated that the number of layers illustrated in FIG. 6A-6E are for example purposes only. The illustrated embodiment is an example of a single die, however additional chiplets may be accommodated without deviating from the teachings herein. In embodiments where the chiplet has more connections to be fanned-out, additional VDL layers may be utilized to accomplish the fan-out arrangement. It should be appreciated that in some embodiments, the fanning out of the connections starts on the periphery and progresses towards the center with each successive layer. It should further be appreciated that in embodiments having multiple chiplets, the last set of VDL layers may follow the same configuration if a pattern fan-out is desired.

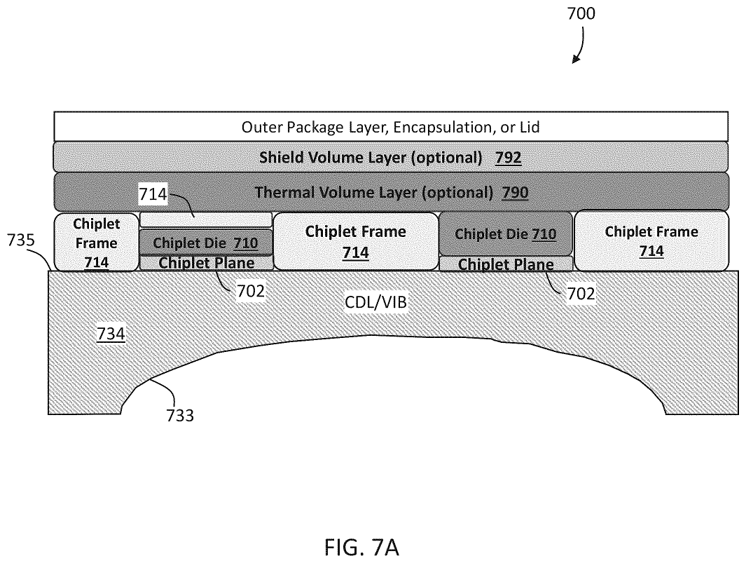

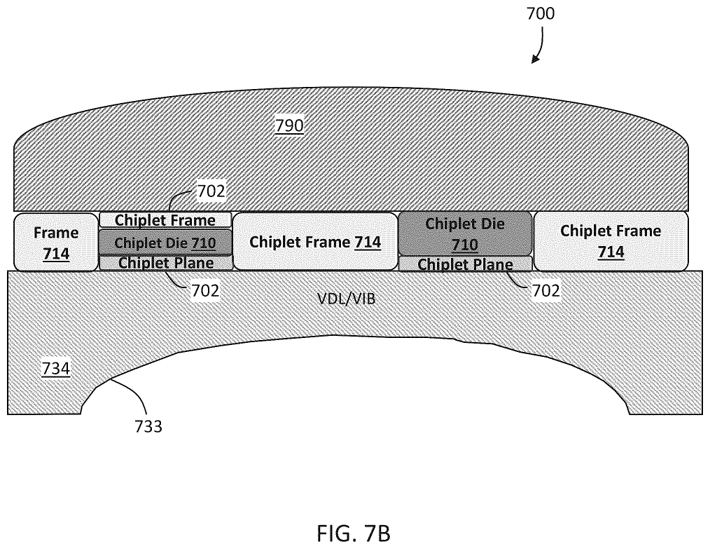

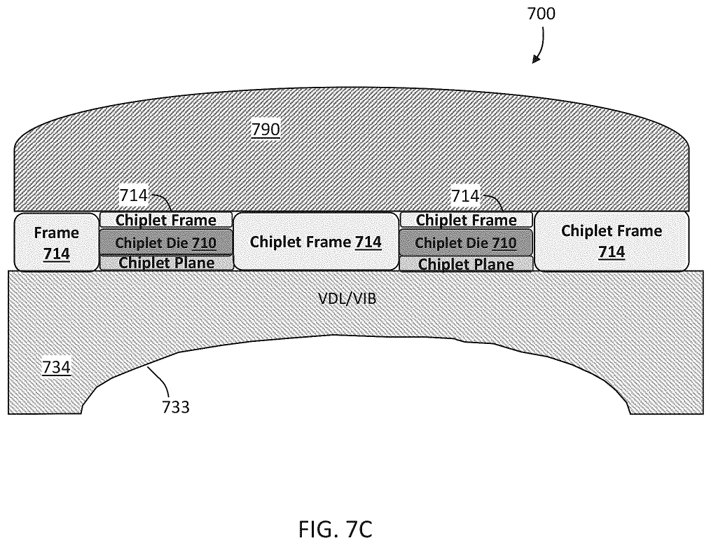

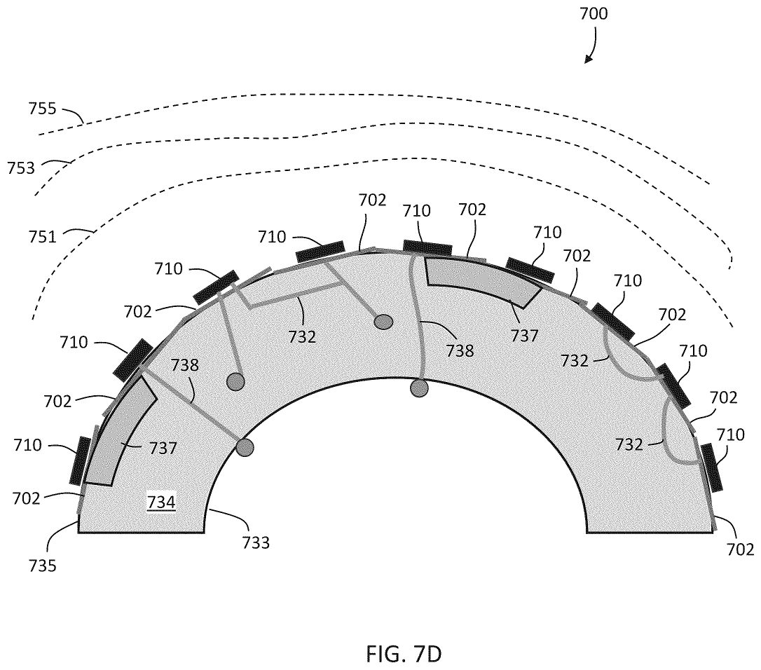

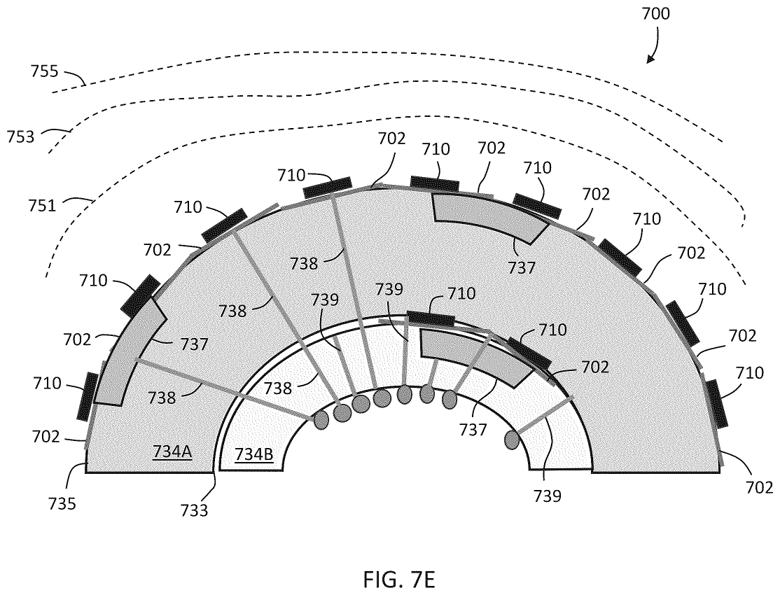

The embodiments illustrating the semiconductor packaging have shown the layers mainly in a planar configuration. As discussed previously, one advantage of the embodiments herein includes the ability to form the layers in multiple dimensions without being constrained to the sandwiched layer approach of the prior art. Referring now to FIG. 7A-7E embodiments are shown are cross-sections of devices having nonplanar or at least partially nonplanar structures.

The embodiment of FIG. 7A illustrates a device 700 having a VDL 734 with a curved surface 733 on one side and a planar or relatively planar opposing surface 735. Arranged on surface 735 are frames 714 and chiplet mounting members 702. The chiplet dies 710 are coupled to the chiplet mounting members 702. Optional thermal/shielding/lid volume layers 790, 792 are disposed oved the chiplet frames 714 and chiplet dies 710. In an embodiment, the encapsulation layer 745 may be disposed adjacent to the shield volume layer 792. In an embodiment, an additional chiplet frame 714 may be disposed between one or more of the chiplet dies 710.

Referring now to FIG. 7B, an embodiment is shown that is similar to FIG. 7A, except in this embodiment, the optional thermal/shielding/encapsulation/lid volume layer 790 has a curved upper surface that defines a nonplanar shape.

Referring now to FIG. 7C, an embodiment is shown that is similar to FIG. 7B, except in this embodiment, both of the chiplet dies 710 are separated from the thermal volume layer 790 by a frame 714.

Referring now to FIG. 7D, an embodiment is shown of a device 700 having a VDL 734 having a two curved surface 733, 735. Disposed on the curved surface 735 are chiplet mounting members 702 that adapt the curvature of surface 735 to the planar structure of the chiplet die 710. In an embodiment, each chiplet die 710 includes a chiplet mounting member 702. Further illustrated in FIG. 7D are volume interconnect bridges (VIB) 737. The VIB 737 allows for the interconnection of chiplets having different size or density of connections, such as to connect a chiplet with a C2 bump to a chiplet with a C4 bump. In some embodiments, the VIB's may be fabricated separately, such as with an additive manufacturing system having a higher resolution for example and placed in the VDL 732. This may provide advantages in reducing costs. The embodiment of FIG. 7D further illustrates TPV's 738 and spatial interconnects 732.

It should be appreciated that the device 700 of FIG. 7D may also include additional layers, such as a thermal volume layer 751, a shielding volume layer 753, a lid layer 755, or outer I/O layer for example.

Referring now to FIG. 7E, an embodiment is shown of a device 700 having a first VDL 734A within a first chiplet voxel and a second VDL 734B within a second chiplet voxel. The first chiplet-voxel/VDL 734A is constructed in a similar manner to FIG. 7D. The second VDL 734B is disposed adjacent to surface 733. This embodiment illustrates that the chiplet dies 710 or other active passive devices within a VDL layer may be disposed internally to the device 700, such as between the VDLs 734A, 734B. The TPV's 738 extends through the first VDL 734A and the second VDL 734B to allow an interconnection between components in or on the first VDL 734A with contacts on an opposing surface 741 of the second VDL 734B. Other TPV's 739 extend through only through the second VDL 734B. It should be appreciated that there may be TPV's or spatial interconnects (not shown) that electrically couple components, such as chiplet dies 710 or VIB's 737 in the first VDL 734A with components in the second VDL 734B and optional connects to other active or passive electrical components.

It should be appreciated that the device 700 of FIG. 7E may also include additional layers, such as a thermal volume layer or a shielding volume layer. As discussed in more detail herein, the embodiment of FIG. 7E may be an example of a multi-chiplet voxel arrangement.

An example of a single chiplet voxel device may include the embodiment of FIG. 7D where the VDL 734 defines the three-dimensional space of the chiplet voxel. Another example of a multi-chiplet-voxel device includes the embodiment of FIG. 7E where the VDL 734A defines a first three-dimensional space and the VDL 734B defines a second three-dimensional space.

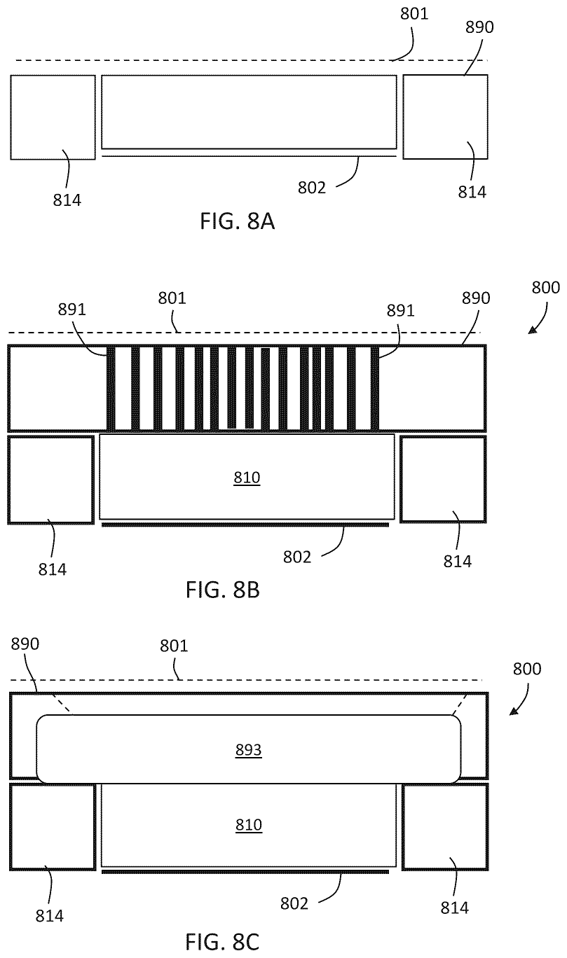

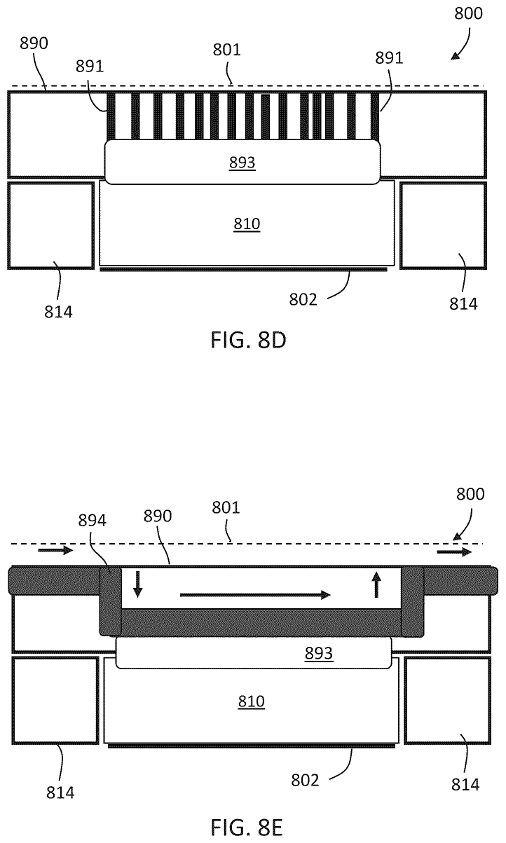

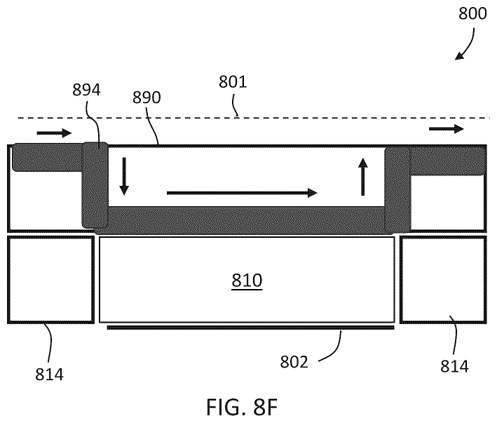

Referring now to FIG. 8A, an embodiment is shown of a device 800 having a chiplet die 810 on a chiplet mounting member 802. As discussed herein, the chiplet mounting member may be a planar region within a VDL that is sized to receive the chiplet die 810. The VDL (not shown) may be any desired shape as described herein. A frame 814 is disposed about the chiplet die 810. It should be appreciated that it may be desired to operate the chiplet or the circuit in general within predetermined thermal limits, such as for performance or reliability for example. In the embodiment of FIG. 8A, an outer packaging layer or encapsulation layer 801 may be disposed adjacent to the chiplet die 810. In this embodiment, the encapsulation layer provides sufficient thermal transfer for the operation of the circuit.

Referring now to FIG. 8B, an embodiment is shown of device 800 having a chiplet die 810 on a chiplet mounting member 802. As discussed herein, the chiplet mounting member may be a planar region within a VDL that is sized to receive the chiplet die 810. The VDL (not shown) may be any desired shape as described herein. A frame 814 is disposed about the chiplet die 810. It should be appreciated that it may be desired to operate the chiplet or the circuit in general within predetermined thermal limits, such as for performance or reliability for example. Unlike the embodiment of FIG. 8A, the encapsulation layer 801 does not provide sufficient thermal performance. In this embodiment, a thermal volume layer 890 is disposed over the chiplet die 810. In some embodiments, the thermal volume layer 890 includes a plurality of thermal vias 891 that exit thermal egress, such as air for example. It should be appreciated that if additional layers, such as a shielding layer or the encapsulation layer 801 are provided, these may include apertures to allow heat transfer. During operation, as the chiplet die generates heat, the thermal energy is transferred via the thermal vias away from the chiplet 810.

Referring now to FIG. 8C, an embodiment is shown of a device 800 having a a chiplet die 810 on a chiplet mounting member 802. The VDL (not shown) may be any desired shape as described herein. A frame 814 is disposed about the chiplet die 810. The heat sink may be additively deposited (e.g. a metal or copper material) or may be a pick and place component manufactured in a separate system in as a prefabricated part for example. In this embodiment, a heat transfer device, such as a heat sink 893 is disposed over the chiplet die 810. In an embodiment the heat sink 893 may be coupled directly to the chiplet die 810. During operation, the heat sink 893 conducts heat from the chiplet die 810 and transfers it to the thermal volume layer 890. In some embodiments, part of the thermal layer 890 may be formed such that the heat sink 893 is exposed to promote thermal dissipation.

The embodiment of FIG. 8D shows a device 800 that combines the conductive thermal cooling of FIG. 8C with the convective cooling of FIG. 8B. In this embodiment, a heat sink 893 is thermally coupled to the chiplet die 810. A thermal volume layer 890 is fabricated over the heat sink 893 to conduct heat away from the chiplet die during operation. The thermal volume layer 890 includes a plurality of thermal vias 891 that extend between the heat sink 893 opposite the chiplet die 810 to a thermal egress, such as air for example.

The embodiment of FIG. 8E shows a device 800 that combines the conductive thermal cooling of FIG. 8C with active cooling provided by a thermal carrier. In this embodiment, a heat sink 893 is thermally coupled to the chiplet die 810. A thermal volume layer 890 is fabricated over the chiplet die with microfluidic channels 894 integrally formed therein. The microfluidic channels 894 are thermally coupled to the heat sink. During operation, the microfluidic channels 894 flow a thermal carrier/fluid, such as glycol for example, that receives thermal energy from the heat sink and removes it from the device 800.

The embodiment of FIG. 8F shows a device 800 that is similar to the embodiment of FIG. 8D except that the thermal layer 890 is fabricated in a manner where microfluidic channels 894 directly remove thermal energy from the chiplet die 810. During operation, the microfluidic channels 894 flow a thermal carrier, such as glycol for example, that receives thermal energy from the chiplet die 810 and removes it from the device 800. It should be appreciated that the geometry of the fluid passages in the illustrated embodiment is for example purposes and the claims should not be so limited. In other embodiments, the passages may have other shapes or sizes for example.

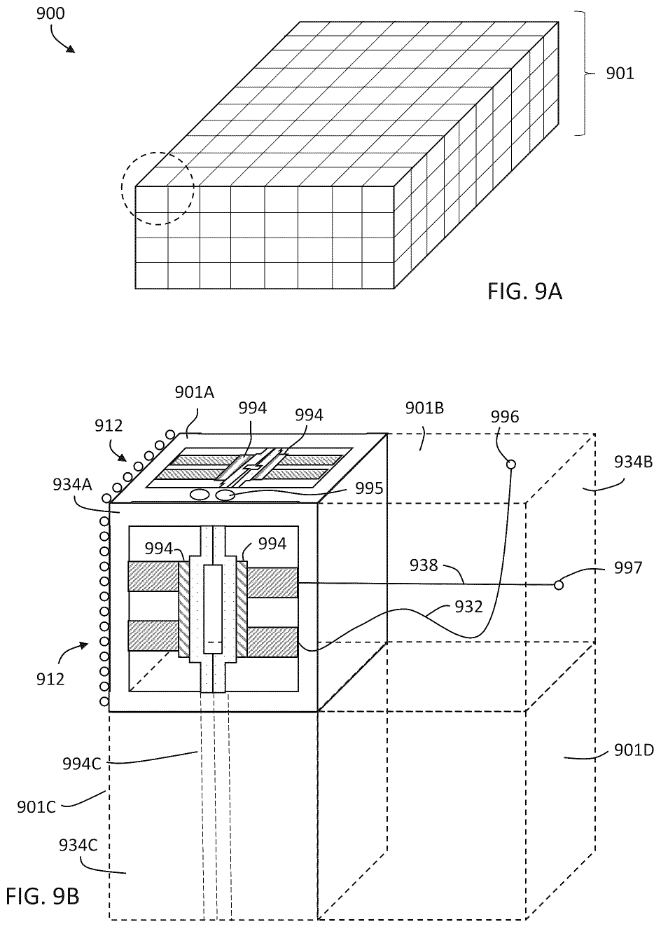

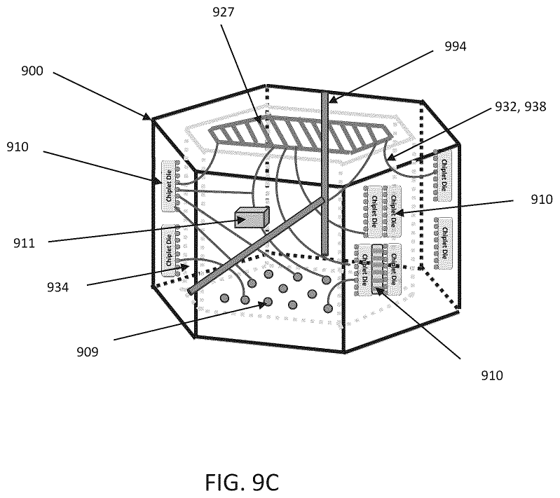

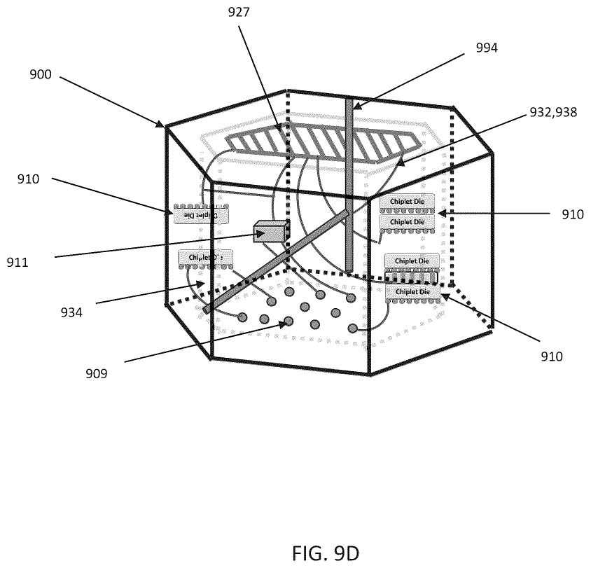

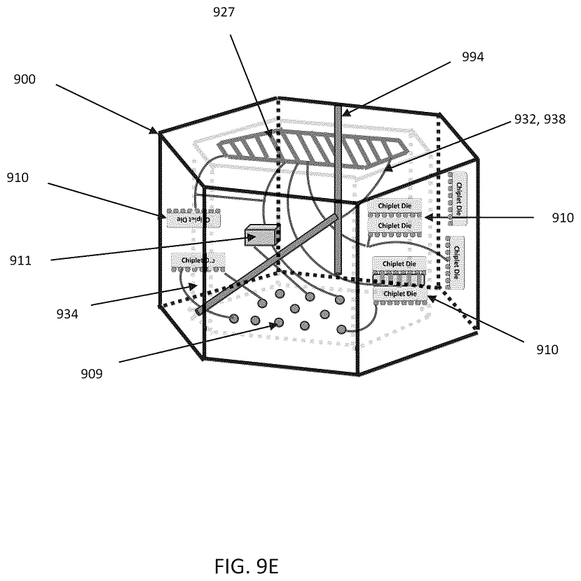

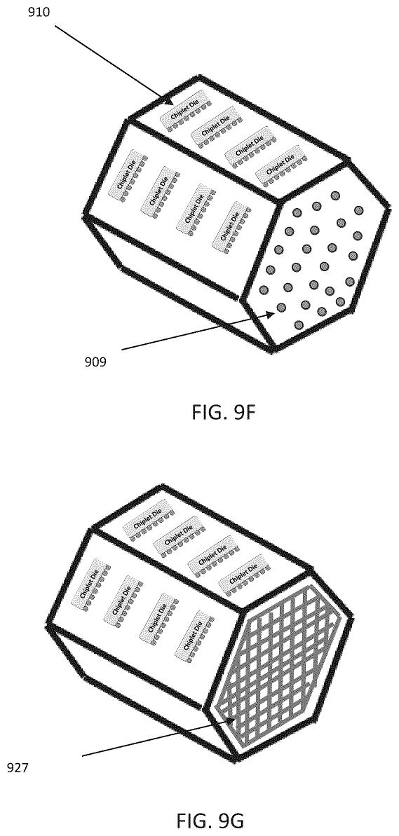

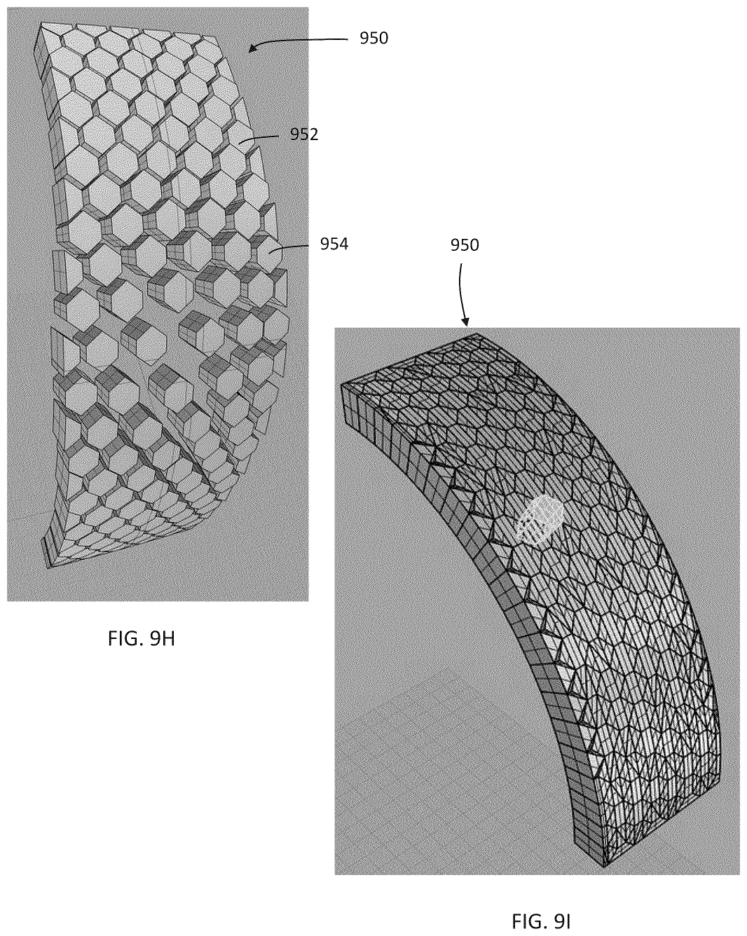

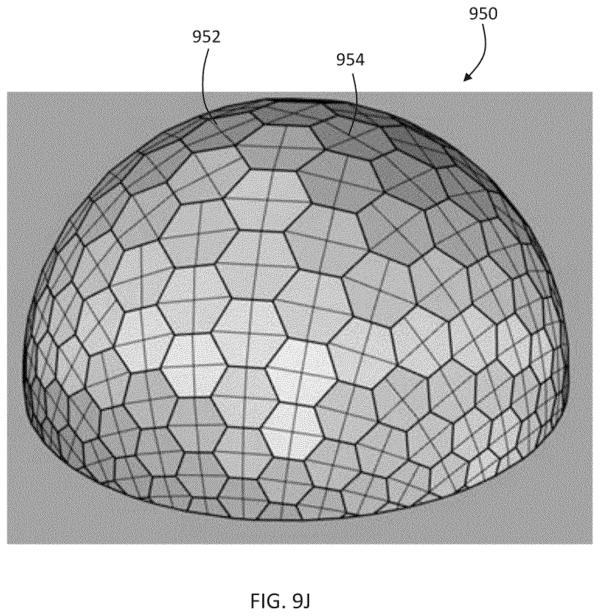

Referring now to FIGS. 9A and 9B, an embodiment is shown of a device 900 that is comprised of a plurality of chiplet voxels 901 that are combine together to define the shape of the device package. It should be appreciated that while the chiplet voxels 901 are illustrated as defining a generally planar device 900, this is for example purposes and the claims should not be so limited. In other embodiments, the chiplet voxels 901 may define any desired arbitrary shape. Further, the chiplet voxels 901 are illustrated as being cuboids, this is for example purposes and the claims should not be so limited. In other embodiments, the chiplet voxels may be arbitrary curved shapes, spherical, cylindrical, cone, pyramidal, hexagonal, prismatic, tetrahedral, pentagonal, or combinations of the forgoing for example.

As shown in more detail in FIG. 9B, a chiplet voxel 901A define a VDL 934A that includes one or more chiplet dies 910. The chiplet dies may be integrated with any of the other components described herein, such as but not limited to microfluidic channels 994, VIB's, spatial interconnects 932, TPV's 938, dielectric layers, electrical connections, bumps 912, or a combination of the foregoing for example. Further, in an embodiment, each chiplet voxel 901 may include one or more ports 995 that are fluidly coupled to the microfluidic channels 994. The ports 995 form an interface to allow the thermal transfer medium to flow through the chiplet voxel 901.

FIG. 9B also illustrates other examples of chiplet voxel types. For example, chiplet voxel 901B illustrates a VDL 934B, that includes one or more spatial interconnects 932 that traverse the chiplet voxel along a desired three-dimensional path and TPV's 938. The spatial interconnects and TPV's may terminate in an external connection or a bump, such as connection 996 for example. The spatial interconnects and TPV's may also terminate in an internal connection with an adjacent chiplet voxel, such as connection 997 for example.

Chiplet voxel 901C illustrates a VDL 934C that includes provides coolant channels 994C that connect the microfluidic channels 994 of chiplet voxel 901A to adjacent or downstream chiplet voxels. Chiplet voxel 901D is an example of a null chiplet voxel that provides structural support to adjacent chiplet voxels, such as chiplet voxel 901B and chiplet voxel 901C for example.

Referring now to FIG. 9C-9G, embodiments are shown of a device package 900 that includes a hexagonal chiplet voxel elements. In the embodiment of FIG. 9C the chiplets 910 are shown as vertical orientations (when viewed from the viewpoint of FIG. 9C). Further, the chiplet planes (not shown) are planar slices from side-to-side). The chiplets 910 may be connected via spatial interconnects 932 and TPV's 938 to other components in the same manner as described herein. The device 900 may include stacked chiplets connected via direct bonding methods, stacked chiplets using a VDL/TPV interconnect method for example. The device 900 may further include active/passive electronic devices 911, microfluidic channels 994 for cooling and package I/O 909 (solder balls/bumps) as shown in FIG. 9C and FIG. 9F. In the illustrated embodiment, the device 900 includes an antenna/sensor element 927 as shown in FIG. 9C and FIG. 9G (e.g. MEMS, image/Focal Plane Array (FPA), phases array antenna elements).

The embodiment of FIG. 9D is similar to the embodiment of FIG. 9C except the chiplets 910 (and chiplet planes) are arranged in a more horizontal orientation (when viewed from the viewpoint of FIG. 9D. In this embodiment, the chiplet planes (not shown) would be slices from top-to-bottom (when viewed from the viewpoint of FIG. 9D).

The embodiment of FIG. 9E illustrates an embodiment that combines the vertical and horizontal orientations of the chiplets 910 (when viewed from the viewpoint of FIG. 9E) shown in FIG. 9C and FIG. 9D in a single device package 900. It should be appreciated that the chiplet planes (not shown) are in multiple angles relative to one another. If should be appreciated that the chiplet planes may be oriented at different angles relative to each other and in some embodiments may not be at 90-degree angles relative to each other as illustrated in FIG. 9E.

Referring now to FIG. 9H and FIG. 9I, embodiments is shown of a system 950 having a non-planar three-dimensional shape, such as a curved or semi-spherical shape for example. In this embodiment, the device 950 includes a plurality of chiplet/HI based semiconductor device packages, such as device packages 952, 954 for example that are coupled to the system as could, for example, device packages connected to a backplane circuit board, flexible electronics material, or otherwise flexible substrate. It should be appreciated that while the embodiment of FIG. 9H and FIG. 9I illustrated the chiplet/HI-based device packages as being substantially uniform in shape and size, this is for example purposes and the claims should not be so limited, in other embodiments these device packages may each have difference shape and/or size.

In an embodiment, the device packages 952, 954 may extend from, be coupled to, plugged-in, or otherwise attached to a curved surface/volume structure for an array or matrix of elements. In an embodiment, the backplane could collectively implement a multi-element array surface for imaging, radar, or communications.

In the embodiment of FIG. 9J, the device 950 is similar to the embodiments of FIG. 9H and FIG. 9I illustrate how the hexagonal package elements extend from, are coupled to, connected to, plugged-in, or otherwise attached to a semi-spherical or dome volume structure for an array or matrix of elements. In an embodiment, this backplane could collectively implement a multi-element array surface for imaging, radar, or communications.

It should be appreciated that while the embodiments of FIG. 9C-9G are illustrated as being hexagonal shaped device packages fabricated from hexagonal shaped chiplet voxels, however this is for example purposes and in other embodiments, other chiplet voxel shapes may be used. These chiplet voxel shapes include but are not limited to, cylindrical, cubic, conical, triangular, other polygon volumes, or combinations thereof. It is contemplated that any three-dimensional shape or configuration and arrangements that are supported by the methods described herein may be used.

### Quality Control and Semiconductor Device Yield Improvement Methods

As mentioned previously, the semiconductor packaging methodology and structures described herein provide numerous advantages in creating devices that are flexible in shape and size and are lower in cost to achieve than prior art planar or 2.5D/3D packaging arrangements.

Further still, when combined with an additive manufacturing systems, such as the aforementioned U.S. application Ser. No. 17/574,326 for example, additional advantages may be achieved. Such as in the quality control of the fabricated devices. In semiconductor device manufacturing, each of the devices is tested and parameters measured prior to proceeding to the end customer or to other downstream fabrication or assembly operations. Typically, this testing is performed at discrete points in the fabrication process. The number of inspection points, and amount of testing is balanced against the cost of performing the inspection. Thus, the fabricator tries to reduce the number of inspections while keeping high confidence that the end device will still function within the desired parameters to avoid having to scrap or rework the devices.

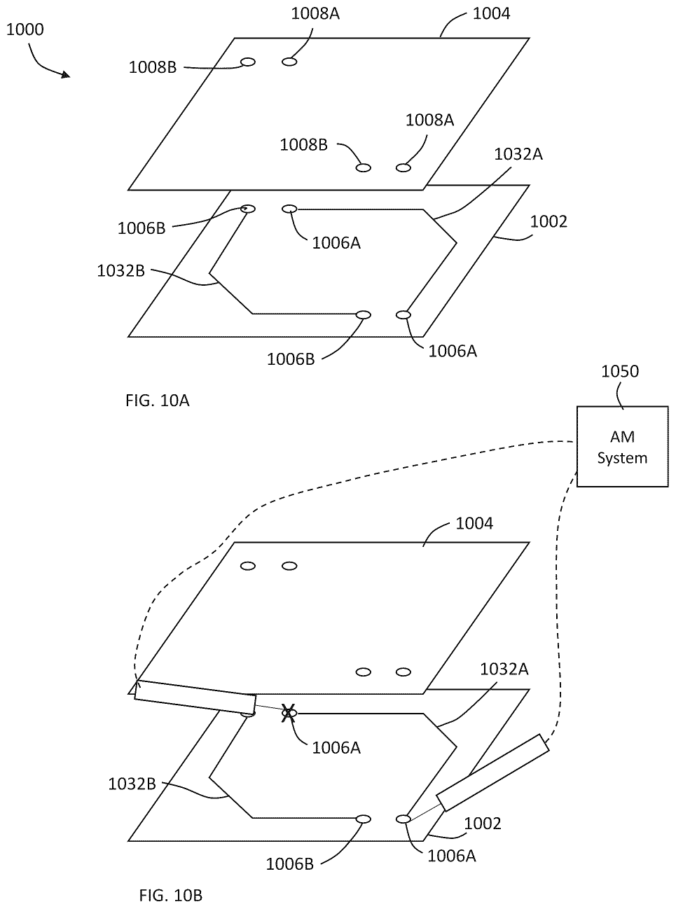

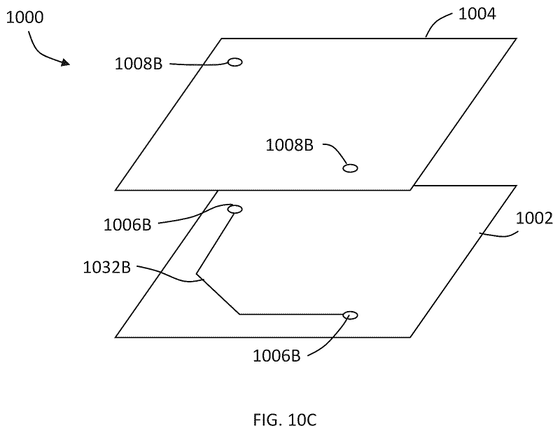

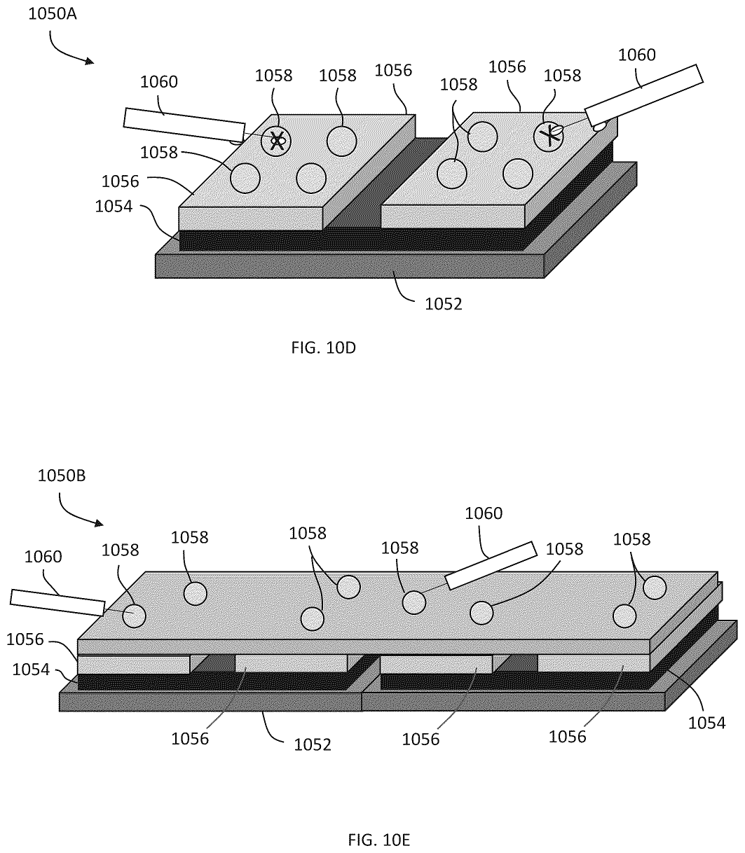

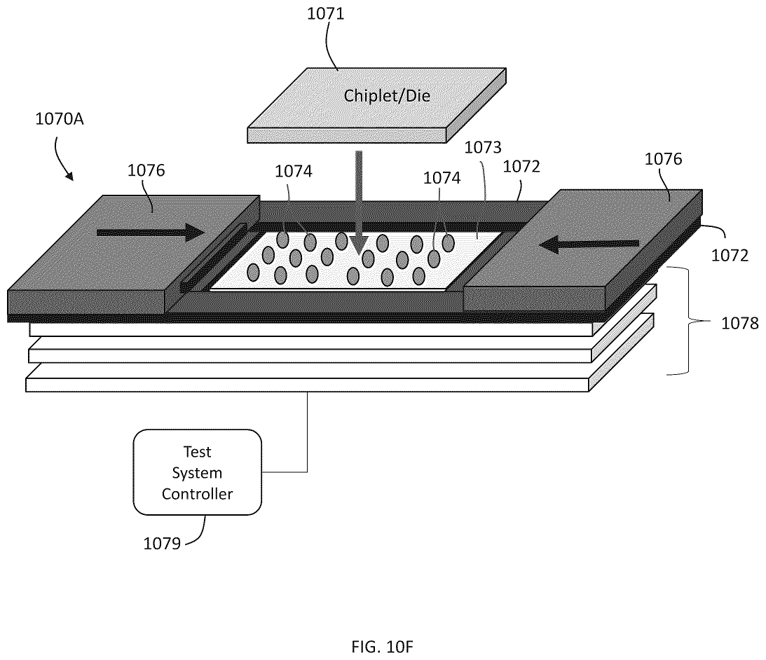

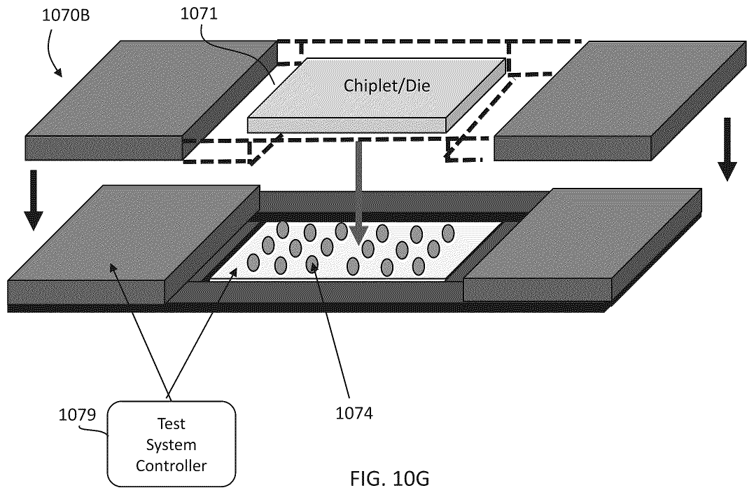

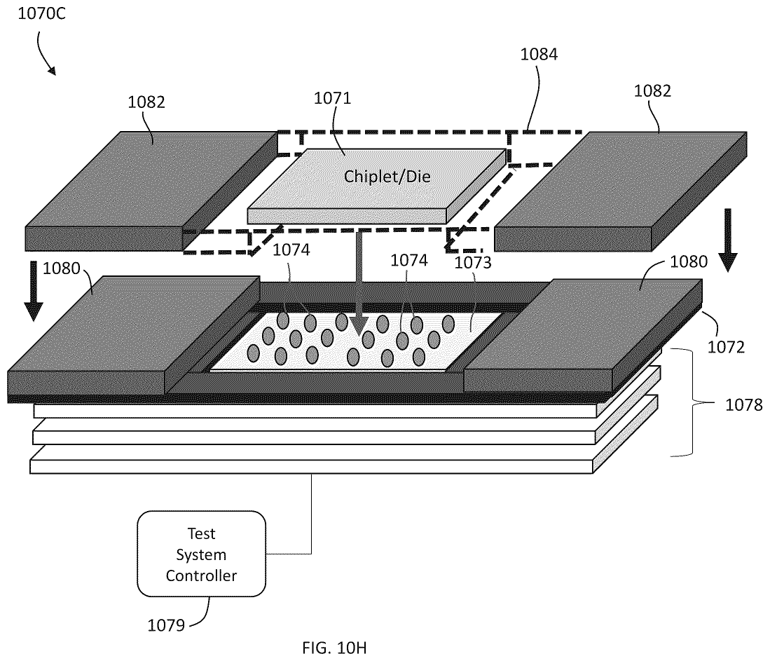

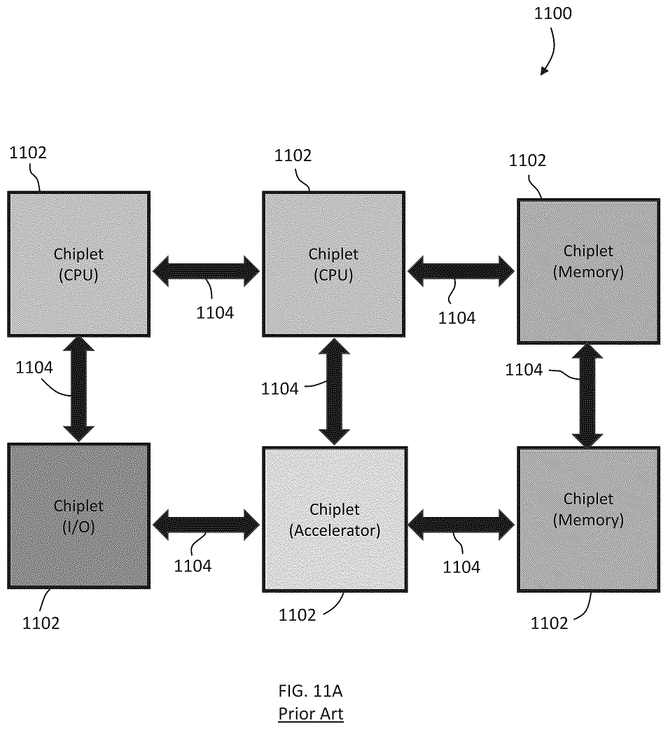

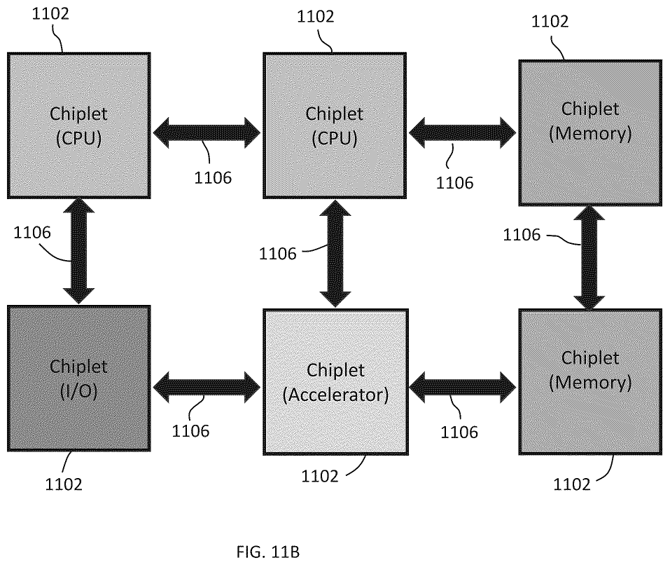

Referring now to FIG. 10A-10C, an embodiment of a method for in-process inspection and rework/repair is shown. It should be appreciated that this method is enabled by the additive manufacturing semiconductor packaging that is described herein. In this embodiment, a device 1000 is being fabricated that includes at least two layers, such as a VDL 1002, and a VDL 1004. The VDL 1002 includes spatial interconnects 1032A, 1032B that each terminate in electrical connections 1006A, 1006B respectively. The electrical connections 1006A, 1006B are electrically connected to TPV's 1008A, 1008B in VDL 1004 respectively. For purposes of this example, the spatial interconnects 1032A, 1032B are redundant. In other words, the device 1000 only needs one of these electrical circuits. This may be done for example, where this portion of the device 1000 has historically had reliability issues in the manufacturing process.

During fabrication, test probes 1010A, 1010B are used by the additive manufacturing system to measure one or more parameters of the circuits defined by the spatial interconnects 1032A, 1032B. For purposes of example, one or more of the parameters associated with spatial interconnect 1032A is not within the desired specifications. When this occurs, the method of fabricating the subsequent layer or chiplet voxel (e.g. VDL 1004) is changed to accommodate the out of specification portion of the circuit.

For example, where the circuit 1032A is out of specification, but a redundant circuit 1032B is operating within specification, the fabrication of the VDL 1004 may be changed such that the circuit 1032A is effectively disconnected from the remainder of the device 1000. In the illustrated embodiment, this may be accomplished by either removing the TPV's 1008A (e.g. using a nonconductive material in place of the conductive material), or where the hole for the TPV 1008A is already formed, by filling it with a nonconductive material or omitting the conductive material. As a result, the device 1000 will utilize redundant circuit 1032B.

It should be appreciated that in an embodiment where the testing devices can be automatically deployed and operated while the device is being fabricated, the amount of scrap or rework in the final device 1000 and thus costs reduced. Further, the disclosed embodiments allow for a “fast fail” approach where defects may be identified earlier in the process thus reducing the cost and time spent on components that will not satisfy specifications for the product. As will be discussed in more detail herein, this enables additional methodologies, such as the automatic re-generation/re-design/re-configuration of the device or individual chiplet voxels to accommodate the measured parameters. This may be accomplished for example, using machine learning or generative artificial intelligence that has been trained on historical data measured during the fabrication process.

Referring now to FIG. 10D, an embodiment is shown of a device 1050A that may be used to test chiplet dies individually to ensure desired functionality. In this embodiment, the device 1050 includes a substrate 1052 on which a layer 1054 having a frame and a chiplet die to be tested are mounted/fabricated using the methods described herein. A VDL layer 1056 is fabricated over the chiplet die using the methods described herein. The VDL layer 1056 includes a plurality of test pads 1058 that allow a technician to use probes 1060 to test different functionality. It should be appreciated that the VDL layer 1056 may, in some embodiments, be comprised of a plurality of layers that allow for the fanning out as shown in FIG. 6A-6E to facilitate access to the test pads 1058. It should be appreciated that the other test pads 1058 may be coupled to other circuits, such as to provide power for operating the chiplet for example.

It should be appreciated that in some embodiments it may be desirable to test the operation of multiple chiplets simultaneously, such as to test the combined functionality, or subsets of functionality, for example. Referring now to FIG. 10E, a testing device 1050B is shown. The device 1050B is similar to the device 1050A of FIG. 10D, having a substrate 1052 with a layer 1054 having a frame and chiplet die fabricated thereon. A first VDL 1056 is fabricated over the chiplet layer 1054, such as to fan out the chiplet contacts for example. In an embodiment, a second VDL layer 1062 is fabricated over the first VDL 1056. In this embodiment, the second VDL 1062 spans across a plurality of chiplet dies to allow interconnection therebetween. The second VDL 1062 further includes a plurality of test pads 1058 on a surface opposite the VDL 1056. As discussed above, the test pads 1058 allow for the interrogation of the device 1050B with probes 1060. Further, the test pads 1058 may be used to provide additional functionality such as power and grounding to the device 1058 for example.

It should be appreciated that in some embodiments it may be desirable to test the operation of multiple chiplets and/or other device components simultaneously, such as to test the combined functionality, or subsets of functionality, for example. For example, a heterogeneous device may have multiple chiplets and/or other device components, which can be in various arrangements. It is desirable to test the operation of the multiple chiplets and/or other device components together, not just the chiplets themselves. It should be further appreciated that in some embodiments it may be desirable to test the operation of the non-chiplet device components simultaneously, such as to test the combined functionality, or subsets of non-chiplet device components functionality, for example.

In the embodiments of FIG. 10D and FIG. 10E, the chiplet die is integrated into the testing device 1050A, 1050B. This may be desirable, for example, to allow engineers to test or build prototype circuits for example. However, the HI AME methods disclosed herein may also be used to test chiplets/dies in a non-destructive manner, such as for quality control purposes in a production environment for example. Referring now to FIG. 10F, an embodiment is shown of a testing device 1070A that is configured to allow the chiplet/die 1071 to be removably coupled to the device 1070A.

In this embodiment, the testing device 1070A includes a first layer 1072 having a contact area 1073 (e.g. a chiplet surface) with a plurality of contacts 1074 (also referred to as “test probes”) that are sized and positioned to engage the chiplet/die 1071. The layer 1072 may be fabricated using the AME methods described herein. Disposed on the layer 1072 on opposite sides of the contact area 1073 are a pair of chiplet frames 1076. In this embodiment, the chiplet frame 1076 is movable and configured to engage and hold the chiplet 1071 in place during testing. In some embodiments, the layer 1072 may include features, such as rails for example, that guide the movement of the frames 1074. The device 1070A further includes one or more VDL layers 1078 that are configured to couple the contacts 1074 to a test system controller 1079.

In operation, the chiplet 1071 is placed onto the contact area 1073 with one or more of the chiplet contacts in electrical contact with the contacts 1074. While the chiplet 1071 is held in place, the frames 1076 are moved from an open or first position (shown in FIG. 10F) to a closed or second position in contact with the chiplet 1071 to mechanically secure the chiplet 1071 to the first layer 1072. The test system controller 1079 then supplies power to the chiplet 1071 via the VDL's 1078 and performs any desired tests on the chiplet 1071 to confirm that it operates appropriately. Once the testing is completed, the frames 1076 are moved back to the open or first position and the chiplet 1071 is removed from the device 1070A.

It should be appreciated that while the embodiment of FIG. 10F illustrates a single chiplet testing device, this is for example purposes. In other embodiments, the testing device 1070A may have a plurality of contact areas 1073, each arranged to receive a chiplet. In this way, the test system controller 1079 may test multiple chiplets simultaneously or serially.

Referring further to FIG. 10F and also to FIGS. 10G, a contiguous treatment of package embodiments is shown. In particular, FIGS. 10F and 10G depict an AME-based scenario for device packaging for a representative test package or multi-dimensional build platform element (e.g., devices 1070A and 1070B of FIGS. 10F and 10G respectively) . . . . For example, large test packages can be built in such a way as to auto-generate a multidimensional build platform (e.g., volume elements that conform to those in FIGS. 10F and 10G) for high-volume test scenarios. According to one or more embodiments described herein, basic test probe packages (e.g., FIGS. 10D and 10E) are generated. Next, test problem packages are generated as multidimensional build platform volume elements (e.g., FIGS. 10F and 10G). Finally, test probe packages are generated for single test probe packages and auto-generated for high-volume testing using a multidimensional build platform.

Particularly, FIG. 10F depicts an actuating static pressure method according to one or more embodiments described herein. FIG. 10F depicts an actuating electro-magnetic compression method according to one or more embodiments described herein. In the embodiments of FIGS. 10F and 10G, chiplet testing and quality assurance can be performed in conjunction with an AME package implementing a test probe fixture (e.g., test probes (e.g., plurality of contacts 1074) connected to the test system controller 1079) that can execute tests and monitor results for the device 1070A and/or the device 1070B. In one or more embodiments, an multi-dimensional build platform configuration can be used additionally or alternatively with test probes on a build volume surface performing a similar operation. In such an embodiment, the multi-dimensional build platform provides the ability to implement a non-planar test environment. For multiple chiplets and/or component configurations (see, e.g., FIG. 10G), a similar methodology can be extended to additional chiplets and/or components using a similar approach. In FIG. 10G, a top plate can be hinged, rotate in/out, or actuate from top down.

Referring now to FIG. 10H, an embodiment is shown of a testing device 1070C that is similar to the devices 1070A, 1070B having a layer 1072 with a contact area 1073 with contacts 1074 disposed thereon. A one or more VDL layers 1078 electrically couple the contacts 1074 to a test system controller 1079.

In this embodiment, the layer 1072 has static fames 1080 fabricated thereon. Operable coupled to the frames 1080 are a pair or opposing frames 1082. The frames 1082 may be coupled to the frames 1080 or the layer 1072, such as by a hinge, a rotation mechanism, or an actuator for example. The frames 1082 are configured to generate a magnetic field 1084 that holds the chiplet/die 1071 and holds the chiplet 1071 in place on the contact area 1073 during testing.

It should be appreciated that the devices 1050A, 1050B, 1070A, 1070B are illustrated as being planar layers, however, this is for example purposes. In other embodiments, the devices 1050A, 1050B, 1070A, 1070B may include one or more non-planar (three-dimensionally shaped) layers.

### Multi-Chiplet Heterogeneous Integration

A System-on-Chip (SoC) integrates components of an electronic system (e.g., a computer) into a single integrated circuit. Examples of such components include processing units, memories, I/O devices, and/or the like including combinations and/or multiples thereof. One type of integrated circuit is based on the concept of a chiplet. Chiplets implement portions of SoCs broken down by functional part. A single SoC can be divided into multiple chiplets, each of which provides one or more specific functions and/or features that, when put together, can replicate the overall functions and features of the SoC. Chiplets provide for mixing and matching functionality by using different chiplets (available from different and/or multiple suppliers), improving overall yield, hence reducing cost, reusing intellectual property, providing interoperability (given varying standards as described herein) from different chip dies from different vendors, and/or the like including combinations and/or multiples thereof. Heterogeneous integration (HI) refers to integrating chiplets (potentially from multiple chiplet suppliers/manufacturers) to form complex functionality and systems within a single device package.

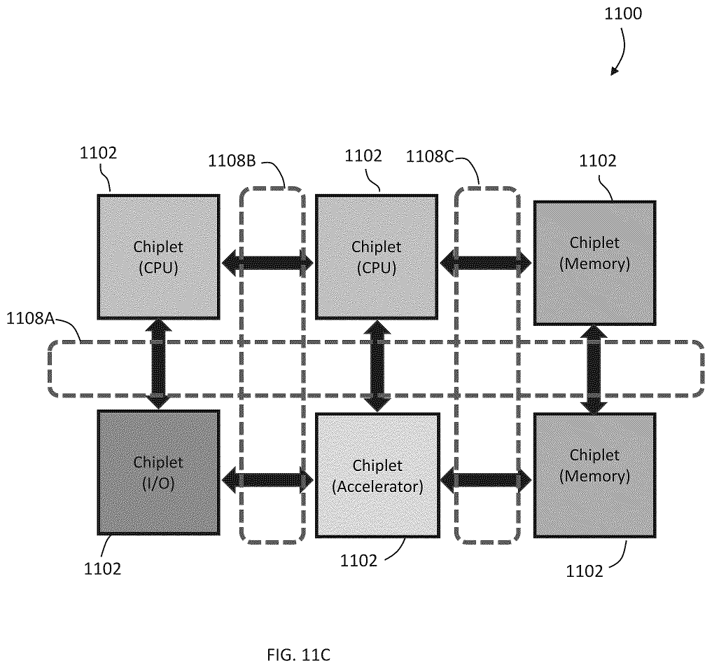

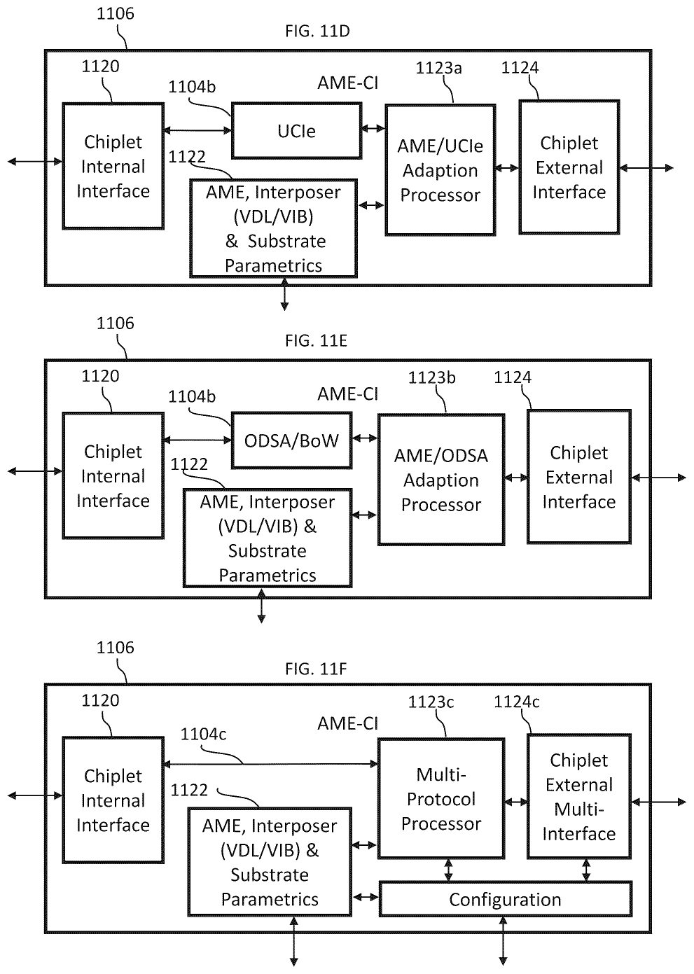

Referring now to FIG. 11A, a prior art chiplet packaging arrangement 1100 is shown. In the prior art systems, the interconnection of the chiplet dies 1102 (e.g., CPU, memory, I/O, accelerator, etc.) are defined by a standard, such as the Universal Chiplet Interconnect Express (UCIe) standard, the Open Domain-Specific Architecture (ODSA) standard, the AIB standard, or other suitable standard, including suitable combinations thereof. The standard provides die-to-die interconnect and signal/data bus interconnections between chiplets, such as the chiplet dies 1102, using on-die interconnect technologies and package type classifications (shown in FIG. 11A as “UCIe/ODSA/BoW 1104”). As an example, the UCIe standard enables the construction of large System-in-Package (SiP) and System-on-Package (SoP) semiconductor packages. The UCIe, for example, defines a physical layer, stack protocol, and software model. Various on-die interconnect technologies and package type classifications (e.g., the UCIe/ODSA/BoW 1104) are defined by the standard. In should be appreciated that the UCIe is only one possible standard and that other suitable standards may be used instead.

In an embodiment, the multi-die interconnection technologies and package type classifications defined by prior-art standards (e.g., the UCIe/ODSA/BoW 1104) can be replaced with comparable additive manufactured electronics (AME) methods as described herein that enable additive manufacturing of both planar and non-planar chiplet-based package arrangements.

The AME approach to chiplet HI can involve extending the chiplet internal interfaces (e.g., for external inter-chiplet communications) to include AME constructs, methods, and devices to consider the impact on the physical properties (e.g., thermal/heat transfer, structural stresses/considerations, material characteristics, such as dielectric properties), electrical properties, (e.g., noise, cross-talk, inductive/capacitive couplings, power losses, insertion losses, signal degradation, latency, etc.), and/or the like including combinations and/or multiples thereof.

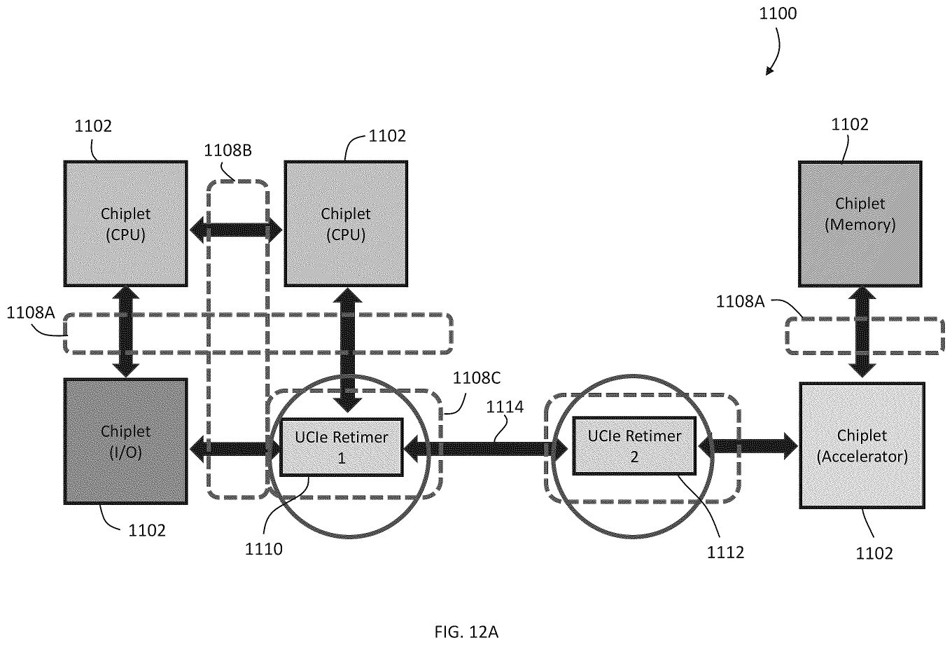

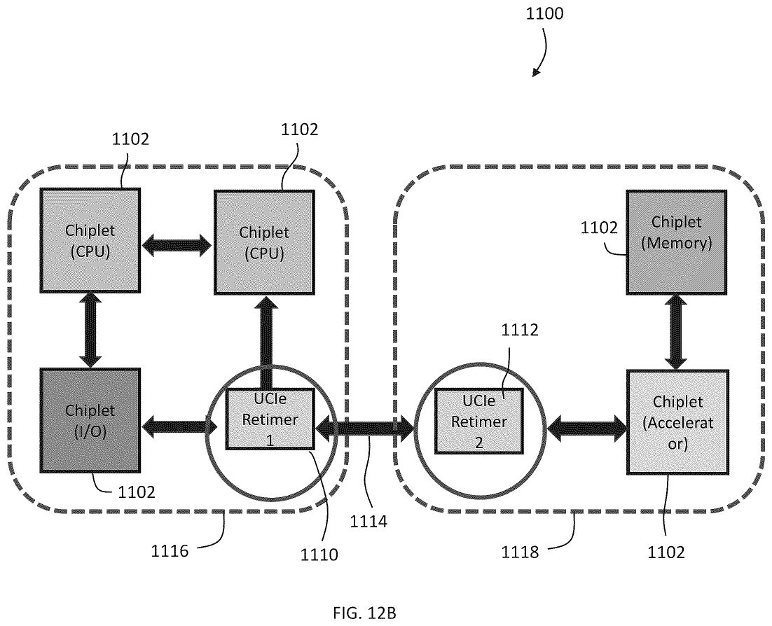

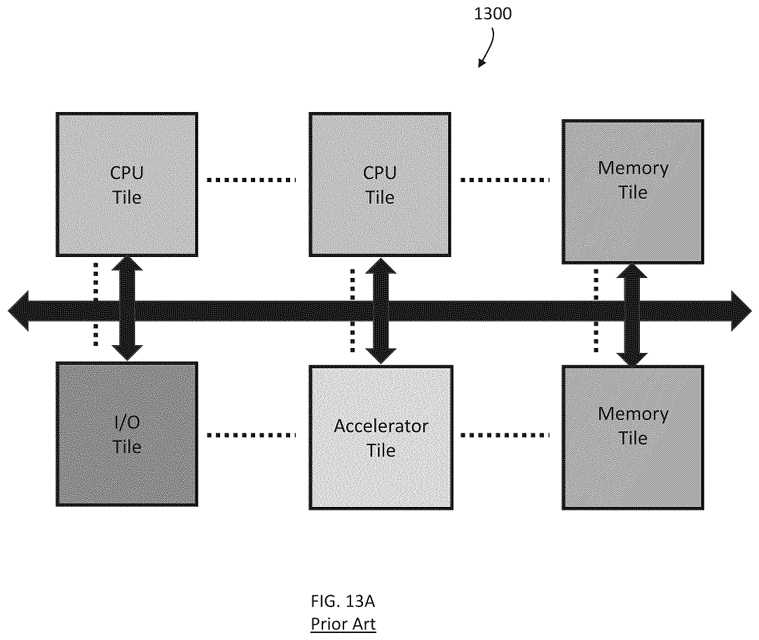

As shown in FIG. 11B, the UCIe/ODSA/BoW 1104 of FIG. 11A is replaced with or adapted using AME chiplet interconnect (AME-CI) 1106. According to one or more embodiments described herein, each of the chiplet dies 1102 may be interconnected by VDL's containing one or more of VIBs, spatial interconnects, TPV's, active electrical components, and passive electrical components, for example, where the AME-CI 1106 is a feature embodiment of the chiplet implementation. In one embodiment, the AME-CI 1106 is utilized to connect individual die modules 1102 similar to the prior art as shown in FIG. 11A such that the AME-CI 1106 replaces or adapts the UCIe/ODSA/BoW 1104 to provide a unified method for inter-chiplet integration in planar or non-planar packaging arrangements. More particularly, the AMI-CE 1106 suitably adapts the standard methods in FIG. 11A (e.g., UCIe, ODSA/BoW, AIB, and/or the like including combinations and/or multiples thereof) to operate within an AME fabricated structure using materials that differ from silicon-based semiconductors of the prior art (e.g., materials and their associated AME parametrics yielding an AME oriented process for device package fabrication while leveraging the standards). Although in FIGS. 11A-11C the UCIe/ODSA/BoW 1104 and the AME-CI 1106 are shown between chiplets 1102, it should be understood that the UCIe/ODSA/BoW 1104 and similarly the AME-CI 1106 are implemented within the chiplet dies 1102, not externally at the bus signals between the chiplets 1102, according to one or more embodiments described herein. However, in some embodiments, such as shown in FIG. 12A, for example, the inter-chiplet communications is adapted via an external UCIe retimer that is external to the chiplets. With continued reference to FIGS. 11A, 11B, and/or 11C, according to one or more embodiments described herein, some active components are present in support of the AME-CI 1106 interconnection functionality (e.g., using UCIe retimers as described herein), but the arrows with labels in FIGS. 11A-11C between and among the chiplets 1102 are indicated to show interconnections implemented by the capability of the chiplets 1102. The AME-CI 1106 is an enhancement to the UCIe/ODSA/BoW 1104 chiplet internal module to support the AME and AME parametrics techniques described herein. This approach enables flexible geometric package configurations, reducing manufacturing cost, time, and complexity while improving reuse and reducing the number of new or redesigns. The inter-chiplet integration via AME methods described herein are implemented in either of the chiplets 1102 themselves as illustrated in the AME-CIs 1106, or in conjunction with one or more VDL's 1108A, 1108B, 1108C that embody one or more AME parametrics and simultaneously connect one or more chiplets 1102 as shown in FIG. 11C.

FIGS. 11D, 11D, and 11E show examples of an AME-CI 1106 according to one or more embodiments described herein. Particularly, these three figures depict architectures for implementing the AME-CI 1106. The AME-CI 1106 includes a chiplet internal interface 1120, parametrics 1122, a processor 1123, as described herein, and an interface 1124. The AME-CI 1106 also includes a standard or modified standard for interfacing between the chiplet internal interface 1120 and the respective processors 1123. Particularly, FIG. 11D includes a UCIe 1104 for interfacing between the chiplet internal interface 1120 and an AME/UCIe adaptation processor 1123a. The UCIe 1104b can be substituted for other standards in other embodiments. For example, FIG. 11E includes an ODSA/BoW 1104b for interfacing between the chiplet internal interface 1120 and an AME/ODSA/BoW adaptation processor 1123b. The standards (e.g., UCIe, ODSA, and/or BoW) of FIGS. 11D and 11E can be adapted and/or replaced with an AME-CI protocol 1104c as shown in FIG. 11F for interfacing between the chiplet internal interface 1120 and a multi-protocol 1123c. The chiplet internal interface 1120 enables the AME-CI 1106 to interface with an internal bus, switch, core, tile, and/or the like including combinations and/or multiples thereof. The processors 1123 incorporate AME parametrics and the respective standard protocol (e.g., UCIe, ODSA, or BoW) implementation and regenerates the necessary signals and data for the standard interconnection protocol and physical layer standard to operate over the AME structure using the interface 1124. The interface 1124 provides the physical layer interface with one or more of the chiplets 1102 making up the complete device package. The parametrics 1120 can include AME, interposer (VDL/VIB), and substrate parametrics as shown. This provides for a more comprehensive set of inputs to the processor 1123 in FIGS. 11D and 11E. The embodiment of FIG. 11F is a fully generic method for multi-chiplet communications where the standards specific implementation (AME/UCIe or AME/ODSA/BoW of FIGS. 11D and 11E respectively) is replaced with a generic multi-protocol processor 1123c and a chiplet external multi-interface 1124c. The idea here is that a reconfigurable module core or tile is provided that can support multiple inter-chiplet standards.

In an embodiment, AME parameters (which can include parameters, configurations, and/or parametrics) refer to the material, electrical, thermal, geometrical, and signaling/timing parameters, characteristics and behaviors, that a hardware interface or controller (e.g., the AME-CI 1106 shown in FIGS. 11D-11F), software interface or controller, or computer aided design (CAD) tool (e.g., during chiplet/HI AME package design) considers and generates for operation or execution. According to one or more embodiments described herein, the AME parametrics are variables and configuration that are defined or generated by the CAD tool processes, material characteristics, metrology, tool path, and process generation of the AME system during the design of, configuration, and operation of the AME system, for fabricating the package. According to one or more embodiments described herein, the AME parametrics are at the hardware/chiplet and component level, and their interconnections, where AME parameters influence the behavior of the interface/control logic responsible for integration and sending/receiving of control or data signals that occur across one or more chiplet interfaces and/or other components within an AME fabricated package. AME parametrics can include material parameters, electrical parameters, signal timing parameters, and/or the like including combinations and/or multiples thereof.

In a first example, material parameters may include the physical properties (such as dielectric constant, insulator properties, the conductivity/resistivity of the materials, inks/pastes, thermal/hot-spot and structural properties such as warpage/stress, material gradations, and the internal topology (e.g., material variations and geometric structure, for example where graded materials with different materials are used in different ways that vary), metamaterial structure, lattices, etc.) of the substrate, VDL/VIB, conductive interconnections, I/O pads/bumps/solder balls, and interconnection parameters and design rules associated conductive or insulator line widths, spacing, and depth that affect the transmission properties of any control or data signals.

In a second example, electrical parameters (can be static analysis or based on simulation, and/or runtime analysis from CAD/tools, or even a real-time hardware based measurement capability within the chiplet and/or device components) include the resistivity, conductivity, dielectric constant, power and current loads, thermal characteristics, insertion loss, capacitance and inductance of the interconnects, and/or materials, power and signal integrity related parameters such as BER, return loss, cross-talk, Z-impedance, IR drops, parametrics derived from a power delivery network (PDN) analysis, noise/ripple-noise effects, insertion-loss, parasitic, S-parameters, AC time and frequency domain analysis, RF, EMI, shielding, and/or the like including combinations and/or multiples thereof. For example, as an embodiment, electrical and material parameters can modify the AME parametric set to facilitate the design of proper thermal and shielding layers as described herein.

In a third example, signal timing parameters relate to timing such as latency parameters, propagation delays, and round-trip time (RTT), asynchronous, or latency insensitive design parameters that can be used to influence buffering and asynchronous communications implementation and real-time operational behavior.

In a fourth example, AME system parameters relate to build platform and cavity characteristics, such as temperature, tool configurations (e.g., laser spot beam size), camera and vision system, calibration tools, deposition characteristics (e.g., droplet, aerosol, or jetting characteristics), curing and sintering processes and associated properties, pick-and-place configurations, and/or the like including combinations and/or multiples thereof.

In a fifth example, AME parametrics may incorporate results derived from the principles and methods of Latency Insensitive Design to compensate, including but not limited to, clock-timing compensation, methods of synchronization, and/or asynchronous timing between communicating elements, components or systems, timing and clock management, timing regeneration, and rate-adaption methods, to adapt, and/or improve performance, for inter-chiplet communication characteristics within the methods described herein of AME fabrication of device packages. The principles and methods of Latency Insensitive Design are also described in Carloni, From Latency-Insensitive Design to Communication-Based System-Level Design, Proceedings of the IEEE, Vol. 103, No. 11, November 2015, the contents of which is incorporated by reference herein. Still further aspects of Latency Insensitive Design are described in Carloni, et al., The Theory of Latency Insensitive Design, IEEE Transactions on Computer-Aided Design of Integrated Circuits and Systems, Volume: 20, Issue: 9, September 2001, the contents of which are incorporated by reference herein.

It should be appreciated that an embodiment, the theory of latency insensitive design allows for the implementation of inter-connected devices such that communication latency can be compensated for, given the paradigm and using the methods of the papers described above. In an embodiment, to incorporate the AME parametrics into the formal methods, and/or the AME-CI (FIGS. 11D-11F) such that the latency issues that may be introduced by additive manufacturing and materials can be compensated for to ensure the desired operation of chiplet-to-chiplet and/or system-level communications in the AME fabricated device package.

In a sixth example, AME parametrics may include and represent optimized configurations generated through machine learning algorithms including generative AI whereby an optimal set of AME parametrics are computed for a given set of fabrication, processes, materials, and device package arrangements.

AME parameters may be heterogeneous in nature, meaning that different parameters and associated characteristics may vary on chiplet voxel by chiplet voxel basis and/or may vary on a VDL/VIB layer-by-layer basis.

The AME parameters may additionally be utilized by AM systems (including 3D build platform) to effect behavior of the AME tools, toolpath generation and operation as well as testing, package verification, and automated repair strategies.

Referring now to FIG. 12A and FIG. 12B, an embodiment is shown where active devices are arranged within VDL for UCIe signal conditioning. In FIG. 12A, a UCIe element (e.g., UCIe retimer modules 1110 and 1112) compensates outside the chiplets residing in the VDL domain. This provides for a component that sits between two groups of chiplets that communicate with one another. Such component (e.g., somewhere within the VDL of the package) adapts the communication/electrical objectives to sustain a desired level of operation among the chiplets that are potentially far apart from one another (e.g., the chiplets 1102). FIG. 12B shows that the retime modules (e.g., UCIe retimer modules 1110 and 1112) can exist in different chiplet voxels. The UCIe specification defines the inter-chiplet communications. It should be appreciated that the use of a VDL may result in changes in the signal processing, propagation, or timing. In an embodiment, UCIe retimer modules 1110, 1112 is embedded within the circuit, in which case the AME parameters are considered at the physical level. According to one or more embodiments described herein, alternatively or complementary to FIGS. 11D-11F, the UCIe retime modules 1110, 1112 are implementation dependent based on whether (or which of) the embodiments of FIGS. 11D-11F are used independently, whether a VDL is added to one or more of the embodiments of FIGS. 11D-11F, or whether a VDL is used independently for AME-based UCIe communications. The UCIe retime modules 1110, 1112 may be electrically coupled by an AME interconnect 1114, such as a TPV or spatial interconnect. It should be appreciated that the device/circuit 1100 may also be arranged as chiplet voxels 1116, 1118 as shown in FIG. 12B. One or more of the UCIe retime modules 1110, 1112 are devices incorporated into a VDL layer (e.g., in a positioned within a chiplet frame).

In the embodiments of FIGS. 12A and 12B, the AME interconnection methods among chiplet architectures were illustrated in conjunction with AME parameters. It should be appreciated that other standard interconnection specifications may be used, and the embodiments described herein are not limited to those described here. Other standards methods may come into existence in the future; however, the methods described in the application where we utilize AME parameters to support the inter-chiplet communications implementation are applicable.

Non-limiting examples of chiplet-to-chiplet integration standards are the UCIe, the ODSA standard promoting BoW (bunch of wires), Advanced Interface Bus (AIB), CEI-112G-XSR, and/or the like including combinations and/or multiples thereof.

### Chiplet/HI Tile-Based Network-On-Chip Architecture

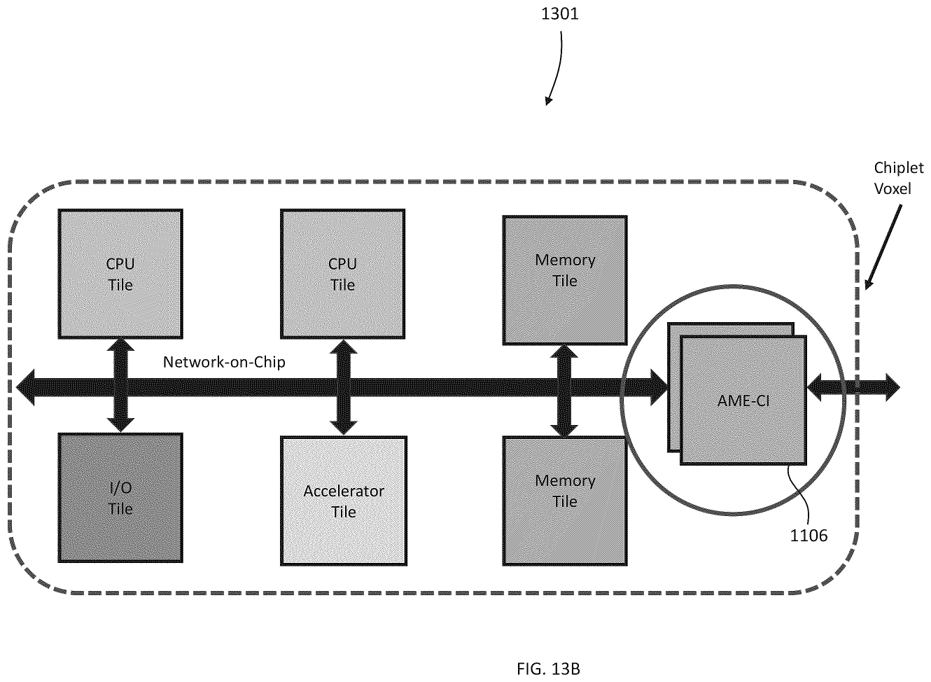

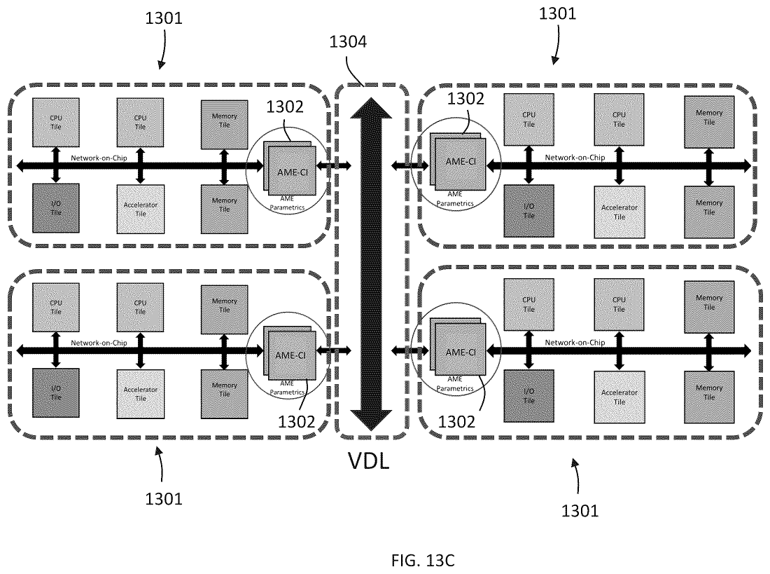

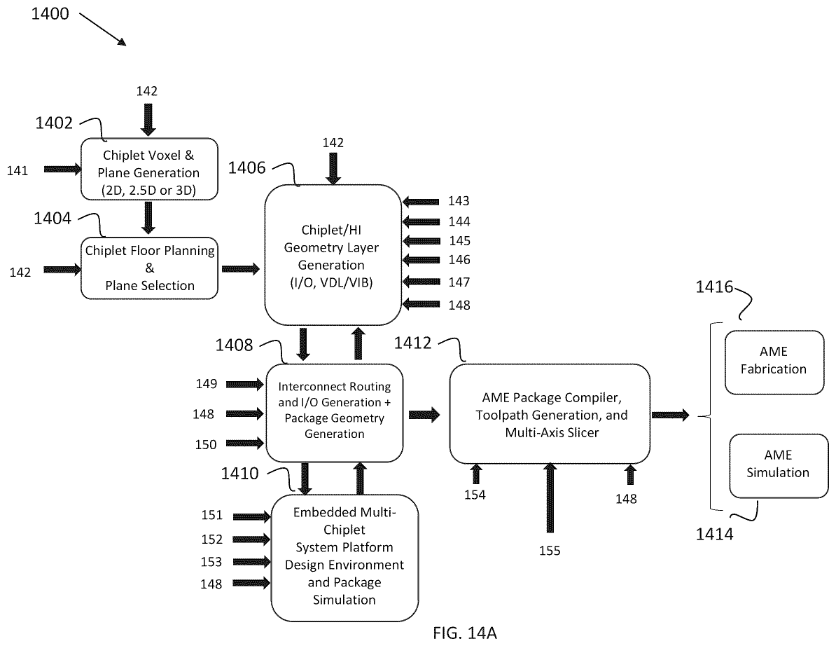

Referring now to FIG. 13A, an embodiment is shown of a prior art device 1300 configured as an array of tile-based cores (where individual cores may include, but are not limited to, one or more of CPUs, GPUs, memory, I/O, etc., each incorporating a network-on-chip interface functionality) module communication utilizing a network-on-chip for inter-tile communications.

Referring now to FIG. 13B and FIG. 13C, an embodiment of a tile-based chiplet 1301 is shown having AME-CIs 1106 that are incorporated into a chiplet to provide an interface enabling communications among multiple of the tile-based chiplets 1301. The AME-Cis 1106 provides physical, transport, and protocol levels of integration according to one or more embodiments described herein. According to one or more embodiments described herein, the AME-CIs 1106 include a network-on-chip (NoC)/router interface to an internal tile network architecture, buffering and control logic for asynchronous inter-chiplet communications, and an AME parameter driven physical interconnection interface to other tile-based chiplets, such as those present in the 3D space of the heterogeneous integration package.

In an embodiment as shown in FIG. 13C, one or more of the AME-CIs 1106 is electrically connected by a VDL 1304 that may integrate one or more chiplet voxels, each including spatial interconnects, TPV's, active electrical components, and/or passive electrical components, for example. It should be appreciated that the interconnection bus shown in FIG. 13C implements the inter-chiplet communications (across multiple possible methods) and is implemented within the one or more VDLs (e.g., the VDL 1304).

It should be appreciated that for the embedded design system of individual chiplets based on a tile and network-on-chip approach, may be based, at least in part, on the methods described in Mantovani et al., Agile SoC Development with Open ESP, 2020 International Conference On Computer Aided Design (ICCAD)—Special Session on Opensource Tools and Platforms for Agile Development of Specialized Architectures, Sep. 2, 2020, the contents of which are incorporated herein by reference.

### Chiplet/HI & AME Design Flows

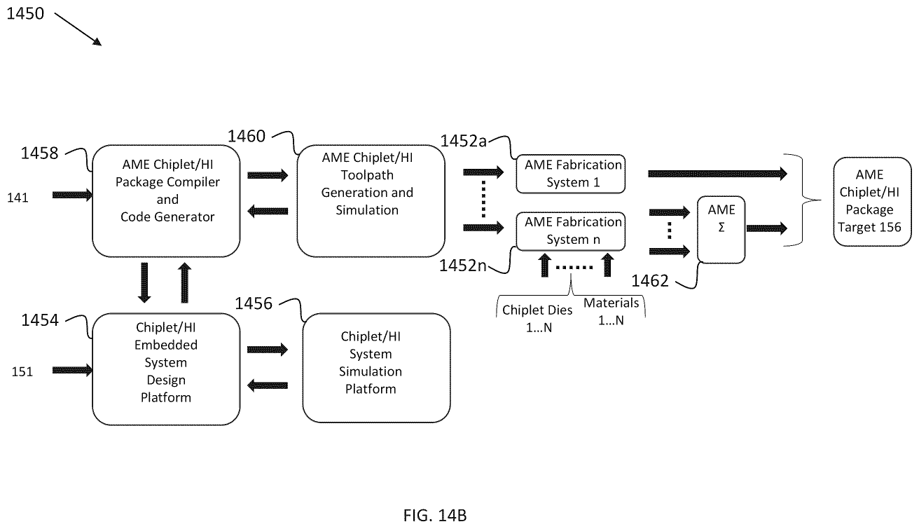

FIG. 14A illustrates a flow diagram of a method 1400 for fabricating a chiplet-based device package using AME parametrics for additive manufacturing according to one or more embodiments described herein.

At block 1402, chiplet voxels and corresponding chiplet planes are generated based on a target package geometry 141 and a user control/selection 142. The user control/selection 142 is the user-interface (UI), visual editor, or configuration file definition of the specific set of chiplet voxels available from the resulting generative process of volume or surface meshing of the target package geometry 141. Further, once the chiplet voxels are selected from the previous operation, the user then selects (via the UI or via configuration file) the set of possible chiplet planes definable within each chiplet voxel by a similar generative process. Particularly, at block 1402, a target package geometry 141 and a user control/selection 142 are received as described. The target package geometry 141 defines a high-level chiplet target package geometry in terms of overall shape characteristics. The target package geometry 141 can be imported in multiple formats, including stereolithography (STL) file format, a Standard for the Exchange of Product Data (STEP, ISO 10303) design data format, and/or the like including combinations and/or multiples thereof.

At block 1404, a chiplet floor plan is generated and a plane is selected based on a user control/selection 142. The chiplet floor plan defines the layout of individual chiplet dies to within each chiplet voxel instance from block 1402. For example, a shape, such as a cylinder or any other suitable shape, is meshed into multiple chiplet voxels, and a user selects where a plane passes through one or more of the chiplet voxels. According to one or more embodiments described herein, the plane can be orientated automatically. According to one or more embodiments described herein, each chiplet voxel has one plane per chiplet voxel. It should be appreciated that a plane can pass through a chiplet voxel at any orientation (see, e.g., FIG. 3A and FIG. 3B). The chiplet voxels define a space for the chiplet mounting member and allow the chiplet planes to be defined on any angle within the chiplet voxel.

At block 1406, chiplet/HI geometry layers are generated based on a user control/selection 142 of various factors, such as chiplet/component data 143, inter-chiplet and component net list data 144, power/ground and thermal/shielding design data 145, input/output configuration data 146, VDL active/passive device configuration data 147, AME parametrics 148, and/or the like including combinations and/or multiples thereof. The various factors describe how pads are designed/arranged, whether there are any VDL device configurations (e.g., chip capacitators, resistors, inductors, etc.), and/or the like including combinations and/or multiples thereof. The various factors are received and used to build a geometry that includes the VDL/VIB layer stacking as desired. The result is a geometry defined by layers that can be passed to block 1408. According to one or more embodiments described herein, the component net list data includes some or all of the components of the device, not just the chiplet(s).

At block 1408, interconnect routing and package geometry generation are performed. The interconnect routing and package geometry generation takes in configuration data, such as electrical/physics configuration data 149, AME parametrics 148, physical design rules and interconnection configuration data 150, and/or the like including combinations and/or multiples thereof. The various inputs are used to generate I/O and package geometry information.

At block 1410, each chiplet itself is designed. Particularly, an embedded multi-chiplet system platform design environment and package simulation tool use the one or more chiplet design specifications data 151, chiplet interconnection design data 152, chiplet(s) design data 153, AME parametrics 148, and/or the routing information block 1408 to design each chiplet desired in the target device package. It should be appreciated that the chiplet system platform design environment may include a visual design editor, or otherwise allow for the chiplet design to be defined in a programming language, or combinations of both.

It should be appreciated that block 1406, 1408, and 1410 can be interconnected such that changes to the design within one of the blocks can be propagated to the other blocks. For example, if information about the chiplet design changes at block 1410, those changes can be propagated to block 1408 and 1406 to update the routing and geometry, respectively.

According to one or more embodiments described herein, the blocks 1402-1410 are performed in a design software, such as a CAD tool.

At block 1412, the geometry, routing, and chiplet(s) information are sent to an AME package compiler, toolpath generation, and multi-axis slicer tool to compile to code to additively manufacture a complete chiplet/HI device package. The AME package compiler defines the properties of the chiplet/HI device package to be fabricated using additive manufacturing. According to one or more embodiments described herein, the AME device package is a device package that contains one or more chiplets integrated via principles of heterogeneous integration. The AME package compiler can generate AM-Code, for example. The AME package compiler can generate the AM-Code for all layers of the device package, multi-region subsets of AM-Code, and/or individual region AM-Code. The AME package compiler, toolpath generation, and multi-axis slicer tool can receive a toolpath configuration 154 (e.g., type of tool, path of tool, etc.), material configuration 155 (e.g., information about the material(s) used for additive manufacturing), and/or AME parametrics 148 to generate the AME device package. The AME package compiler can be used to perform an AME simulation (block 1414) to simulate fabrication of the chiplet/HI and/or perform AME fabrication (block 1416) tool path simulation for fabrication of the chiplet/HI package.

According to one or more embodiments described herein, the block 1412 is performed by a software tool of an additive manufacturing printer, or additive manufactured electronics system solution, or 3D printed electronics system, or a third-party software tool separate from a software tool of the additive manufacturing printer.

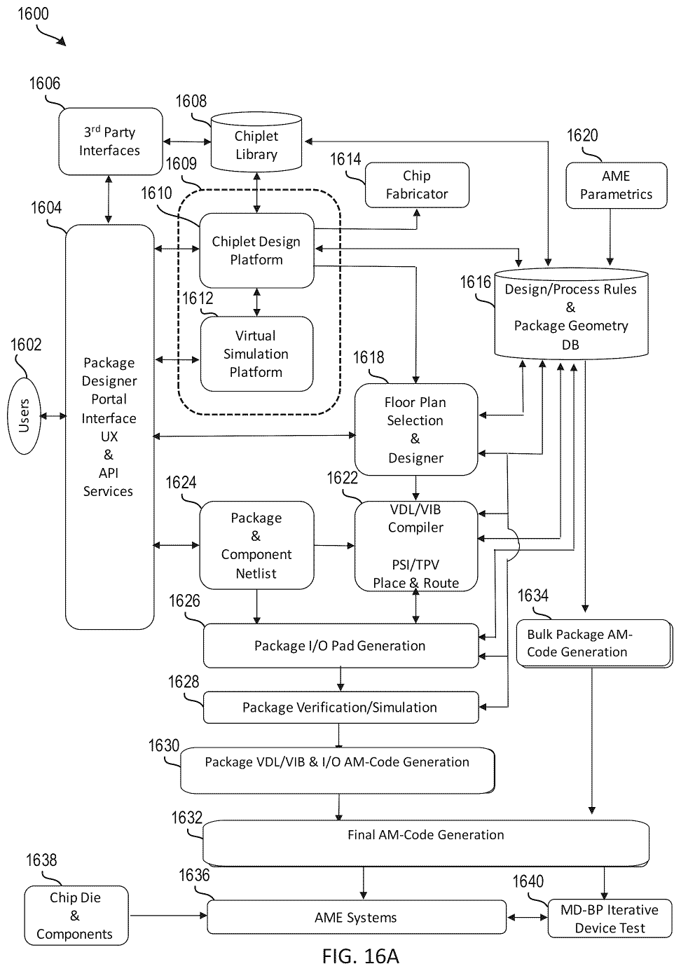

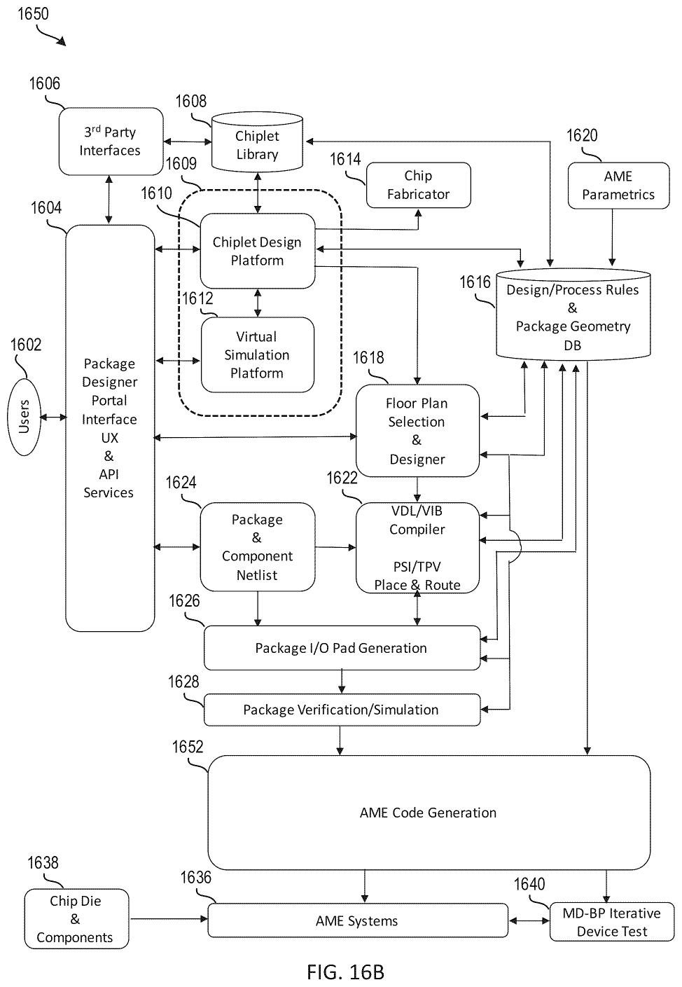

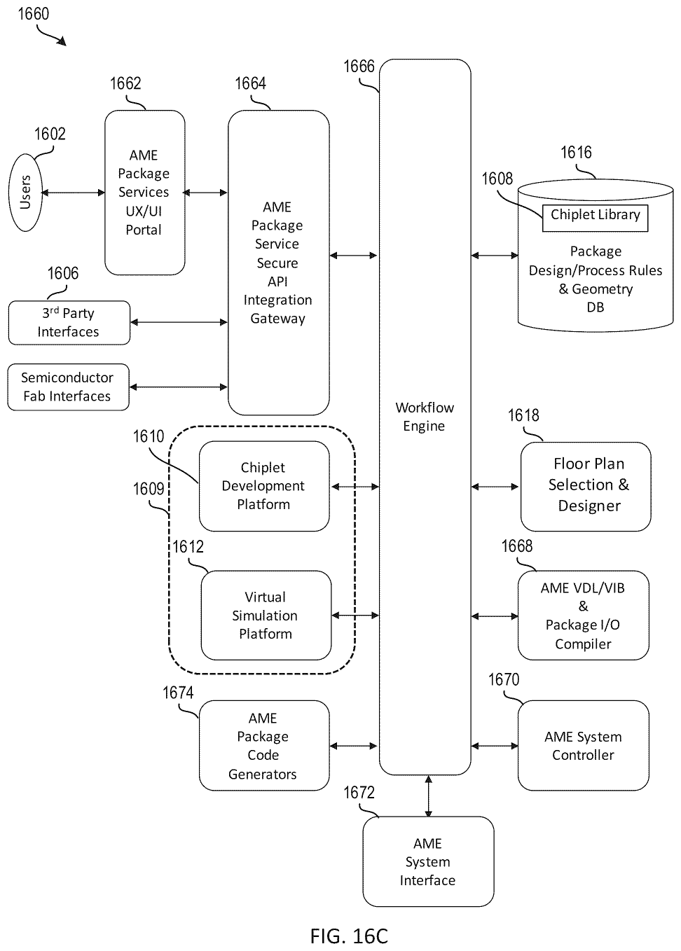

Additional processes also may be included, and it should be understood that the processes depicted in FIG. 14A represent illustrations, and that other processes may be added, or existing processes may be removed, modified, or rearranged without departing from the scope of the present disclosure. It should also be understood that the processes depicted in FIG. 14A may be implemented as programmatic instructions stored on a non-transitory computer-readable storage medium that, when executed by a processor (e.g., the processing device 1621 of FIG. 16) of a computing system (e.g., the processing system 1600 of FIG. 16), cause the processor to perform the processes described herein.

FIG. 14B illustrates a flow diagram of a method 1450 for fabricating a chiplet/HI device package using AME parametrics for additive manufacturing according to one or more embodiments described herein. In this example, multiple AME fabrication systems can be used, such as AME fabrication systems 1452a . . . 1452n.

Chiplet-based design specifications 151 are input into a chiplet/HI embedded system design platform 1454. The chiplet (or multi-chiplets) design can be simulated by a chiplet/HI system simulation platform 1456. The target package geometry 141 (described herein) is input into an AME chiplet/HI package compiler and code generator 1458 (see, e.g., block 1412 of FIG. 14A), which can receive the chiplet design specifications via the chiplet/HI embedded system design platform 1454. Using the target package geometry 141 and the set of chiplet design specifications 151, the AME chiplet/HI package compiler and code generator 1458 generates the AME device package (described herein) in conjunction with an AME chiplet/HI toolpath generation and simulation tool 1460. The AME device package can then be sent to the multiple AME fabrication systems 1452a . . . 1452n. The multiple AME fabrication system 1452a . . . 1452n provide advantages over a single AME fabrication system. For example, each AME fabrication system can be configured to use different materials, to build different volumes, to operate at different properties (e.g., temperatures), etc. The multiple AME fabrication systems 1452a . . . 1452n can receive one or more chiplet dies, one or more materials, and/or the like including combinations and/or multiples thereof. Fabricated components from the AME fabrication systems 1452a . . . 1452n can be integrated at block 1462 to generate an AME chiplet/HI package target 156. Further, multiple components can be prefabricated to accelerate the production of one or more chiplet-based device packages utilizing the methods as described herein.

Additional processes also may be included, and it should be understood that the processes depicted in FIG. 14B represent illustrations, and that other processes may be added or existing processes may be removed, modified, or rearranged without departing from the scope of the present disclosure. It should also be understood that the processes depicted in FIG. 14B may be implemented as programmatic instructions stored on a non-transitory computer-readable storage medium that, when executed by a processor (e.g., the processing device 1621 of FIG. 16) of a computing system (e.g., the processing system 1600 of FIG. 16), cause the processor to perform the processes described herein.

Chiplet/HI & AME with Redundant Interconnects for Auto-Recovery/Repair

In chiplet/HI-based implementations, interconnects or “nets” are used to connect dies. During fabrication, errors can occur that cause a net to be inoperable or otherwise unusable. It is therefore desirable to implement recovery nets that can be used when a primary net fails. This approach improves chiplet/HI based device package manufacturing quality and efficiency by enabling chiplet/HI based devices to be used that might otherwise be inoperable.

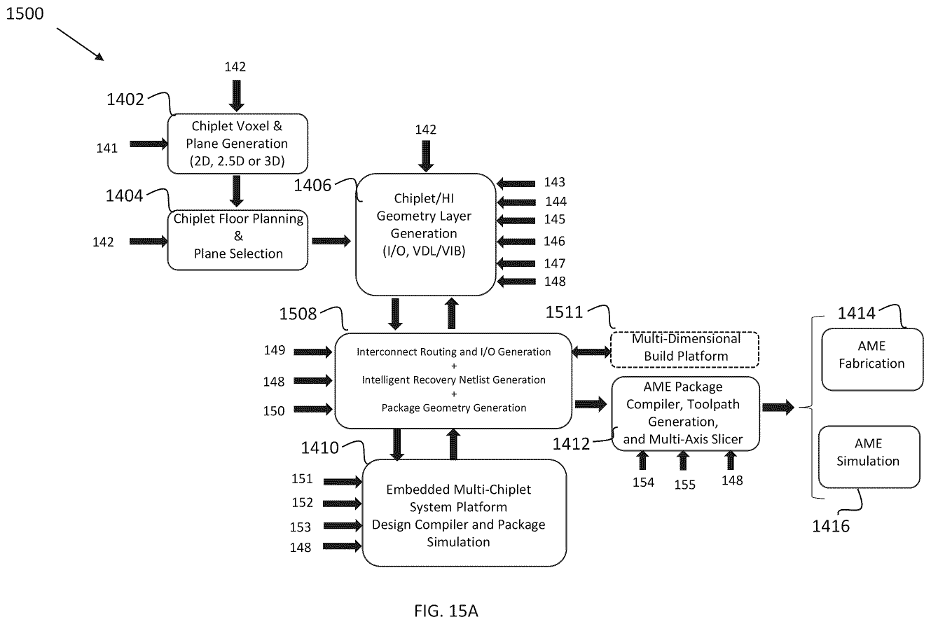

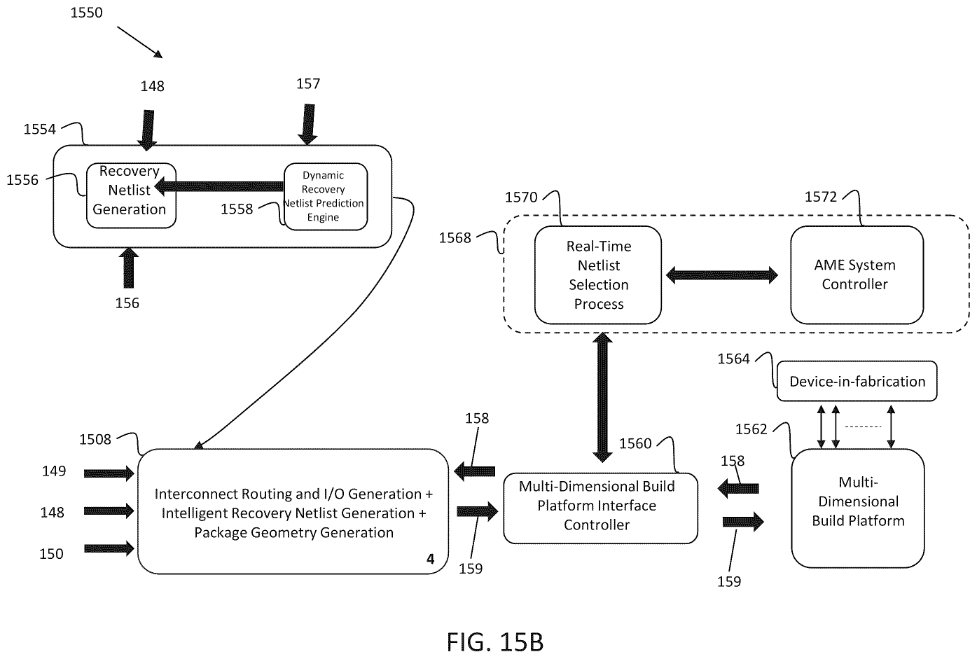

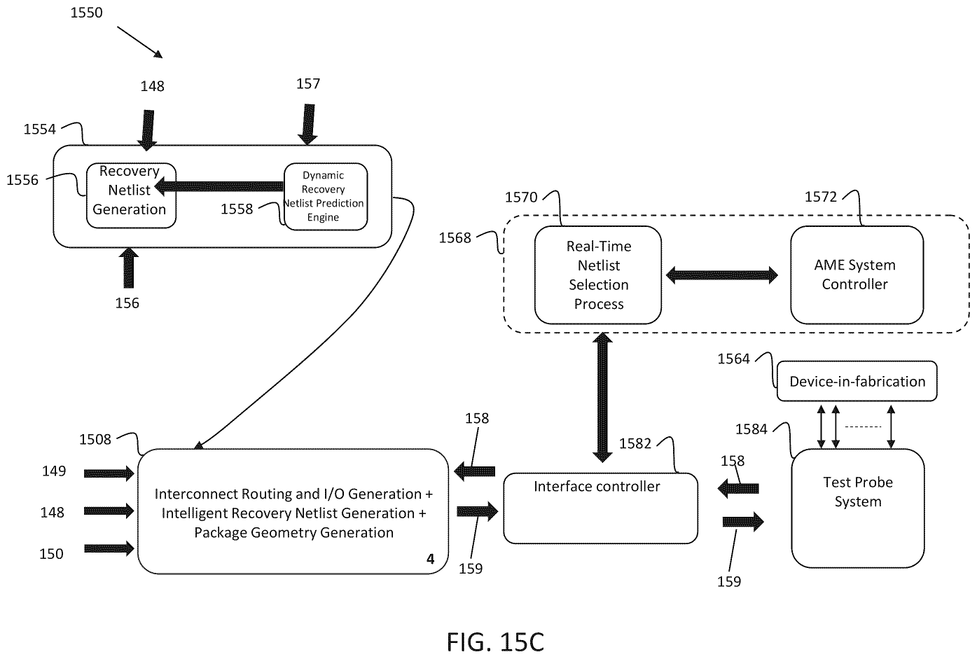

FIG. 15A illustrates a flow diagram of a method 1500 for fabricating a chiplet/HI based device package using AME parametrics for additive manufacturing according to one or more embodiments described herein. The method 1500 is similar to the method 1400; however, the method 1500 provides for generating a new (recovery) netlist that can be used for recovery.

At block 1402, chiplet voxels and corresponding chiplet planes are generated as described herein. At block 1404, a chiplet floor plan is generated and a plane is selected based on a user control/selection 142. At block 1406, a chiplet/HI geometry layer is generated based on various factors as described herein. At block 1508, as with block 1408 of FIG. 14A, interconnect routing and package geometry generation are performed. In addition, block 1508 generates an intelligent recovery netlist 159. In this embodiment, the AME parametrics 148 can include reliability data, which can describe historical net failure information (e.g., how likely a net is to fail). At block 1410, the one or more chiplets are designed as described herein.

It should be appreciated that block 1406, 1508, and 1410 can be interconnected such that changes to the design within one of the blocks can be propagated to the other blocks. For example, if information about a given chiplet design changes at block 1410, those changes can be propagated to block 1508 and 1406 to update the routing and geometry, respectively, including updating the recovery netlist.

According to one or more embodiments described herein, the blocks 1402-1406, 1410, and 1508 are performed in a design software, such as a CAD tool.

At block 1412, the geometry, routing, and chiplet information for each chiplet are sent to an AME package compiler, toolpath generation, and multi-axis slicer tool to compile the AME device package. The AME device package can be used to perform an AME simulation (block 1414) to simulate fabrication of the chiplet-based device package and/or perform AME fabrication simulation (block 1416) to evaluate the fabrication or tool path operation associated with the additive manufacturing of the chiplet-based device package.

According to one or more embodiments described herein, the block 1412 is performed by a software tool of an additive manufacturing printer, or additive manufactured electronics system solution, or 3D printed electronics system solution, or a third-party software tool separate from a software tool of the additive manufacturing printer.

At block 1511, the recovery netlist can be sent to a multi-dimensional build platform to aid in building recovery netlists into the fabricated chiplet-based device package. Recovery netlists provide backup nets that can be used when a primary net fails. The recovery netlist is a predicted netlist based on an existing netlist, design rules, and/or historical, real-time, and/or near-real-time fabrication and testing data. The recovery netlist provides for building redundant circuit layer geometries so alternative paths can be selected and used when a fault is detected. The recovery netlist is generated, for example, based on physical design rules and an initial chiplet-to-chiplet netlist.

Additional processes also may be included, and it should be understood that the processes depicted in FIG. 15A represent illustrations, and that other processes may be added, or existing processes may be removed, modified, or rearranged without departing from the scope of the present disclosure. It should also be understood that the processes depicted in FIG. 15A may be implemented as programmatic instructions stored on a non-transitory computer-readable storage medium that, when executed by a processor (e.g., the processing device 1621 of FIG. 16) of a computing system (e.g., the processing system 1600 of FIG. 16), cause the processor to perform the processes described herein.

FIG. 15B illustrates an architecture 1550 for implementing a recovery netlist. In this example, block 1508 (also described with reference to FIG. 15A) generates the recovery netlist. For example, AME parametrics 148, an inter-chiplet netlist 156, and physical design rules 157 are received at block 1554, where the recovery netlist is generated at block 1556 using a dynamic recovery netlist prediction engine 1558. The inter-chiplet netlist describes the primary and backup netlists that are designed into the chiplet.

A multi-dimensional build platform interface controller 1560 uses the interconnect routing and I/O, the package geometry, and the intelligent recovery netlist 159 from block 1508 to generate a netlist-to-test vector which is sent to a multi-dimensional build platform 1562. The multi-dimensional build platform interface controller 1560 and the multi-dimensional build platform 1562 may be those described in more detail in U.S. patent application Ser. No. 17/574,326 filed Jan. 12, 2022, U.S. Provisional Application No. 63/453,394, filed Mar. 20, 2023, U.S. Provisional Application No. 63/455,083, filed Mar. 28, 2023, or U.S. Provisional Application 63/430,106, Dec. 5, 2022 the contents of all of which are incorporated by reference herein in their entirety. The multi-dimensional build platform 1562 testing of the chiplet-based package under fabrication at block 1564, where build volume test elements are generated, and collects real-time (or near-real-time) (RT) test data 158, which can be sent back to the block 1508 via the multi-dimensional build platform interface controller 1560. The RT test data 158 can be used at block 1554 to generate the recovery netlist for a current or future design.

The multi-dimensional build platform interface controller 1560 also integrates with an AME system 1568, which provides real-time netlist selection (block 1570), which is communicated to an AME system controller 1572. More particularly, the real-time netlist selection (block 1570) selects a netlist to use. When a netlist fails during fabrication, a recovery netlist from the recovery netlist can be selected and indicated to the AME system controller 1572.

FIG. 15C illustrates an architecture 1580 for implementing a recovery netlist. In this example, the multi-dimensional build platform interface controller 1560 and the multi-dimensional build platform 1562 are replaced, respectively, by an interface controller 1582 and a test probe system 1584.

Prior embodiments could be used for planar and/or non-planar chiplet/HI package AME design and fabrication. It was described that AME could be used for design/fabrication of semiconductor die testing, and through extension, multi-Chiplet/HI systems, via AME design/fabricated test fixtures or multi-dimensional build platform implementations. This is because, through using AME methods and the “additive approach,” incremental testing can be performed, at the die level, multi-die level, and die+interconnections and components level, inclusive of applying automated repair. Now, embodiments are described that are focused on planar design and fabrication. Particularly, FIGS. 16A and 16B are block diagrams of architectures 1600, 1650, respectively, for optimized planar chiplet/HI package AME design and fabrication according to one or more embodiments described herein.

FIG. 16C is a block diagram of a software architecture 1660 for AME-based package as a service according to one or more embodiments described herein. FIGS. 16-16C are now described together. It should be noted that there is no limitation that planar packages must be used, as the same methodologies described herein (see, e.g., FIGS. 14A-15C) can also be used to implement a non-planar packaging workflow and service. That is, FIGS. 14A-15C depict a more general case of non-planar, chiplet voxel-based package scenarios, whereas the architectures 1600, 1650, 1660 represent a degenerative, optimized approach that results in an efficient approach to planar packaging scenarios that can readily support user-interactive and/or automated package design and fabrication through multiple methods described including generatively through machine learning methods. Such approaches are more cost effective and are quicker to implement and execute, reducing the cost and fabrication time of SiP/SoP solutions.

FIGS. 16A and 16B illustrate functions that are used to implement an optimized planar device packaging capability along with the sequence of operations/workflow as methods 1600, 1650 respectively. FIGS. 16A and 16B are now described together.

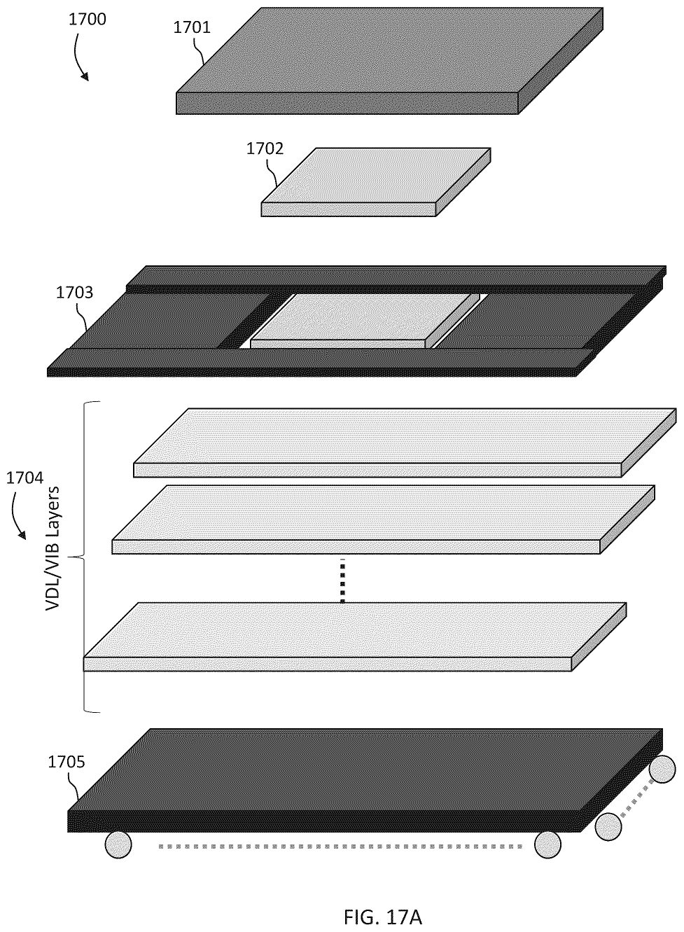

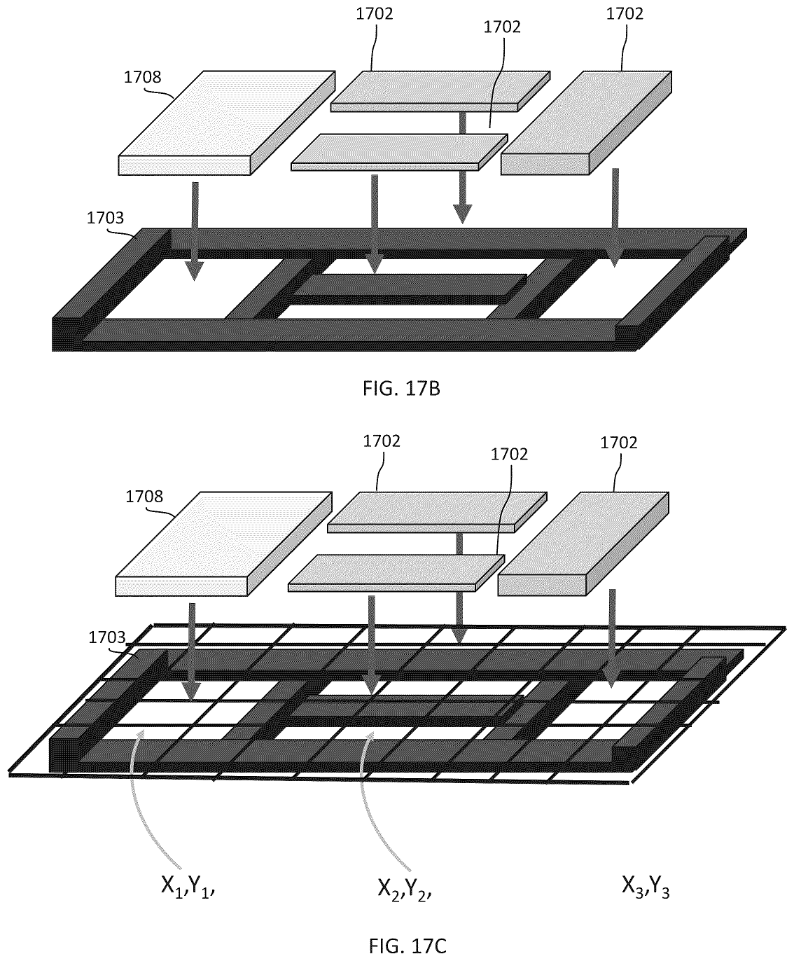

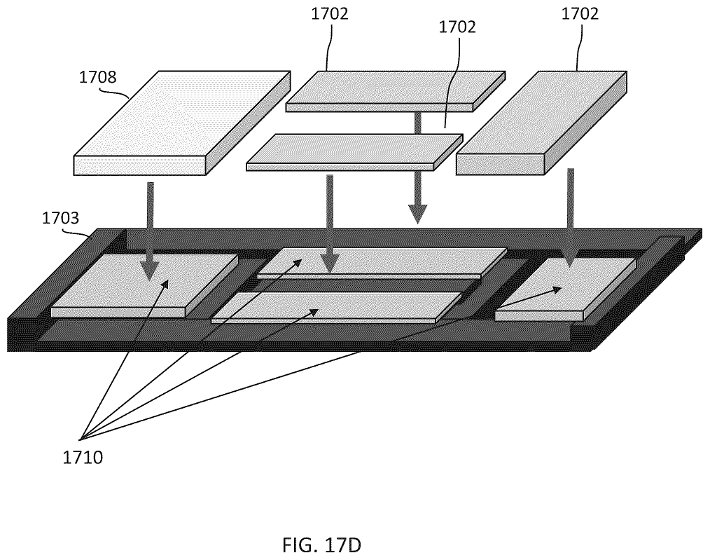

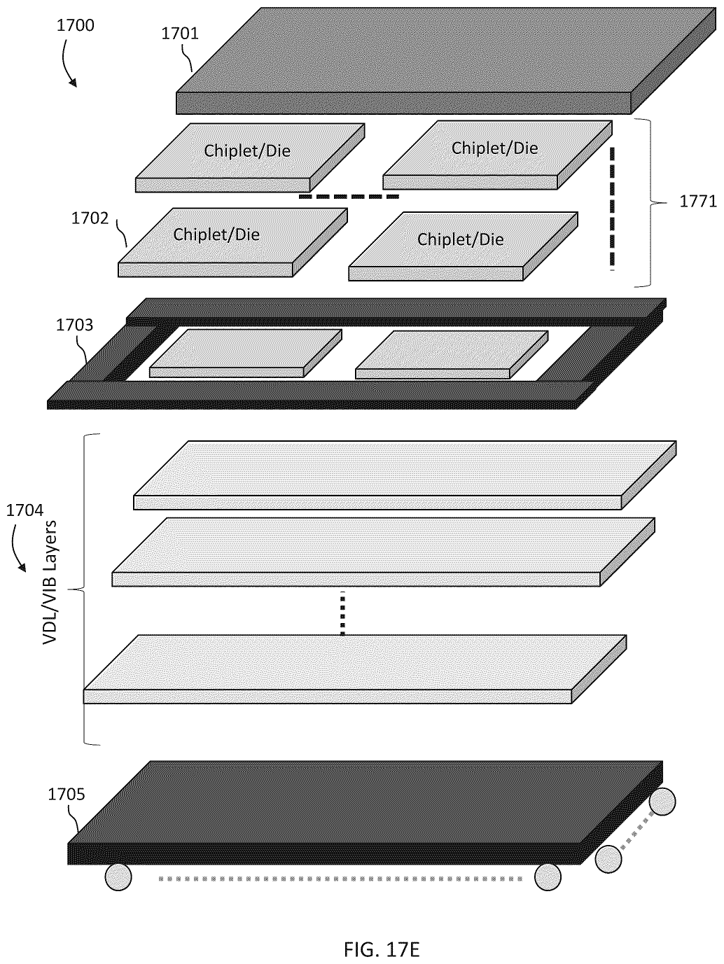

Users 1602 (or a single user) initiates designing a planar device for each of the methods 1600, 1650. One of four different options for defining a chiplet/HI SiP/SoP device are possible: external predefined, interface to a third-party service, automated through machine learning, such as generative methods, and user defined. The options for defining the chiplet/HI SiP/SoP can be selected using a package designer portal interface UX & API services 1604. For the first option (external predefined), the user may select to import a design via one or more third party interfaces 1606. For example, it may be desirable to import a design where that design follows design and process rules defined within a process design kit and/or assembly design kit that are available to the designer and pulled in from the chiplet library 1608 to a chiplet design platform 1610. For the second option (interface to a third-party service), the user loads a design from a pre-existing chiplet library 1608. The third option (user defined) is for the user to create the design using the chiplet design platform 1610 and to simulate the design using a virtual simulation platform 1612 to simulate the design before committing to the chiplet/die fabrication, shown together in block 1609. In a fourth method, the user defines a set of requirements, and through machine learning methods, the platform 1600 synthesizes a chiplet/HI package design. The user may iterate through multiple designs generated until an optimal design is implemented. Once the design has been selected/created, the resulting chiplet is also exported for fabrication to a chip fabricator 1614 where it is manufactured. Within the framework of the package service methodology of FIGS. 16A and 16B, the user can select and configure (depending on the scenarios already described) a floor plan that maps to a specific chiplet/HI frame implementation and target package geometry. The floor plan is a set of scenarios that can be preconfigured and/or user-designed as described with respect to FIGS. 17A-17E. For example, the user uses a floor plan selection and designer module 1618 to select the floor plan. In an embodiment, the floor plan can be automatically generated through the use of machine learning methodologies whereby an optimal floor plan is synthesized based on all the design requirements and specifications provided by the user. The target package geometry can be received from a design/process rules and package geometry database 1616, which implements AME parameters 1620. Thus AME parametrics 1620 and other design/process rules for package fabrication are considered in the floor plan selection. It should be appreciated that, in one or more embodiments, there may be some iteration between the functional blocks 1618, 1622, and 1626 such that the computation of the VDL/VIP, or I/O, etc., may influence the floor plan. Accordingly, the functional blocks 1618, 1622, and 1626 can send/receive information/data among one another based on results of verification/simulation, for example, by the package verification/simulation module 1628 (described herein).

To fully define the Chiplet/HI at the system level, the user provides, using a package and component netlist module 1624, the package and component netlist, which describes how the chiplets, dies, and other active/passive components are to be assembled and interconnected. This specification plus the floor plan From the floor plan selection and designer module 1618) is used by the VDL/VIB compiler 1622 and the package I/O pad generation module 1626 together to generate VDL/VIB layers that include interconnections now routed and placed, or the basic fan-out interconnections as per the scenarios described with reference to FIGS. 17A-17E. Additionally, the package I/O pad generation module 1626 assigns and defines the package solder bumps or otherwise required interconnection pads and substrate mounting structures needed for package bonding to a substrate, such as a PCB.

Before finalizing the package assembly, a package verification/simulation module 1628 can be used to validate that the interconnections, substrate, VDL/VIB are implementable for correctness and design rules, and are optimal for the given design specification and package generated. If desired, the process can iterate through successive optimization processes (implemented in blocks 1618, 1622, and 1626) until a desirable solution is obtained. For example, the verification/simulation module 1628 as part of verification/simulation can invoke an optimization process until there is convergence towards an acceptable overall design. Once validated and the solution is optimal or acceptable, the method 1600 proceeds to a package VDL/VIB & I/O AM-Code generation module 1630 while the method 1650 proceeds to an AME code generation module 1652.

With reference to FIG. 16A, the package VDL/VIB & I/O AM-Code generation module 1630 is special slicer that accepts the upstream geometries of the specified package layers and generates the AM-Code and associated machine toolpath instructions for AME systems 1636. According to one or more embodiments described herein, this is performed for the intermediate layers associated for the Chiplet/HI die bonding layers, VDL/VIB, etc. A bulk package AM-Code generation 1634 generates the overall package geometry AM-Code, and toolpath instructions, but this is for the overall package, without knowledge of the device package internal circuitry. Once the AM-Code is generated, a final AM-Code Generation module 1632 takes the subset slices sets representing the device package and circuit internals and replaces/merge/refactors them into the bulk packaging AM-Code. That is, the final AM-Code Generation module 1632 integrates user-or-system customized and/or computed, predicted through machine learning, or otherwise auto-generated layer geometries into the overall package geometry. The result is a fully merged and correct set of instructions to build the complete package with the 3D printed electronics and chiplet/HI plus components fully integrated for complete package fabrication. The result from the final AM-Code Generation module 1632 is fed into the AME systems 1636, along with the chiplet/dies and components information 1638, for package fabrication. According to one or more embodiments described herein, a multi-dimensional build platform interactive device test module 1640 can be included, where the data from the AME systems 1636 coupled with the package interconnection data can be used to drive a test system ad described herein.

Similar to the method 1600, the method 1650 feeds the results from the package verification/simulation module 1628 into the AME code generation module 1652 which generates the AM-Code similarly to that described for the method 1600. The resulting AM-Code can be fed into the AME systems 1636 and the multi-dimensional build platform interactive device test module 1640.

FIG. 16C is a block diagram of a software architecture 1660 for AME-based package as a service according to one or more embodiments described herein. The architecture 1660 provides merely one of many different possible architectures for building the Chiplet/HI device packaging service described herein. Each of the modules described with respect to FIGS. 16A and 16B could function as a loose collection of asynchronous service modules as shown in FIG. 16C, collectively orchestrated by a central workflow engine 1666 that understands how to invoke different modules, move data between, and orchestrate their operations relative to one another. The architecture 1660 can be hosted in a cloud computing environment, for example, where users could access it via the Internet or other suitable network and a UX/UI to interact with the services used to bring a Chiplet/HI SiP/SoP to fabrication and package. Further note, third-party integrations (supplier of Chiplets designs, libraries, data, or fabrication interfaces to manage Chiplet/die fabrication activities) can occur via a set of micro-services implemented by a secure API integration gateway technology as illustrated.

For example, the architecture 1660 can include an an AME package services UX/UI portal to enable users 1602 to interact with the workflow engine via an AME package service secure API integration gateway 1664. The workflow engine 1666 can access one or more of the chiplet development platform 1610, the virtual simulation platform 1612, the package design/process rules and geometry database 1616, the chiplet library 1608, the floor plan selection and designer module 1618, an AME VDL/VIB and package I/O compiler 1668, an AME system controller 1670, an AME system interface 1672, and AME package code generators 1674. The AME VDL/VIB and package I/O compiler 1668 can compile packages as described herein (e.g., the VDL/VIB compiler module 1622). The AME system controller 1670 can control the AME systems 1636. The AME system interface 1672 can provide an interface between the architecture 1660 and the AME system 1636. The AME package code generators 1674 can generate AM-Code as described herein (e.g., the package VDL/VIB & IO AM-Code generation 1630, the bulk package AM-Code generation 1634, the final AM-Code Generation module 1632, and/or the AME code generation module 1652).

FIG. 17A is a pre-defined layer stack 1700 made up of a frame 1703 and one or more additional layers according to one or more embodiments described herein. In this embodiment, the stack 1700 includes a package lid 1701, a chiplet/die 1702 (that is representative of one or more chiplet/dies and/or components), the frame 1703, VDL/VBI layer(s) 1704, and a lower substrate 1705 (e.g., an external package layer with I/O pads/bumps/balls).

In the embodiment of FIG. 17A (referred to as a device package), the stack 1700, similar to FIGS. 5A and 5B, is shown in which the chiplet/die 1702 is in a pre-configured planar arrangement. One or more chiplet(s)/die(s) and/or component(s) within a fixed frame geometry selectable from a package library are implemented. It should be appreciated that, while a planar implementation is shown in FIG. 17A, such embodiments are not limited to planar arrangements, and non-planar packages can be implemented as described herein. It should be appreciated that, while a single chiplet/die is shown in FIG. 17A, such embodiments are not limited to a single chiplet/die, and one or more chiplets/dies and/or components may be arranged and implemented in multiple different configurations.

The frame 1703 is defined by a floor plan, which can be pre-defined, configurable, and/or computer-defined as described herein. For example, as shown in FIG. 17B, the frame 1703 can be pre-defined based on a use-case, type/number of chiplet(s) and/or component(s) to be used, selected by a user (e.g., from a library), and/or the like including combinations and/or multiples thereof. As yet another example, as shown in FIG. 17C, the frame 1703 can be configurable, such that a pre-defined frame or user-defined frame can be customized/adjusted by a user and/or automatically. As yet another example, as shown in FIG. 17D, the frame 1703 can be generated using one or more various algorithms including machine learning or other similar techniques.

The frame 1703 can be configured to include any suitable and/or desirable number of chiplet(s)/die(s) and/or component(s). For example, the frame 1703 can be configured to include a chiplet/die 1702 (as shown in FIG. 17A) or multiple chiplets/dies (as shown in FIGS. 17B and 17C). The frame 1703 can alternatively or additionally be configured to include a component 1708 (as shown in FIGS. 17B and 17C) or multiple components (not shown). It should be appreciated that in some embodiments, as shown in FIG. 17A, the frame can be configured to include a single chiplet/die (or multiple chiplets/dies) without a component or including components. Other configurations may also be possible. In some embodiments, the chiplet/die 1702 may be arranged in a 3D configuration as a chiplet stack 1771 and the frame 1703 may be configured to include the chiplet stack 1771 (shown in FIG. 17E).

With continued reference to FIG. 17A, for device packages, one or VDL/VIB layer(s) 1704 is introduced in accordance with the VDL/VIB layers 1 . . . . N as described herein. The one or more VDL/VBI layer(s) 1704 is a routing layer(s) and is disposed between the chiplet/die 1702 and the lower substrate 1705. As shown in each of FIG. 17A, the frame 1703 is used to align the chiplet/die 1702 and/or additional chiplet(s)/die(s) and/or component(s). The frame 1703 can be pre-defined (see, e.g., FIG. 17B), configurable by a user (see, e.g., FIG. 17C), and/or automatically generated (see, e.g., FIG. 17D). For example, depending on the scenarios (e.g., FIGS. 2A, 2B, 3A, 3B), the frame 1703 can be either a set of chiplet/die frames templates or a user-defined set of chiplet/die frames, such as on a Cartesian X-Y grid.

FIG. 17B depicts packaging pre-defined device floor plan for a planar packaging flow according to one or more embodiments described herein. In this example, the frame 1703 is pre-defined to receive multiple chiplets/dies 1702 and a component 1708 as shown. However, in other examples, the frame 1703 can be configured differently to receive other types, numbers, layouts, etc., of chiplet(s)/die(s) and/or component(s).

Multiple scenarios can be implemented for device packaging using one or more of the techniques shown in FIGS. 17B and 17C. With reference particularly to FIG. 17B, in a first scenario, chiplet/die bumps are bonded to the substrate. In this example, multiple chiplets/dies 1702 and component 1708 are heterogeneously integrated, where a user (e.g., one of the users 1602) can select N possible predefined frames 1703 from a package geometry library (e.g., the chiplet library 1608). The user can select existing chiplet designs from the library or design new ones (e.g., using the chiplet design platform 1610) and import to platform aligned to N packaging structures. In a second scenario, chiplet(s) are integrated with one or more VDL/VIB layers (e.g., the layers 1704). In this example, multiple chiplets/dies 1702 and component 1708 are heterogeneously integrated, where the user (e.g., one of the users 1602) can select N possible predefined frames 1703 from a package geometry library (e.g., the chiplet library 1608). The user can select existing chiplet designs from library (e.g., the chiplet library 1608) or design new ones (e.g., using the chiplet design platform 16010) and import to platform aligned to N packaging structures. In this example, the package format supports AME interposer with and/or without VIBs.

Turning now to FIG. 17C, in a third scenario, multiple chiplets/dies 1702 and component 1708 are heterogeneously integrated, where the user (e.g., one of the users 1602) can dynamically define/select and place each chiplet/die 1702 and/or component 1708 onto the frame 1703 anywhere on an X-Y grid as shown. In a fourth scenario, chiplet(s) are integrated with one or more VDL/VIB layers (e.g., layers 1704). In this example, multiple chiplet/dies 1702 and component 1708 are heterogeneously integrated where the user (e.g., one of the users 1602) can dynamically define/select and place each chiplet/die 1702 and/or components 1708 onto the frame 1703 anywhere on the X-Y grid as shown. In this example, the package format supports AME with and/or without VDL/VIBs.

FIG. 17D depicts AME-based service model scenarios for device package formats according to one or more embodiments described herein. In this embodiment, the user defines the chiplet/dies and component(s) (along with the other input parameters such as netlists), and the platform 1600 or 1650 generate the package design automatically. For example, the platform 1600 or 1650 can utilize one or more of optimization algorithms, floor planners, artificial intelligence (AI)/machine learning (such as generative AI approaches designs the optimal floor plan for the user), and/or the like including combinations and/or multiples thereof, to generate the package design. This is illustrated in the example shown in FIG. 17D whereby the chiplet/dies 1702 and one or more components 1708 are to be located on a chiplet frame floor plan 1710 that is automatically generated in accordance with input requirements. While not shown, it should be appreciated that the automated or generative machine learning processes may also implement the other package structures, such as the VDL/VIB's and any associated interconnection routing (PSI, TPV, etc.), I/O and external pads, shielding and thermal layers, etc.

As an embodiment, it should be appreciated that beyond a user-based interaction with the service platforms 1600, 1650, the automated or generative package generation platform workflow can be invoked via the services model defined and as such can be initiated and executed via third-party API's and other service integration methods.

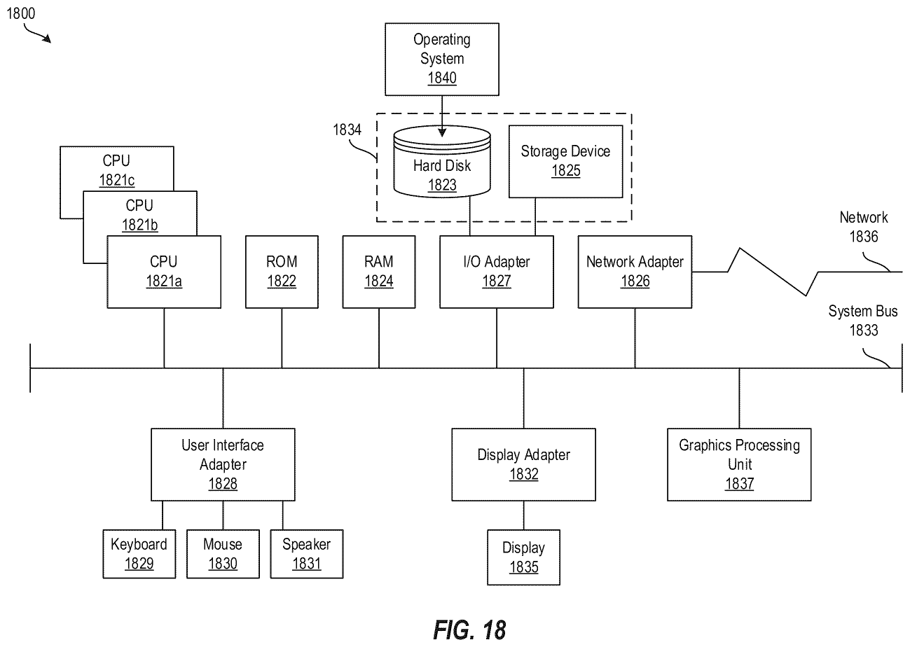

It is understood that one or more embodiments described herein is capable of being implemented in conjunction with any other type of computing environment now known or later developed. For example, FIG. 18 depicts a block diagram of a processing system 1800 for implementing the techniques described herein. In accordance with one or more embodiments described herein, the processing system 1800 is an example of a cloud computing node of a cloud computing environment. In examples, processing system 1800 has one or more central processing units (“processors” or “processing resources” or “processing devices”) 1821a, 1821b, 1821c, etc. (collectively or generically referred to as processor(s) 1821 and/or as processing device(s)). In aspects of the present disclosure, each processor 1821 can include a reduced instruction set computer (RISC) microprocessor. Processors 1821 are coupled to system memory (e.g., random access memory (RAM) 1824) and various other components via a system bus 1833. Read only memory (ROM) 1822 is coupled to system bus 1833 and may include a basic input/output system (BIOS), which controls certain basic functions of processing system 1800.

Further depicted are an input/output (I/O) adapter 1827 and a network adapter 1826 coupled to system bus 1833. I/O adapter 1827 may be a small computer system interface (SCSI) adapter that communicates with a hard disk 1823 and/or a storage device 1825 or any other similar component. I/O adapter 1827, hard disk 1823, and storage device 1825 are collectively referred to herein as mass storage 1834. Operating system 1840 for execution on processing system 1800 may be stored in mass storage 1834. The network adapter 1826 interconnects system bus 1833 with an outside network 1836 enabling processing system 1800 to communicate with other such systems.

A display (e.g., a display monitor) 1835 is connected to system bus 1833 by display adapter 1832, which may include a graphics adapter to improve the performance of graphics intensive applications and a video controller. In one aspect of the present disclosure, adapters 1826, 1827, and/or 1832 may be connected to one or more I/O busses that are connected to system bus 1833 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 1833 via user interface adapter 1828 and display adapter 1832. A keyboard 1829, mouse 1830, and speaker 1831 may be interconnected to system bus 1833 via user interface adapter 1828, which may include, for example, a Super I/O chip integrating multiple device adapters into a single integrated circuit.

In some aspects of the present disclosure, processing system 1800 includes a graphics processing unit 1837. Graphics processing unit 1837 is a specialized electronic circuit designed to manipulate and alter memory to accelerate the creation of images in a frame buffer intended for output to a display. In general, graphics processing unit 1837 is very efficient at manipulating computer graphics and image processing and has a highly parallel structure that makes it more effective than general-purpose CPUs for algorithms where processing of large blocks of data is done in parallel.

Thus, as configured herein, processing system 1800 includes processing capability in the form of processors 1821, storage capability including system memory (e.g., RAM 1824), and mass storage 1834, input means such as keyboard 18218 and mouse 1830, and output capability including speaker 1831 and display 1835. In some aspects of the present disclosure, a portion of system memory (e.g., RAM 1824) and mass storage 1834 collectively store the operating system 1840 to coordinate the functions of the various components shown in processing system 1800.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It should also be noted that the terms “first”, “second”, “third”, “upper”, “lower”, and the like may be used herein to modify various elements. These modifiers do not imply a spatial, sequential, or hierarchical order to the modified elements unless specifically stated.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instruction by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments described herein.

While the disclosure is provided in detail in connection with only a limited number of embodiments, it should be readily understood that the disclosure is not limited to such disclosed embodiments. Rather, the disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that the exemplary embodiment(s) may include only some of the described exemplary aspects. Accordingly, the disclosure is not to be seen as limited by the foregoing description, but is only limited by the scope of the appended claims.

What is claimed is:

1. A method for manufacturing a semiconductor package using an additive manufacturing system, the method comprising:
forming a base layer;
forming a frame coupled to the base layer, the frame having a volume configured to receive at least one a semiconductor die;
inserting the at least one semiconductor die into the frame, the semiconductor die having at least one connection point;
forming a volume distribution layer around the plurality of connection points, the volume distribution layer having at least one interconnect integrally formed in the volume distribution layer, the at least one interconnect connected to one or more of the at least one connection point; and
depositing a coupling connector on each interconnect, the coupling connector being coupled to the volume distribution layer.

2. The method of claim 1, further comprising forming an encapsulating layer on at least one side of the volume distribution layer, the base layer, or the frame.

3. The method of claim 2, wherein the encapsulating layer is formed around the deposited coupling connectors on the volume distribution layer.

4. The method of claim 1, further comprising forming a thermal layer between the semiconductor die and the base layer.

5. The method of claim 1, wherein the base layer is one or more of a thermal layer and/or a shielding layer.

6. The method of claim 1, wherein the semiconductor die is an arrangement of electrically connected semiconductors.

7. The method of claim 6, wherein the arrangement of electrically connected semiconductors is inserted into the frame as a prefabricated assembly.

8. The method of claim 1, wherein one or more regions of the semiconductor package are formed using Volumetric Additive Manufacturing by selective photo-polymerization or simultaneous synthesis of a liquid substrate.

9. The method of claim 8, wherein the liquid substrate is polymerized or synthesized as an dielectric, insulator or structural region when forming non-conductive regions within the volume distribution layer and the liquid substrate is polymerized or synthesized as a conductor when forming the conductive interconnects within the volume distribution layer.

10. The method of claim 1, further comprising inserting a plurality of semiconductor dies into the frame;
wherein the interconnects formed in the volume distribution layer connect one or more of the plurality of semiconductor dies to each other.

11. A method for manufacturing a semiconductor package using additive manufacturing, the method comprising:
forming a first volume distribution layer with at least one first interconnect integrally formed in the first volume distribution layer;
forming at least one first mount on a surface of the first volume distribution layer, each first mount having a planar surface opposite the surface of the first volume distribution layer, the at least one first interconnect being formed in and extending through each first mount;
mounting at least one semiconductor die having at least one connection point on each first mount;
bonding the at least one connection point of the semiconductor die to the at least one interconnect of the respective first mount.

12. The method of claim 11, further comprising forming a second volume distribution layer around at least one of the first volume distribution layer, the at least one first mount, and at least one semiconductor die, the second volume distribution layer having at least one second interconnect integrally formed therein, the at least one first interconnect is connected the at least one second interconnect; and
forming at least one second mount on a surface of the second volume distribution layer, each second mount having a planar surface opposite the surface of the second volume distribution layer, the at least one second interconnect being formed in and extending through each second mount;
mounting at least one semiconductor die having at least one connection point on each second mount;
bonding the at least one connection point of the semiconductor die to the at least one interconnect of the respective second mount.

13. The method of claim 12, wherein at least one semiconductor die on the first mount is connected to at least one semiconductor die on the second mount by the at least one first interconnect and the at least one second interconnect.

14. The method of claim 12, further comprising forming at least one of a shielding layer or a thermal layer between the first volume distribution layer and the second volume distribution.

15. The method of claim 12, further comprising forming one or more of a shielding layer, a thermal layer, and an encapsulating layer around the second volume distribution layer.

16. The method of claim 11, wherein the surface of the first volume distribution layer is non-planar.

17. The method of claim 11, wherein the first mount comprises a plurality of members of varying dimension to conform with the surface of the first volume distribution layer to form the planar surface.

18. An additive manufactured semiconductor device comprising:
a three dimensionally shaped volume distribution layer having a plurality of interconnects;
at least one mount integrally formed on the volume distribution layer, the at least one mount defining a semiconductor plane and the plurality of interconnects extending through each mount and the semiconductor plane; and
at least one semiconductor die mounted on each semiconductor plane, the respective at least one semiconductor die being bonded to one or more of the plurality of interconnects extending through the respective at least one mount;
wherein the plurality of interconnects are integrally formed in the volume distribution layer and the at least one mount.

19. The device of claim 18, wherein the volume distribution layer is non-planar and each mount comprises a plurality of members of varying dimension to conform with a surface of the volume distribution layer to form the semiconductor plane.

20. The device of claim 18, further comprising at least one of a shielding layer or thermal layer formed around each semiconductor die.
